(19) United States
(12) Patent Application Publication
(10) Pub. No.: US 2020/0006687 A1
(43) Pub. Date: Jan. 2, 2020

(54) ORGANIC ELECTROLUMINESCENCE ELEMENT

(71) Applicant: Konica Minolta, Inc., Tokyo (JP)

(72) Inventors: Satoru INOUE, Kunitachi-shi, Tokyo (JP); Taketo NAMIKAWA, Hachioji-shi, Tokyo (JP); Kenichi TABATA, Inagi-shi, Tokyo (JP); Yuta NAKAMURA, Hino-shi, Tokyo (JP)

(21) Appl. No.: 16/483,119

(22) PCT Filed: Feb. 21, 2018
(86) PCT No.: PCT/JP2018/006109

§ 371 Date: Aug. 2, 2019

(30) Foreign Application Priority Data
Mar. 21, 2017 (JP) 2017-054471

(51) Int. Cl. H01L 51/50

(52) U.S. Cl. CPC H01L 51/5004; H01L 51/5016

(57) ABSTRACT

An organic electroluminescent element including a light emitting layer containing a first host compound, a second host compound, and a phosphorescent metal complex disposed between a cathode and an anode, wherein the first and the second host compounds satisfy the requirements that: in comparison of emission bands of maximum emission intensity in fluorescence emission spectra of single films of the first host compound alone, the second host compound alone, and a mixture of the first and the second host compounds, a difference between a wavelength of a fluorescence emission end located on a longer wavelength side among fluorescence emission ends of the first host compound and the second host compound, and a wavelength of a fluorescence emission end of the mixture is −3 to 3 nm; and a LUMO energy level and a HOMO energy level of the first host compound and the second host compound satisfy specific relationships.

### TECHNICAL FIELD

The present invention relates to an organic electroluminescent element. More particularly, the present invention relates to an organic electroluminescent element having high external quantum efficiency and improved element lifetime.

### BACKGROUND

Due to the recent rise in price of fossil energy, a system which is capable of generating electricity directly from natural energy is required. As a solar cell capable of achieving power generation at lower cost than the cost of power generation by fossil fuels, a solar cell using single crystal, polycrystalline, or amorphous Si, a compound solar cell such as GaAs or CIGS, or a dye-sensitized photoelectric conversion element (Gretzel cells) has been proposed and put into practical use.

However, in these solar cells, since heavy glass must be used as a substrate, reinforcement work is required at the time of installation, which is a cause of an increase in power generation cost.

Under such circumstances, an organic bulk heterojunction solar cell has been proposed in which an electron donor layer (p-type semiconductor layer) and an electron acceptor layer (n-type semiconductor layer) are mixed between the anode and the cathode. In this bulk heterojunction solar cells, since the parts other than the anode and the cathode are formed by the coating process, it is expected that high-speed and inexpensive manufacturing is possible, and the above-mentioned problem of power generation cost may be solved.

Further, unlike the above-described Si-based solar cells, compound semiconductor-based solar cells, and dye-sensitized solar cells, the bulk heterojunction solar cell does not have a process at a temperature higher than 160° C. Therefore, it is expected that formation on an inexpensive and lightweight plastic substrate is also possible.

In Non-patent Document 1, in order to efficiently absorb the sunlight spectrum, conversion efficiency exceeding 5% is achieved by using an organic polymer that can absorb light of long wavelengths. However, it does not mean that it is better to lengthen the wavelengths. In order to generate charge separation efficiently, there is a suggestion that it is important that: the energy level of LUMO of the molecules constituting the p-type semiconductor layer (electron donor layer) is higher than the energy level of LUMO of the molecules constituting the n-type semiconductor layer (electron acceptor layer); and, the energy level of HOMO of the molecules constituting the n-type semiconductor layer (electron acceptor layer) is lower than the energy level of the HOMO of molecules constituting the p-type semiconductor layer (electron donor layer).

On the other hand, an organic electroluminescent element (hereinafter, also referred to as an organic EL element) has a function opposite to that of an organic solar cell, it is an element composed of an organic thin film layer (single layer portion or multiple layers) containing an organic light emitting material disposed between a cathode and an anode. When a voltage is applied to such an organic EL element, electrons are injected into the organic thin film layer from the cathode and holes from the anode, and these are recombined in the light emitting layer (the organic light emitting material containing layer) to generate excitons. The organic EL element is a light emitting element utilizing emission (fluorescence and phosphorescence) of light from these excitons, and it is a technology expected as a next-generation flat display and illumination.

It was reported the following from the Princeton University. In principle, an organic EL element utilizing phosphorescence emission from the excited triplet will realize an emission efficiency of 4 times larger compared with an emission efficiency of an organic EL element utilizing fluorescence emission. Since then, there have been investigated all over the world the materials exhibiting phosphorescence emission at room temperature, the layer constitution and the electrode of the luminescent element.

As described above, a phosphorescence emission mode has a very high potential. However, in an organic EL element utilizing phosphorescence emission, the method of controlling the position of the emission center, in particular, the method of recombination inside of the light emitting layer to stably carrying out emission is a technological problem to be solved for improving efficiency and lifetime of the element. This is a large difference from an organic EL element utilizing fluorescence emission. As an approach for that purpose, it is generally assumed that it is preferable to suppress the charge separation process of the excited state actively generated in the organic solar cell and to actively recombine the charge. Studies are being made to transfer energy from the host compound in the light emitting layer to the light emitting dopant and to perform hole trapping or electron trapping on the light emitting dopant to recombine the light emitting dopant radical and the host compound pair radical in the light emitting layer (for example, refer to Non-patent Document 2).

However, only by doping a single host compound with a phosphorescent metal complex, an excited state is generated on the host compound. Since both excited singlet energy and excited triplet energy are high energy, undesirable form change such as reaction, aggregation, or crystallization occurs. By becoming a site (quencher) that quenches the excited state of the luminescent dopant or a non-luminescent site with a small gap between energy levels, deterioration associated with driving of the organic EL element is caused. When using an organic EL element for a lighting device, there existed a problem that a satisfactory element lifetime was not obtained.

Further, in Patent Document 1, there is disclosed a method of increasing the efficiency by transferring energy from an exciplex to a phosphorescent metal complex using a light emitting layer containing two host compounds that form an excited complex (also referred to as an exciplex) and a phosphorescent metal complex.

However, according to the study of the present inventors, the exciplex has an extremely long wave emission that largely changes the spectral shape as compared to a single electron donating host compound and an electron accepting host compound. For the phosphorescent metal complex in the blue region having short wavelength absorption which is not disclosed in the embodiment of the patent document 1, there was found a problem that it is impossible to produce an overlap of light emission and absorption sufficient to cause Forster energy transfer.

That is, when energy cannot be quickly transferred to the phosphorescent metal complex, since the time of staying in the high-energy excited state is long, there is a problem that it is likely to cause morphological change leading to deterioration, and it is difficult to achieve both of high efficiency and element lifetime.

### PRIOR ART DOCUMENTS

### Patent Documents

Patent Document 1: JP-A No. 2012-186461

### Non-Patent Document

Non-patent Document 1: A. Heeger, Science; vol. 317 (2007) p. 222 Non-patent Document 2: Chihaya ADACHI, “Device properties of Organic semiconductor devices” p. 103 (Kodansha Ltd.)

### SUMMARY OF THE INVENTION

### Problems to be Solved by the Invention

The present invention has been made in view of the above problems and circumstances. An object of the present invention is to provide an organic electroluminescent element having high external quantum efficiency and improved element lifetime.

### Means to Solve the Problems

The present inventors found the following idea in the process of examining the cause of the above problem in order to solve the above problem. It was conceived that the excited state of the host compound could be effectively suppressed by incorporating at least two different host compounds having an energy level relationship of the organic solar cell and having a function capable of relaxing the excited state to the charge separation state (hereinafter, also referred to as photoinduced charge transfer) in the light emitting layer of the organic EL element. Thus, an organic electroluminescent element with improved external quantum efficiency and element lifetime was obtained.

That is, the above-described problems of the present invention are solved by the following embodiments.

An organic electroluminescent element comprising a light emitting layer containing at least a first host compound, a second host compound, and a phosphorescent metal complex disposed between a cathode and an anode, wherein the first host compound and the second host compound have the following characteristics (A) and (B),

(A) characteristic of fluorescence emission spectrum:

in comparison of emission bands of maximum emission intensity in fluorescence emission spectra of single films of the first host compound alone, the second host compound alone, and a mixture of both of the first host compound and the second host compound, a difference between a wavelength of a fluorescence emission end located on a longer wavelength side among fluorescence emission ends of the first host compound and the second host compound, and a wavelength of a fluorescence emission end of the mixture is in the range of −3 to 3 nm; and

(B) characteristic of molecular orbital energy levels:

when energy levels of a highest occupied molecular orbital (HOMO) and a lowest unoccupied molecular orbital (LUMO) of the first host compound and the second host compound are respectively HOMO₁, LUMO₁, HOMO₂ and LUMO₂, the energy levels respectively satisfy relationships represented by the following Expressions (1a) to (1c).

LUMO₁>LUMO₂ Expression (1a):

HOMO₁>HOMO₂ Expression (1b):

ΔG=(LUMO₂−HOMO₁)−{a smaller value of (LUMO₁−HOMO₁) and (LUMO₂−HOMO₂)}<−0.1 (eV) Expression (1c):

2. The organic electroluminescent element described in the embodiment 1, satisfying relationships represented by the following Expressions (2a) and (2b).

ΔG′=(LUMO_{PC}−HOMO₁)−T_{PC1}>0 Expression (2a):

ΔG″=(LUMO₂−HOMO_{PC})−T_{PC1}>0 Expression (2b):

wherein,

LUMO_{PC}: an energy level of LUMO of the phosphorescent metal complex,

HOMO_{PC}: an energy level of HOMO of the phosphorescent metal complex,

T_{PC1}: a lowest excited triplet energy level of the phosphorescent metal complex,

HOMO₁: an energy level of HOMO of the first host compound,

LUMO₂: an energy level of LUMO of the second host compound.

3. The organic electroluminescent element described in the embodiment 2, wherein the phosphorescent metal complex has the lowest excited triplet energy level (T_{PC1}) in the range of 2.25 to 3.00 eV.

### Effects of the Invention

According to the above means of the present invention, it is possible to provide an organic electroluminescent element with improved external quantum efficiency and element lifetime.

The mechanism for expressing the effect of the present invention or the mechanism of action is not clear but it is presumed as follows.

The Rehm-Weller equation representing the energy difference between the excited state and the charge separation state generally known in the photochemical domain is shown in Expression (3).

ΔG=(LUMO_{acceptor}−HOMO_{donor})E*−Eq Expression (3):

In Expression (3), LUMO_{acceptor} represents an energy level of LUMO of an electron accepting host compound, HOMO_{donor} represents an energy level of HOMO of an electron donating host compound, E * is an energy of an excited electron accepting host compound or an electron donating host compound (an energy difference between an excited singlet state and a ground state), and Eq represents a coulomb energy between a radical pair.

In Expression (3), when ΔG becomes negative, the energy in the charge separation state is more stable than the energy in the excited state, and relaxation from the excitation state to the charge separation state occurs (this process is also called photoinduced charge transfer).

The present inventors found the following. When an excited state of a host compound is generated, since the excited singlet state and the excited triplet state both have a wide gap and high energy, undesirable shape changes such as reaction, aggregation, and crystallization occur. Then, when the host compound becomes an excited state quencher and a non-emissive recombination substance, it causes deterioration with driving of the organic EL element. In order to solve the above-mentioned problems, the present inventors came to the following idea. In order to inhibit recombination on the host compound and cause only recombination on the dopant, it is possible to more effectively suppress the excited state of the host compound by using light-induced charge transfer (charged state separation in the excited state) widely used in organic solar cells.

That is, two different host compounds corresponding to the configuration of the present invention are mixed to form an energy level relationship that causes charge separation in an excited state used in a bulk heterojunction organic solar cell. When the electron donating host compound is excited, charge transfer is performed by the adjacent electron accepting host compound, and when the electron accepting host compound is excited charge transfer is performed to the adjacent electron donating host compound, thereby the excited states are mutually quenched (deactivated). As a result, it is assumed that the high energy host excited state, which is a starting point of undesirable shape change such as reaction, aggregation, and crystallization, is rapidly removed from the light emitting layer, which leads to the improvement of the element lifetime of the organic EL element.

In addition, the charge separation state generated according to the above Equation (3) may emits light. That is, it is also conceivable that an exciplex formation process may occur in competition with the charge separation process of the excited state. Since the excited triplet energy of the host compound that does not form an exciplex can only be transferred by Dexter energy transfer, which has a low energy transfer rate, the excited state is retained on the excited triplet, it is considered that it tends to be a starting point of the undesirable form change.

However, in the case where an exciplex is generated between two different host compounds and the light absorption spectrum and the emission spectrum of the phosphorescent metal complex sufficiently overlap, this case corresponding to an expression mechanism different from the constitution of the present invention, the excited triplet state and the excited singlet state may be mixed to produce relatively fast Forster energy transfer to the phosphorescent metal complex while competing with the charge separation process. Even in this case, it is presumed that the host excitation state may be more effectively suppressed.

### BRIEF DESCRIPTION OF THE DRAWINGS

FIG. 1A is a conceptual diagram for explaining Expressions (1a) to (1c), and Expressions (2a) and (2b) according to the present invention.

FIG. 1B is another conceptual diagram for explaining Expressions (1a) to (1c), and Expressions (2a) and (2b) according to the present invention.

FIG. 2A is a schematic diagram which indicates the wavelength of the fluorescence emission end according to the present invention.

FIG. 2B is another schematic diagram which indicates the wavelength of the fluorescence emission end according to the present invention.

FIG. 2C is another schematic diagram which indicates the wavelength of the fluorescence emission end according to the present invention.

FIG. 2D is another schematic diagram which indicates the wavelength of the fluorescence emission end according to the present invention.

FIG. 3 is a schematic diagram of a lighting device using an organic EL element of the present invention.

FIG. 4 is a cross-sectional view of a lighting device using an organic EL element of the present invention.

FIG. 5 is a cross-sectional view of a single film sample for evaluation.

FIG. 6 is a cross-sectional view of an organic EL element used in Examples.

### EMBODIMENTS TO CARRY OUT THE INVENTION

An organic electroluminescent element of the present invention has a light emitting layer containing at least a first host compound, a second host compound, and a phosphorescent metal complex disposed between a cathode and an anode, wherein the first host compound and the second host compound have the following characteristics (A) and (B).

This feature is a technical feature common or corresponding to the invention according to each claim.

As an embodiment of the present invention, from the viewpoint of exhibiting the effects of the present invention, it is preferable that the energy levels of the first host compound and the second host compound, and the phosphorescent metal complex (dopant) satisfy the relationships represented by Expressions (2a) and (2b).

In that case, the lowest excited triplet energy level (T_{PC1}) of the phosphorescent metal complex is preferably in the range of 2.25 to 3.00 eV from the viewpoint of obtaining the effect of relaxing the excited state of the present invention.

In the present description, when two figures are used to indicate a range of value before and after “to”, these figures are included in the range as a lowest limit value and an upper limit value.

### «Outline of Organic Electroluminescent Element of the Present Invention»

An organic electroluminescent element of the present invention has a light emitting layer containing at least a first host compound, a second host compound, and a phosphorescent metal complex disposed between a cathode and an anode, wherein the first host compound and the second host compound have the following characteristics (A) and (B).

(A) characteristic of fluorescence emission spectrum:

in comparison of emission bands of maximum emission intensity in fluorescence emission spectra of single films of the first host compound alone, the second host compound alone, and a mixture of both of the first host compound and the second host compound, a difference between the wavelength of the fluorescence emission end located on the longer wavelength side of the fluorescence emission ends of the first host compound and the second host compound, and the wavelength of the fluorescence emission end of the mixture is in the range of −3 to 3 nm.

(B) characteristic of molecular orbital energy levels:

when energy levels of a highest occupied molecular orbital (HOMO) and a lowest unoccupied molecular orbital (LUMO) of the first host compound and the second host compound are respectively HOMO₁, LUMO₁, HOMO₂ and LUMO₂, the energy levels respectively satisfy relationships represented by the following Expressions (1a) to (1c).

LUMO₁>LUMO₂ Expression (1a):

HOMO₁>HOMO₂ Expression (1b):

ΔG=(LUMO₂−HOMO₁)−{a smaller value of (LUMO₁−HOMO₁) and (LUMO₂−HOMO₂)}<−0.1 (eV) Expression (1c):

The magnitude relationship between the energy levels shown by the Expressions (1a) and (1b) relating to the first host compound and the second host compound defines that the first host compound is an electron donor (donor). Thus, in this case, the second host compound becomes an electron acceptor (acceptor).

In addition, that ΔG according to Expression (1c) is a negative value (−0.1 (eV)) indicates that charge separation occurs.

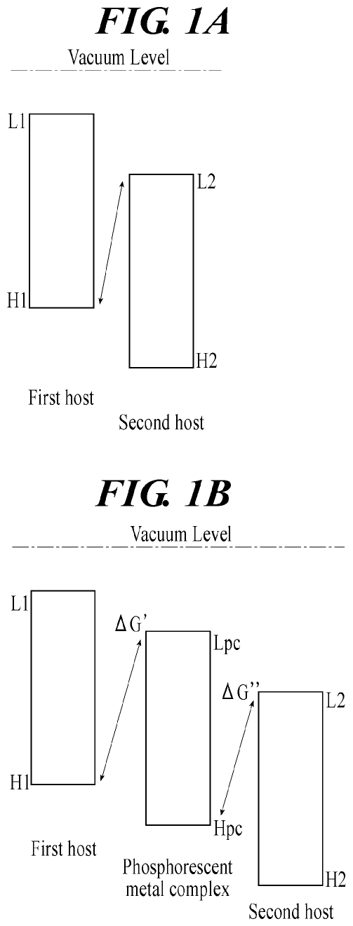

FIG. 1 is a conceptual diagram for explaining Expressions (1a) to (1c), and Expressions (2a) and (2b) according to the present invention.

FIG. 1A is a conceptual diagram indicating the relationship between the energy levels of the first host compound and the second host compound. Here, “L₁” and “L₂” are the LUMO energy levels of the first host compound and the second host compound, and “H₁” and “H₂” are the HOMO energy levels the first host compound and the second host, respectively.

In the present invention, the values of HOMO₁, LUMO₁, HOMO₂, and LUMO₂ are a calculated value with a molecular orbital calculation software Gaussian 98 (Gaussian 98, Revision A. 11.4, M. J. Frisch, et al., Gaussian, Inc., Pittsburgh Pa., 2002). By performing structural optimization of the target molecular structure using B3LYP/6-31G* as a key word for a host compound used in the present invention, and using B3LYP/LanL2DZ as a key word for a phosphorescent metal complex, the respective energies of HOMO, LUMO, and T_{PC1} are calculated (eV unit converted value).

The reason that this calculated value is effective is that it is known that the calculated value obtained by this method has a high correlation with the experimental value. The values obtained by the above method are also used for the numerical values used for the calculation of Expressions (1a) to (1c), and Expressions (2a) and (2b).

The excitation energy of Expression (3) is represented by following Expression (4a) and Expression (4b).

At the time of acceptor excitation, it is expressed as follows.

E*=(LUMO_{acceptor}−HOMO_{acceptor})−e²/(4πεε₀R) Expression (4a):

At the time of donor excitation, it is expressed as follows.

E*=(LUMO_{donor}−HOMO_{donor})−e²/(4πεε₀R) Expression (4b):

In Expressions (4a) and (4b), e²/(4πεε_{0R}) represents exciton binding energy (R is a radius of a sphere having an equivalent molecular radius) in one molecule.

With rough approximation, it can be expressed as follows.

E*−Eq≈(LUMO_{acceptor}−HOMO_{acceptor}) or (LUMO_{donor}−HOMO_{donor}). Expression (4c):

Therefore, Expression (3) is able to evaluate ΔG using HOMO₁, HOMO₂, LUMO₁ and LUMO₂ obtained by the above calculation.

As described above, according to the relationship between the energy levels of HOMO and LUMO of the first host compound and the second host compound in Expressions (1a) and (1b), the first host compound is defined as an electron donor (donor), and the second host compound is defined as electron acceptor. As a result, ΔG of Expression (3) can be rewritten as the following Expression (5).

ΔG=(LUMO_{acceptor}−HOMO_{donor})−{a smaller value of (LUMO_{acceptor}−HOMO_{acceptor}) and (LUMO_{donor}−HOMO_{donor})} Expression (5):

In Expression (5), LUMO_{acceptor} and HOMO_{acceptor} represent the energy levels of LUMO and HOMO of the electron accepting host compound, and LUMO_{donor} and HOMO_{donor} represent the energy levels of LUMO and HOMO of the electron donating host compound. In order to express charge separation in the excited state, ΔG in Expression (5) needs to be negative, and in the present application, ΔG<−0.1 (eV). There is no limit to the lower limit of the negative ΔG range, but as is generally known by the electron transfer reaction rate of Marcus, it is preferred that −ΔG is close to the reorientation energy because charge separation most efficiently occurs. Although the reorientation energy of the organic compound varies depending on the compound to be used, it is approximately 0.1 to 1.0 eV. Therefore, ΔG is preferably in the range of −0.1 to −1.0 eV.

On the other hand, the relationship between the energy levels of the phosphorescent metal complex, the first host compound, and the second host compound preferably satisfies the relationships represented by the Expressions (2a) and (2b).

ΔG′=(LUMO_{PC}−HOMO₁)−T_{PC1}>0 Expression (2a):

ΔG″=(LUMO₂−HOMO_{PC})−T_{PC1}>0 Expression (2b):

Wherein,

LUMO_{PC}: an energy level of LUMO of the phosphorescent metal complex,

HOMO_{PC}: an energy level of HOMO of the phosphorescent metal complex,

T_{PC1}: a lowest excited triplet energy level of the phosphorescent metal complex,

HOMO₁: an energy level of HOMO of the first host compound,

LUMO₂: an energy level of LUMO of the second host compound.

When ΔG′ and ΔG″ become negative, undesirable charge separation quenching may occur from the phosphorescent metal complex, or an exciplex may be formed between the phosphorescent metal complex and the first host compound or the second host compound. This may cause undesirable wave lengthening of the emission light. The undesirable interaction between such luminescent materials and host compounds may be a factor that charge separation quenching has not been actively used in the organic EL element by those skilled in the art.

However, the present inventors came up the idea that the excellent effect of the present invention could be obtained by inducing charge separation between different host compounds while suppressing the interaction between the light emitting material and the host compound.

FIG. 1B is a conceptual diagram indicating the relationship between ΔG′ and ΔG″, wherein ΔG′ is an energy difference between the phosphorescent metal complex and the first host compound, and ΔG″ is an energy difference between the phosphorescent metal complex and the second host compound.

Moreover, in the present invention, it is preferable not to produce an exciplex, and the reason is presumed as follows.

As a similar configuration, for example, in the above-mentioned publication of JP-A No. 2012-186461, there is disclosed a method of transferring energy to a phosphorescent metal complex to increase efficiency by using a light emitting layer containing two kinds of host compounds and a phosphorescent metal complex that form an excited complex (also referred to as an exciplex).

However, in the case where an exciplex is formed as described in paragraph [0074] of the above-described publication, the time of being in the excited state is longer in general. In addition, the exciplexes disclosed in the examples have extremely long-wave light emission that largely changes the spectral shape as compared with a single electron donating host compound/electron accepting host compound (refer to paragraphs [0081] to [0083] of the above-described publication). Therefore, for the phosphorescent metal complex in the blue region having short-wave absorption not disclosed in the examples of the publication, a sufficient overlap of the emission spectrum and the light absorption spectrum to cause Forster energy transfer cannot be produced. When energy transfer to the phosphorescent metal complex cannot be performed promptly, since the time of staying in the high energy excited state is long, it is easy to cause the form change leading to deterioration, and it is a problem that it is difficult to achieve both of the high efficiency and the element lifetime.

Note that photoinduced charge transfer and exciplex both can be distinguished experimentally. The photoinduced charge transfer does not cause wave lengthening because it is deactivation due to electron transfer, and in the exciplex, energy is delocalized between the two host compounds to cause stabilization, resulting in wave lengthening. When there is substantially no wave lengthening at the wavelength of the fluorescence emission end of a single film in which the first host compound and the second host compound are mixed at a ratio of 1:1 compared with the wavelength of the fluorescence emission end of the host compound located on the longer wavelength side among the fluorescence emission end of a single film of the first host compound alone, and the fluorescence emission end of the single film of the second host compound alone, that is, if the wavelength difference of the fluorescence emission end is within the range of −3 to 3 nm including experimental error, it is considered that the wave lengthening has not been made.

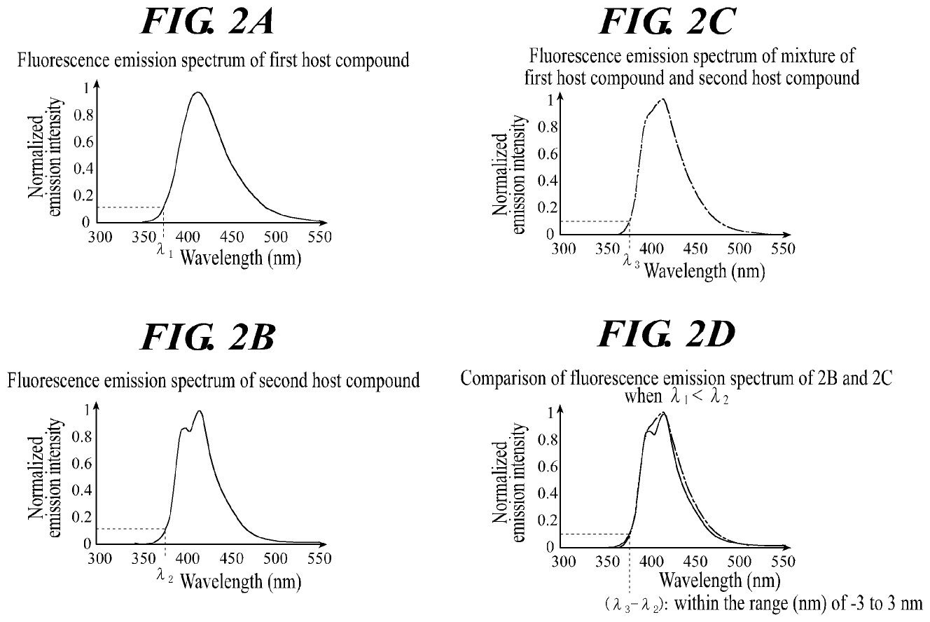

In the present invention, as indicated in FIG. 2, when the intensity of the maximum peak in the emission band of the fluorescence emission spectrum of a single film is normalized to 100%, the wavelength on the short wavelength side whose intensity does not exceed 10% is defined as the wavelength of the fluorescence emission end. Since there is wave lengthening due to relaxation of the polar solvent surrounding the excited compound (so-called solvatochromism), “fluorescence emission maximum wavelength or fluorescence emission largest wavelength” is not suitable for comparison of a single film employing a host compound alone and a single film employing a mixture of host compounds. On the other hand, since the “fluorescent emission end” is not easily affected by the relaxation, in the present application, it is defined not by the “fluorescent emission maximum wavelength or fluorescence emission largest wavelength”, but by the variation of the wavelength of the fluorescent emission end.

FIG. 2A indicates the wavelength λ₁ of the fluorescence emission end determined from the fluorescence emission spectrum of the first host compound, FIG. 2B indicates the wavelength λ₂ of the fluorescence emission end determined from the fluorescence emission spectrum of the second host compound, and FIG. 2C indicates the wavelength λ₃ of the fluorescence emission end determined from the fluorescence emission spectrum of the mixture of the first host compound and the second host compound.

In the case of the present application, as indicated in FIG. 2D, when λ₁<λ₂, it is necessary for the difference between λ₂ and λ₃ to fall within the range of −3 to 3 nm.

The fluorescence emission spectrum is evaluated according to the following measurement method.

The wavelength of the fluorescence emission end is calculated by exciting each single film at an excitation wavelength of 300 nm and measuring the fluorescence emission spectrum at room temperature (23° C., 55% RH). Here, the measurement of the fluorescence emission spectrum is performed using F-7000 (manufactured by Hitachi High-Technologies Corporation), and the wavelength of the fluorescence emission end is a spectrum measured at a resolution of 1 nm.

### »Constitution Layers of Organic EL Element»

Hereinafter, the organic EL element of the present invention will be described in detail.

Representative element constitutions used for an organic EL element of the present invention are as follows, however, the present invention is not limited to these.

(1) Anode/light emitting layer/cathode
(2) Anode/light emitting layer/electron transport layer/cathode
(3) Anode/hole transport layer/light emitting layer/cathode
(4) Anode/hole transport layer/light emitting layer/electron transport layer/cathode
(5) Anode/hole transport layer/light emitting layer/electron transport layer/electron injection layer/cathode
(6) Anode/hole injection layer/hole transport layer/light emitting layer/electron transport layer/cathode
(7) Anode/hole injection layer/hole transport layer/(electron blocking layer/) light emitting layer/(hole blocking layer/) electron transport layer/electron injection layer/cathode

Among these, the embodiment (7) is preferably used. However, the present invention is not limited to this.

The light emitting layer according to the present invention is composed of one or a plurality of layers. When a plurality of layers are employed, it may be placed a non-light emitting intermediate layer between the light emitting layers.

According to necessity, it may be provided with a hole blocking layer (it is also called as a hole barrier layer) or an electron injection layer (it is also called as a cathode buffer layer) between the light emitting layer and the cathode. Further, it may be provided with an electron blocking layer (it is also called as an electron barrier layer) or an hole injection layer (it is also called as an anode buffer layer) between the light emitting layer and the anode.

An electron transport layer according to the present invention is a layer having a function of transporting an electron. An electron transport layer includes an electron injection layer, and a hole blocking layer in a broad sense. Further, an electron transport layer unit may be composed of plural layers.

A hole transport layer according to the present invention is a layer having a function of transporting a hole. A hole transport layer includes a hole injection layer, and an electron blocking layer in a broad sense. Further, a hole transport layer unit may be composed of plural layers.

In the representative element constitutions as described above, the layers eliminating an anode and a cathode are also called as “organic layers”.

### (Tandem Structure)

An organic EL element according to the present invention may be so-called a tandem structure element in which plural light emitting units each containing at least one light emitting are laminated.

A representative example of an element constitution having a tandem structure is as follows.

Anode/first light emitting unit/second light emitting unit/third light emitting unit/cathode; and

Anode/first light emitting unit/intermediate layer/second light emitting unit/intermediate layer/third light emitting unit/cathode.

Here, the above-described first light emitting unit, second light emitting unit, and third light emitting unit may be the same or different. It may be possible that two light emitting units are the same and the remaining one light emitting unit is different.

In addition, the third light emitting unit may not be provided. Otherwise, a further light emitting unit or a further intermediate layer may be provided between the third light emitting unit and the electrode.

The plural light emitting units each may be laminated directly or they may be laminated through an intermediate layer. Examples of an intermediate layer are: an intermediate electrode, an intermediate conductive layer, a charge generating layer, an electron extraction layer, a connecting layer, and an intermediate insulating layer. Known composing materials may be used as long as it can form a layer which has a function of supplying an electron to an adjacent layer to the anode, and a hole to an adjacent layer to the cathode.

Examples of a material used in an intermediate layer are: conductive inorganic compounds such as ITO (indium tin oxide), IZO (indium zinc oxide), ZnO₂, TiN, ZrN, HfN, TiOx, VOₓ, CuI, InN, GaN, CuAlO₂, CuGaO₂, SrCu₂O₂, LaB₆, RuO₂, and Al; a two-layer film such as Au/Bi₂O₃; a multi-layer film such as SnO₂/Ag/SnO₂, ZnO/Ag/ZnO, Bi₂O₃/Au/Bi₂O₃, TiO₂/TiN/TiO₂, and TiO₂/ZrN/TiO₂; fullerene such as C60; and a conductive organic layer such as oligothiophene, metal phthalocyanine, metal-free phthalocyanine, metal porphyrin, and metal-free porphyrin. The present invention is not limited to them.

Examples of a preferable constitution in the light emitting unit are the constitutions of the above-described (1) to (7) from which an anode and a cathode are removed. However, the present invention is not limited to them.

Examples of a tandem type organic EL element are described in: U.S. Pat. Nos. 6,337,492, 7,420,203, 7,473,923, 6,872,472, 6,107,734, 6,337,492, WO 2005/009087, JP-A 2006-228712, JP-A 2006-24791, JP-A 2006-49393, JP-A 2006-49394, JP-A 2006-49396, JP-A 2011-96679, JP-A 2005-340187, JP Patent 4711424, JP Patent 3496681, JP Patent 3884564, JP Patent 4213169, JP-A 2010-192719, JP-A 2009-076929, JP-A 2008-078414, JP-A 2007-059848, JP-A 2003-272860, JP-A 2003-045676, and WO 2005/094130. The constitutions of the elements and the composing materials are described in these documents, however, the present invention is not limited to them.

Hereinafter, each layer which constitutes the organic EL element of the present invention will be described.

### «Light Emitting Layer»

A light emitting layer according to the present invention is a layer which provide a place of emitting light via an exciton produce by recombination of electrons and holes injected from an electrode or an adjacent layer. The light emitting portion may be either within the light emitting layer or at an interface between the light emitting layer and an adjacent layer thereof. The constitution of the light emitting layer according to the present invention is not particularly limited as long as the requirements specified in the present invention are satisfied.

The total thickness of the light emitting layer is not particularly limited, but from the viewpoint of achieving homogeneity of the film to be formed and preventing application of unnecessary high voltage at the time of light emission and improvement of stability of luminescent color with respect to driving current, it is preferable to adjust in the range of 2 nm to 5 nm, more preferably in the range of 2 to 500 nm, and further preferably in the range of 5 to 200 nm.

In the present invention, the thickness of each light emitting layer is preferably adjusted in the range of 2 nm to 1 nm, more preferably adjusted in the range of 2 to 200 nm, further preferably in the range of 3 to 150 nm.

It is preferable that the light emitting layer of the present invention incorporates a light emitting dopant (a light emitting dopant compound, a dopant compound, or simply called as a dopant) and a host compound (a matrix material, a light emitting host compound, or simply called as a host).

### [1] Host Compound

A first host compound and a second host compound according to the present invention are a compound which mainly plays a role of injecting or transporting a charge in a light emitting layer. In an organic EL element, an emission from the host compound itself is substantially not observed.

Preferably, the host compound is a compound exhibiting a phosphorescent emission yield of less than 0.1 at a room temperature (25° C.), more preferably a compound exhibiting a phosphorescent emission yield of less than 0.01. Moreover, it is preferable that the mass ratio in the layer is 20% or more among the compounds contained in a light emitting layer.

It is preferable that the excited energy levels of the first host compound and the second host compound are higher than the excited energy level of the light emitting dopant contained in the same layer.

The first host compound and the second host compound according to the present invention satisfy the following conditions. The difference in wavelength between the wavelength of the fluorescence emission end of the host compound located on the longer wavelength side determined among the fluorescence emission end of the single film of the first host compound alone and the fluorescence emission end of the single film of the second host compound alone, and the fluorescence emission end of a single film obtained by mixing the first host compound and the second host compound is in the range of −3 to 3 nm, and the first host compound and the second host compound satisfy the relationships of Expressions (1a) to (1c).

Therefore, the first host compound and the second host compound according to the present invention are not specifically limited as long as the configuration requirements are met. A known compound previously used in an organic EL element may be used. It may be a compound having a low molecular weight, or a polymer having a high molecular weight. Further, it may be a compound having a reactive group such as a vinyl group or an epoxy group.

The light emitting layer may contain a host compound in addition to the first host compound and the second host compound. As long as the host compound other than the first host compound and the second host compound do not inhibit charge separation between the first host compound and the second host compound, it can be used without particular restrictions on the energy level of HOMO, the energy level of LUMO, and the fluorescence wavelength, and they can be used.

From the viewpoint of having the hole transporting ability or the electron transporting ability, and preventing the increase in wavelength of light emission, and operating the organic EL element stably against heat generation at the time of high temperature drive or device drive, it is preferable that the known first host compound and second host compound have a high glass transition temperature (Tg). Preferably, it is 90° C. or more, and more preferably, it is 120° C. or more.

Here, a glass transition temperature (Tg) is a value obtained using DSC (Differential Scanning Colorimetry) based on the method in conformity to JIS-K-7121.

Specific examples of the known first host compound and second host compound used in the organic EL element of the present invention include compounds described in the following documents, but the present invention is not limited thereto.

Japanese patent application publication (JP-A) Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837; US Patent Application Publication (US) Nos. 2003/0175553, 2006/0280965, 2005/0112407, 2009/0017330, 2009/0030202, 2005/0238919; WO 2001/039234, WO 2009/021126, WO 2008/056746, WO 2004/093 207, WO 2005/089025, WO 2007/063796, WO 2007/063754, WO 2004/107822, WO 2005/030900, WO 2006/114966, WO 2009/086028, WO 2009/003898, WO 2012/023947, JP-A 2008-074939, JP-A 2007-254297, and EP 2034538.

### [1-1] First Host Compound

Although the above-described known host compound may be used as a first host compound, it is preferable to use a material having an electron donating property. Among them, a triarylamine derivative, a carbazole derivative, an indolocarbazole derivative, an azatriphenylene derivative, a low molecule containing an organometallic complex, and a polymer material or an oligomer having the above-described structure introduced into the main chain or side chain are preferably used.

From the viewpoint of the energy level for causing charge separation while suppressing the wave lengthening of the mixed film of the first host compound and the second host compound, carbazole derivatives and indolocarbazole derivatives represented by the following Formula (11) to (15) are more preferable.

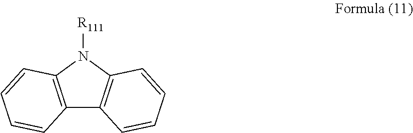

R₁₁₁ represents a hydrogen atom, an alkyl group, an aromatic hydrocarbon ring group, or an aromatic heterocyclic group, and the compound represented by the Formula (11) may further have a substituent.

In Formula (11), examples of the substituent include: an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group); a cycloalkyl group (for example, a cyclopentyl group, and a cyclohexyl group); an alkenyl group (for example, a vinyl group, an allyl group); an alkynyl group (for example, a propargyl group); an aromatic hydrocarbon ring group (also called an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenyl group); a heterocyclic group (for example, an epoxy ring, an aziridine ring, a thiirane ring, an oxetane ring, an azetidine ring, a thietane ring, a tetrahydrofuran ring, a dioxolane ring, a pyrrolidine ring, a pyrazolidine ring, an imidazolidine ring, an oxazolidine ring, a tetrahydrothiophene ring, a sulfolane ring, a thiazolidine ring, an s-caprolactone ring, an s-caprolactam ring, a piperidine ring, a hexahydropyridazine ring, a hexahydropyrimidine ring, a piperazine ring, a morpholine ring, a tetrahydropyran ring, a 1,3-dioxane ring, a 1,4-dioxane ring, a trioxane ring, a tetrahydrothiopyran ring, a thiomorpholine ring, a thiomorpholine-1,1-dioxide ring, a pyranose ring, and a diazabicyclo[2,2,2]-octane ring); an aromatic heterocyclic group (for example, a pyridyl group, a pyrimidinyl group, a furyl group, a pyrrolyl group, an imidazolyl group, a benzimidazolyl group, a pyrazolyl group, a pyrazinyl group, a triazolyl group (for example, 1,2,4-triazol-1-yl group, and 1,2,3-triazol-1-yl group), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diazacarbazolyl group (indicating a ring structure in which one of the carbon atoms constituting the carboline ring of the carbolinyl group is replaced with nitrogen atoms), a quinoxalinyl group, a pyridazinyl group, a triazinyl group, a quinazolinyl group, and a phthalazinyl group); a halogen atom (for example, a chlorine atom, a bromine atom, an iodine atom, and a fluorine atom); an alkoxy group (for example, a methoxy group, an ethoxy group, a propyloxy group, a pentyloxy group, an hexyloxy group, an octyloxy group, and a dodecyloxy group); a cycloalkoxy group (for example, a cyclopentyloxy group and a cyclohexyloxy group); an aryloxy group (for example, a phenoxy group and a naphthyloxy group); an alkylthio group (for example, a methylthio group, an ethylthio group, a propylthio group, a pentylthio group, hexylthio group, an octylthio group, and a dodecylthio group); a cycloalkylthio group (for example, a cyclopentylthio group and a cyclohexylthio group); an arylthio group (for example, a phenylthio group and a naphthylthio group); an alkoxycarbonyl group (for example, a methyloxycarbonyl group, an ethyloxycarbonyl group, a butyloxycarbonyl group, an octyloxycarbonyl group, and a dodecyloxycarbonyl group); an aryloxycarbonyl group (for example, a phenyloxycarbonyl group and a naphthyloxycarbonyl group); a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group); an acyl group (for example, an acetyl group, an ethyl carbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); an acyloxy group (for example, an acetyloxy group, an ethylcarbonyloxy group, a butylcarbonyloxy group, an oclylcarbonyloxy group, a dodecylcarbonyloxy group, and a phenylcarbonyloxy group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethyhexylcarbonylamino group, an octylcarbonylamino group, a dodecylcarbonylamino group, a phenylcathonylamino group, and a naphthylcarbonylamino group); a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethymexylaminocarbonyl group, a dodecylaminocarbonyl group, a phenylaminocarbonyl group, a naphthylaminocarbonyl group, and a 2-pyridylaminocarbonyl group); a sulfinyl group (for example, a methylsulfinyl group, an ethylsufinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an alkylsulfonyl group or an arylsulfonyl group (for example, a methylsulfonyl group, an ethylsulfonyl group, a butylsulfinyl group, a cyclohexylsulfonyl group, a 2-ethylhexylsulfonyl group, and a dodecylsulfonyl group, a phenylsulfonyl group, a naphthylsulfonyl group, and a 2-pyridylsulfonyl group); an amino group (for example, an amino group, an ethylamino group, a dimethylamino group, a butylamino group, a cyclopentylamino group, a 2-ethylhexyl amino group, and a dodecylamino group); an anilino group; a diarylamino group (for example, a diphenylamino group, a dinaphthylamino group, and a phenylnaphthylamino group, a naphthylamino group, and a 2-pyridylamino group); a nitro group; a cyano group; a hydroxy group; a mercapto group; an alkylsilyl group or aiylsilyl group (for example, a trimethylsilyl, a triethylsilyl, a (t)-butyldimethylsilyl, a triisopropylsilyl, a (t)-butyldiphenylsilyl, a triphenylsilyl, a trinaphthylsilyl, and a 2-pyridylsilyl); an alkyl phosphino group or an aryl phosphino group (a dimethyl phosphino group, a diethyl phosphino group, a dicyclohexyl phosphino group, a methylphenyl phosphino group, a diphenyl phosphino group, a dinaphthyl phosphino group, and a di(2-pyridyl)phosphosphino group); an alkyl phosphoryl group or an aryl phosphoryl group (a dimethyl phosphoryl group, a diethyl phosphoryl group, a dicyclohexyl phosphoryl group, a methylphenyl phosphoryl group, a diphenyl phosphoryl group, a dinaphthyl phosphoryl group, and a di(2-pyridyl)phosphoryl group); and an alkylthiophosphoryl group or an arylthiophosphoryl group (a dimethylthiophosphoryl group, a diethylthiophosphoryl group, a dicyclohexylthiophosphoryl group, a methylphenylthiophosphoryl group, a diphenylthiophosphoryl group, a dinaphthylthiophosphoryl group, and a di(2-pyridyl)thiophosphoryl group). In addition, these substituents may be further substituted by the above-described substituent, and they may mutually condense and may form a ring further.

Further, preferred are an alkyl group, an aromatic hydrocarbon ring group, an aromatic heterocyclic group, a heterocyclic group, and a cycloalkyl group.

Specific examples of a compound represented by Formula (11) are indicated in the following, however, the present invention is not limited to these.

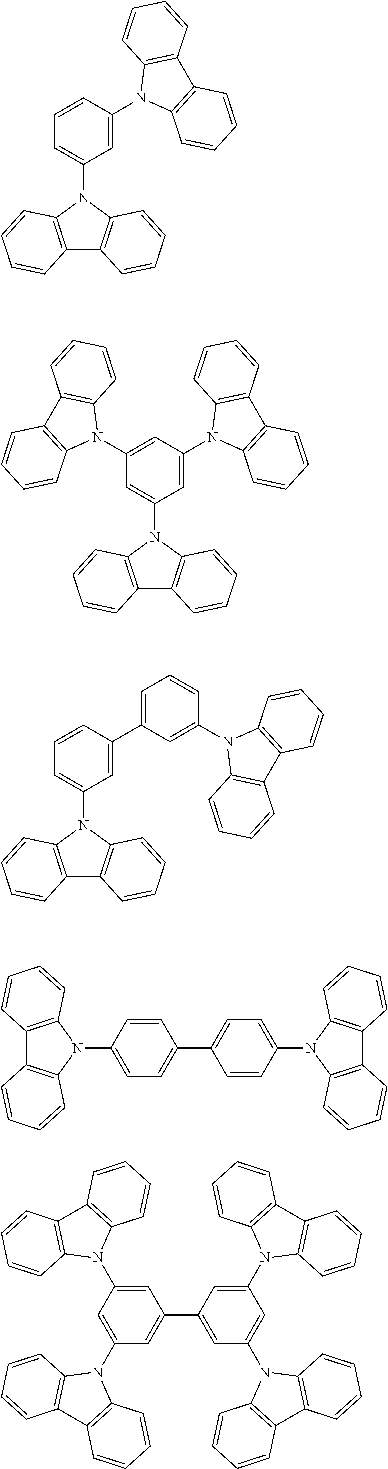

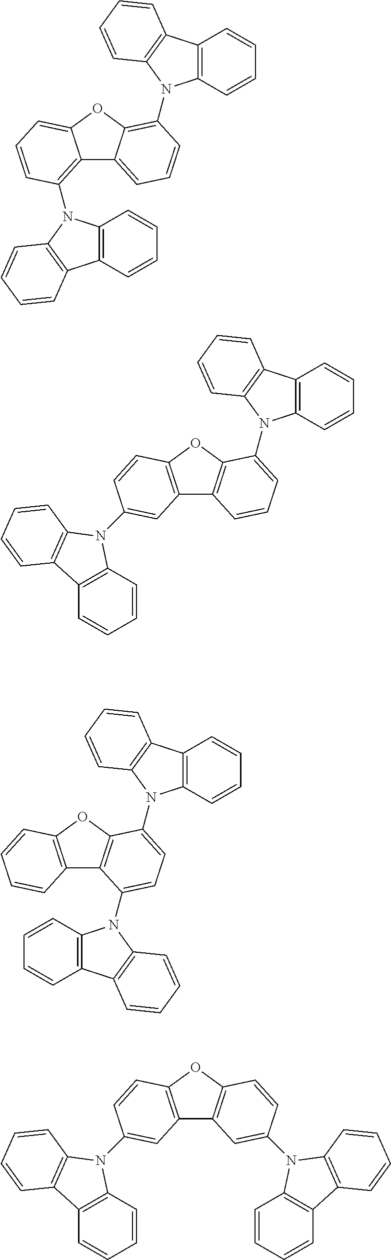

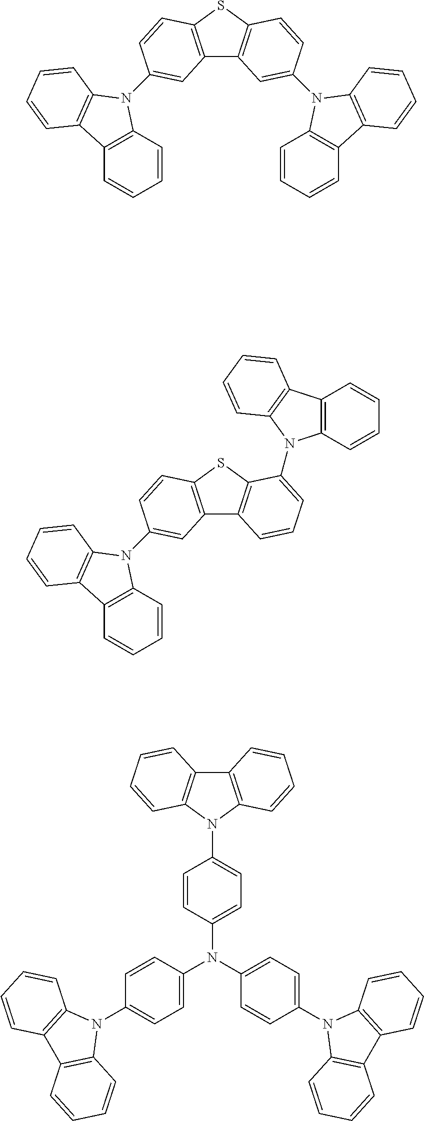

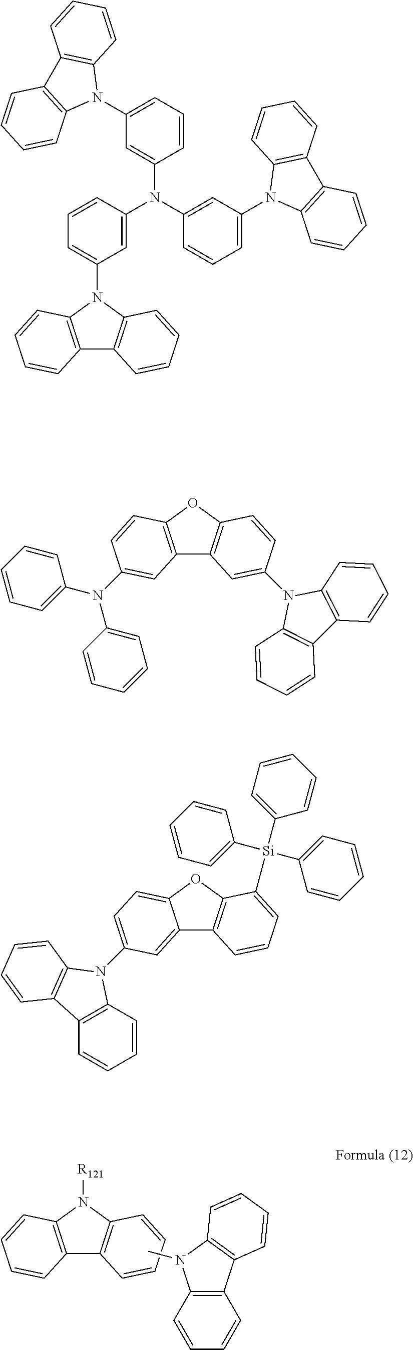

In Formula (12), R₁₂₁ represents an alkyl group, an aromatic hydrocarbon ring group or an aromatic heterocyclic group. The alkyl group, the aromatic hydrocarbon ring group or the aromatic heterocyclic group in Formula (12) has the same meaning as that described for R₁₁₁ in Formula (11).

Specific examples of a compound represented by Formula (12) are indicated in the following, however, the present invention is not limited to these.

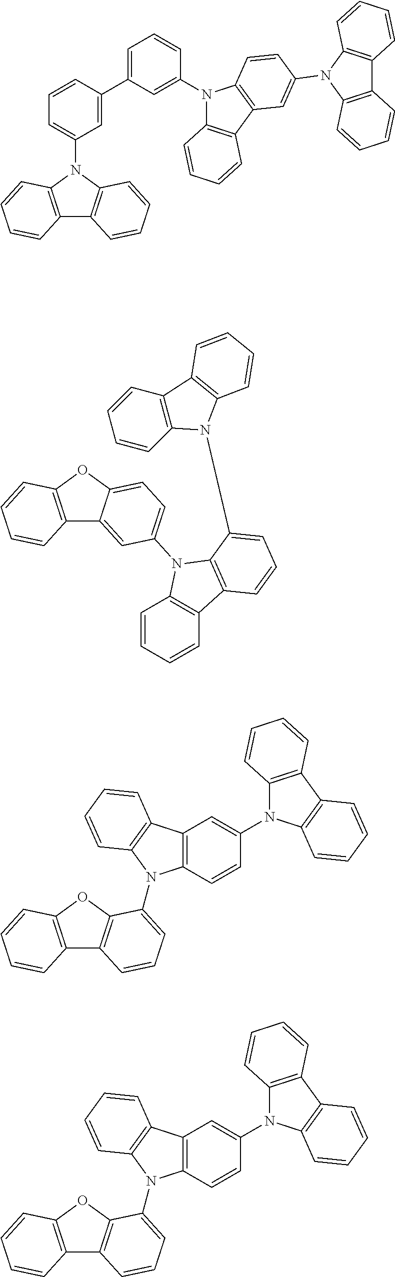

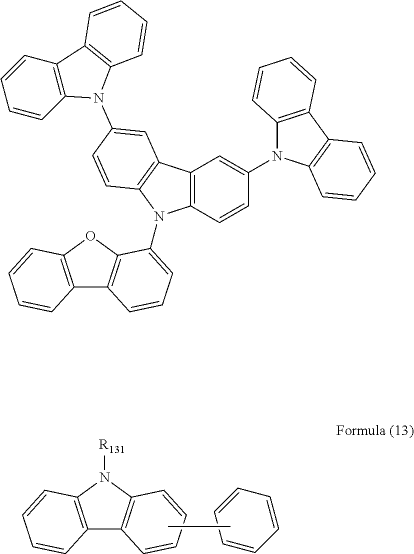

In Formula (13), R₁₃₁ represents an alkyl group, an aromatic hydrocarbon ring group or an aromatic heterocyclic group. The alkyl group, the aromatic hydrocarbon ring group or the aromatic heterocyclic group in Formula (13) has the same meaning as that described for R₁₁₁ in Formula (11).

Specific examples of a compound represented by Formula (13) are indicated in the following, however, the present invention is not limited to these.

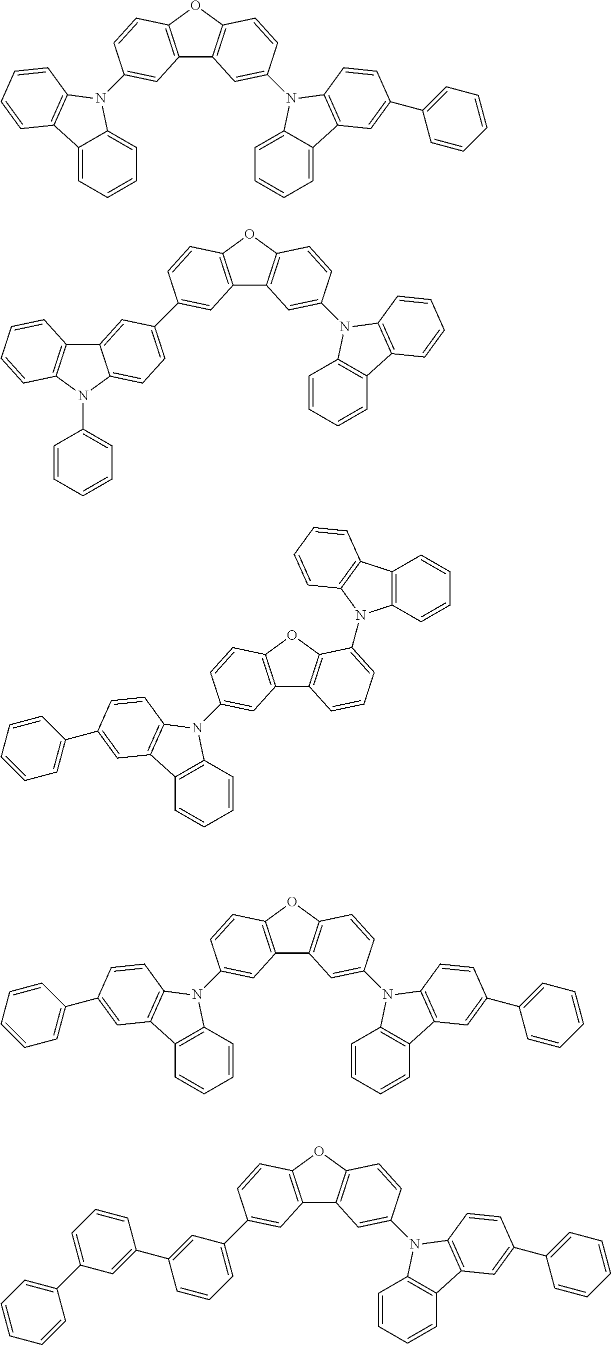

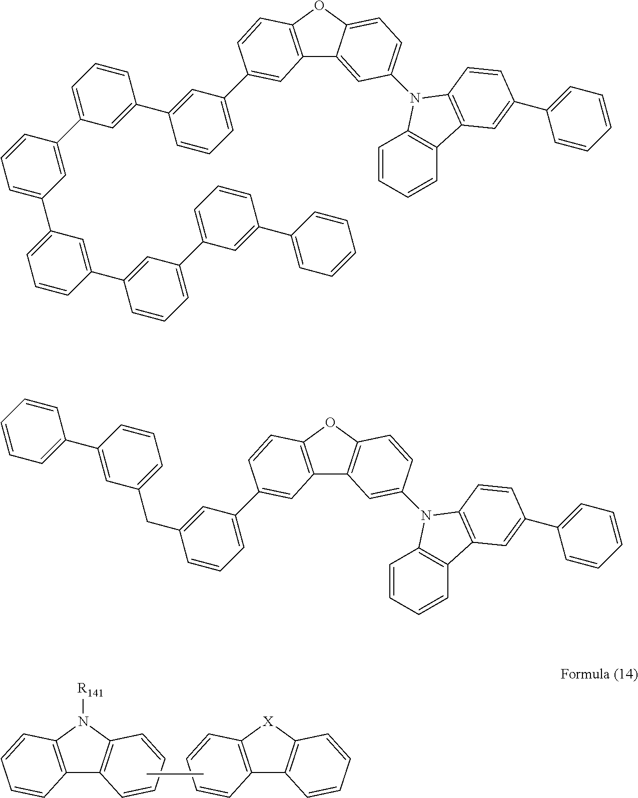

In Formula (14), X represents CRR′, N″, O, S or Si, and R, R′, R″ and R₁₄₁ each independently represent an alkyl group, an aromatic hydrocarbon ring group or an aromatic heterocyclic group. The alkyl group, the aromatic hydrocarbon ring group or the aromatic heterocyclic group in Formula (14) has the same meaning as that described for R₁₁₁ in Formula (11).

Specific examples of a compound represented by Formula (14) are indicated in the following, however, the present invention is not limited to these.

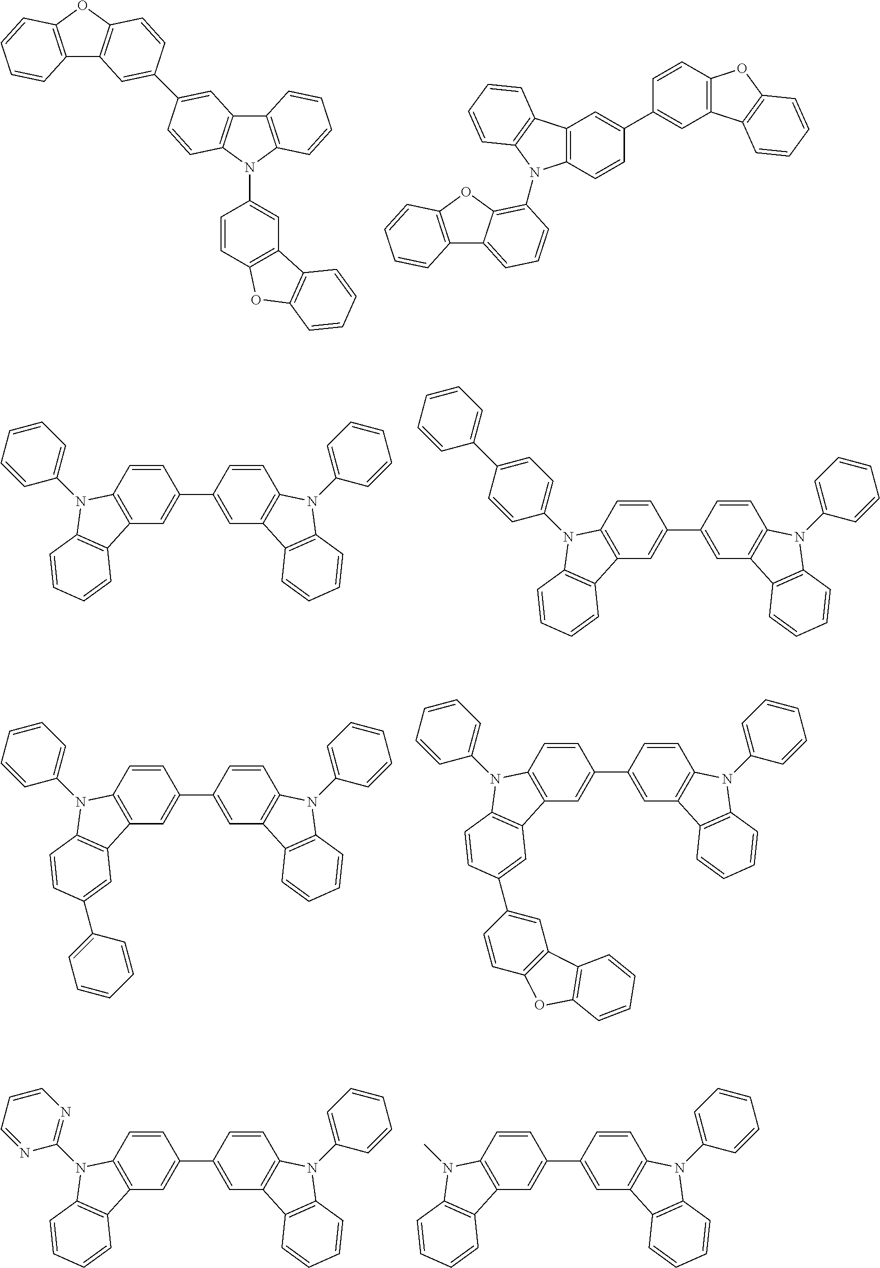

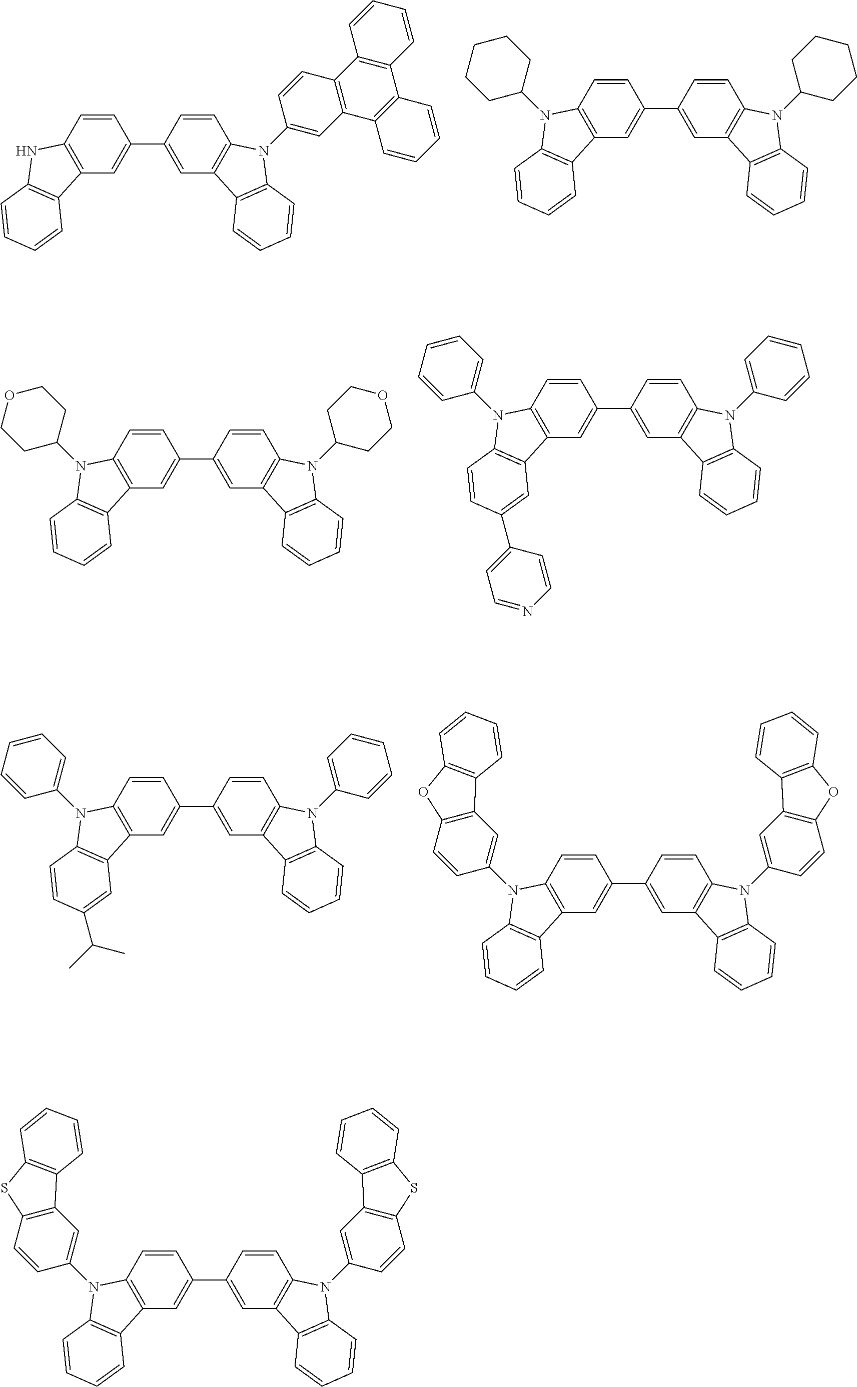

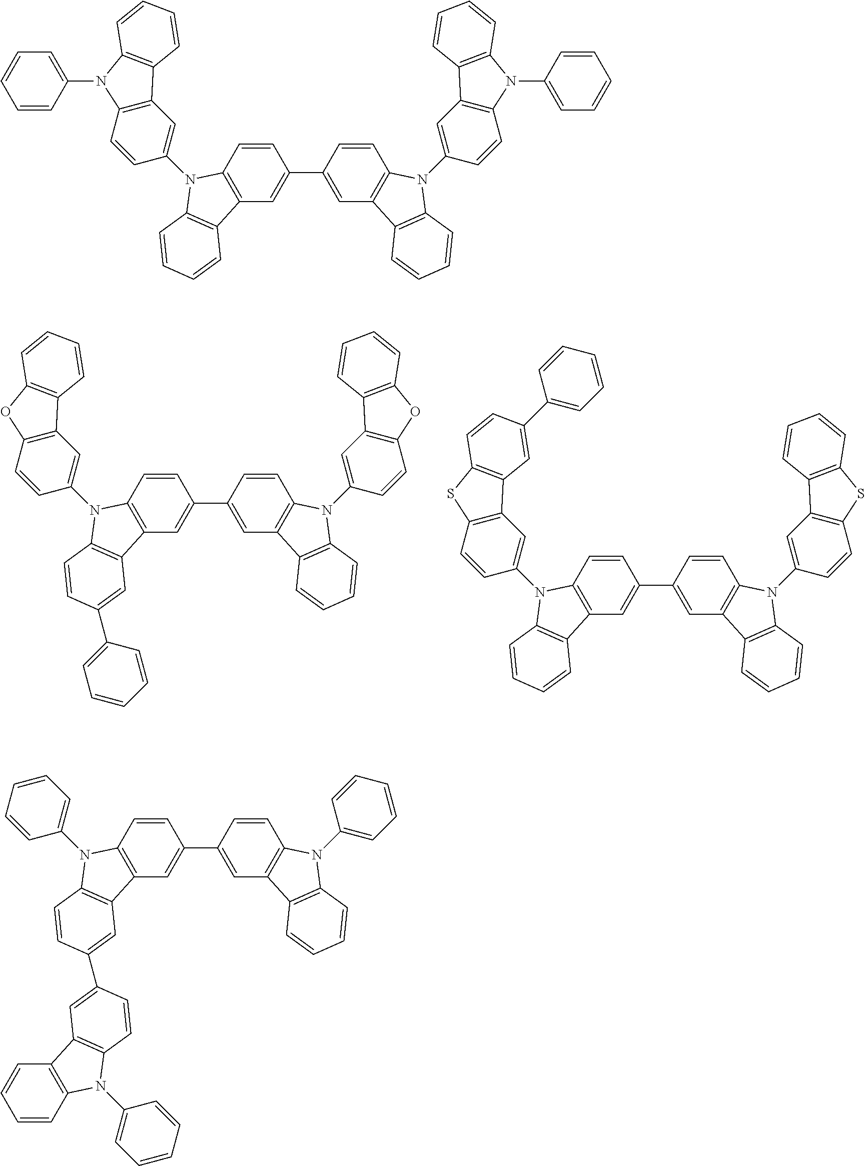

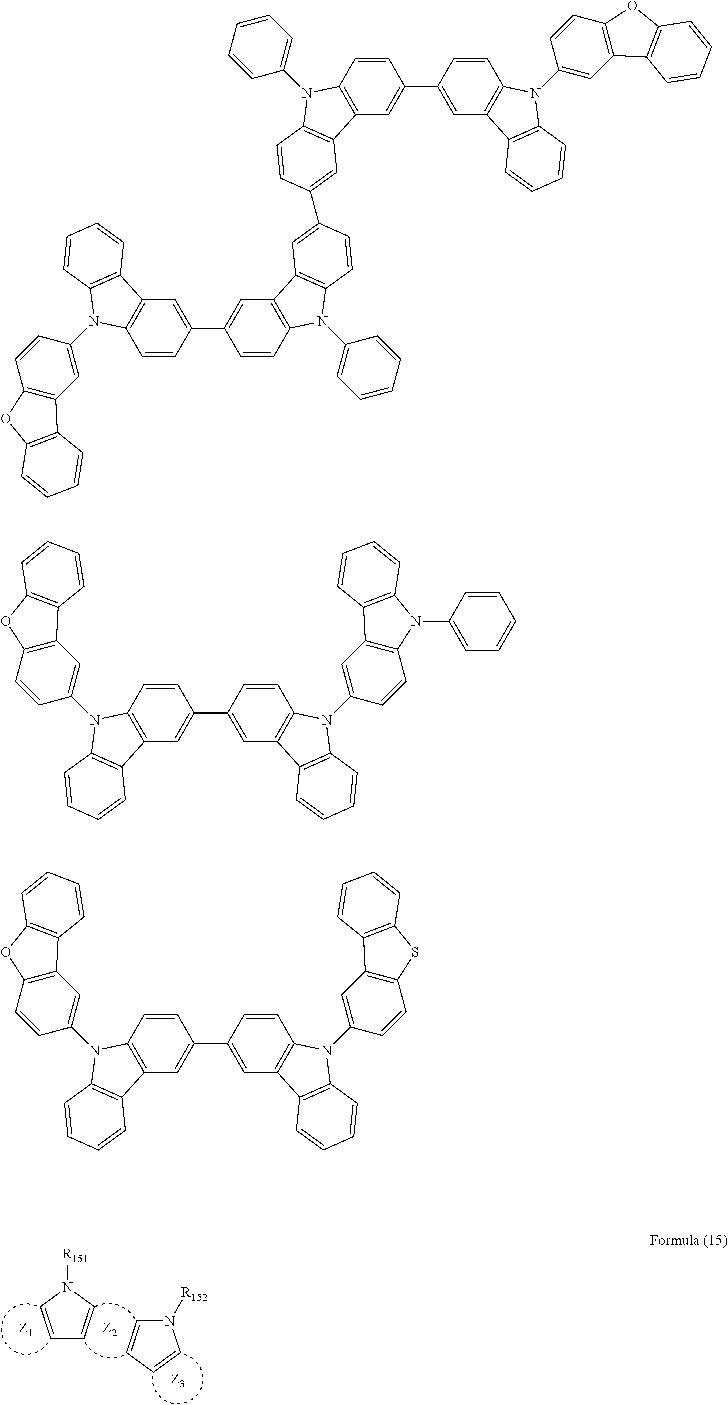

In Formula (15), R₁₅₁ and R₁₅₂ each independently represent an alkyl group, an aromatic hydrocarbon ring group or an aromatic heterocyclic group. Rings Z₁ to Z₃ each represent a residue of forming an aromatic hydrocarbon ring or an aromatic heterocyclic ring, and may have a substituent.

The alkyl group, the aromatic hydrocarbon ring group or the aromatic heterocyclic group in Formula (15) has the same meaning as that described for R₁₁₁ in Formula (11).

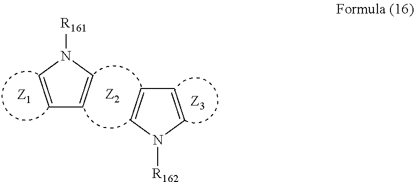

In Formula (16), R₁₆₁ and R₁₆₂ each independently represent an alkyl group, an aromatic hydrocarbon ring group or an aromatic heterocyclic group. Rings Z₁ to Z₃ each represent a residue of forming an aromatic hydrocarbon ring or an aromatic heterocyclic ring, and may have a substituent.

The alkyl group, the aromatic hydrocarbon ring group or the aromatic heterocyclic group in Formula (16) has the same meaning as that described for R₁₁₁ in Formula (11).

Specific examples of a compound represented by Formula (15) or (16) are indicated in the following, however, the present invention is not limited to these.

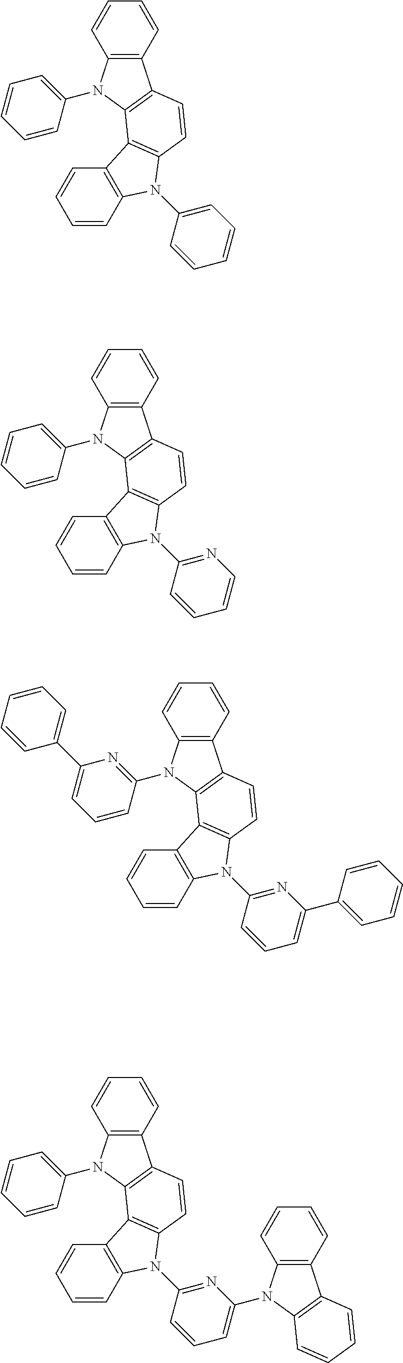 [SMILES: c1ccc(-n2c3ccccc3c3c2ccc2c4ccccc4n(-c4ccccc4)c23)cc1 ; c1ccc(-n2c3ccccc3c3ccc4c(c5ccccc5n4-c4ccccn4)c32)cc1 ; c1ccc(-c2cccc(-n3c4ccccc4c4c3ccc3c5ccccc5n(-c5cccc(-c6ccccc6)n5)c34)n2)cc1 ; c1ccc(-n2c3ccccc3c3ccc4c(c5ccccc5n4-c4cccc(-n5c6ccccc6c6ccccc65)n4)c32)cc1]

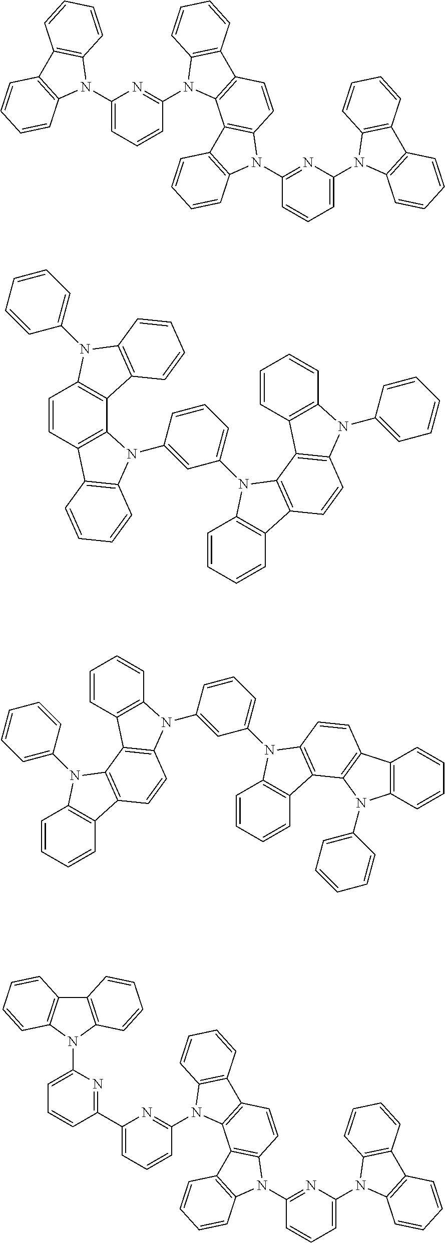 [SMILES: c1cc(-n2c3ccccc3c3ccccc32)nc(-n2c3ccccc3c3c2ccc2c4ccccc4n(-c4cccc(-n5c6ccccc6c6ccccc65)n4)c23)c1 ; c1ccc(-n2c3ccccc3c3c2ccc2c4ccccc4n(-c4cccc(-n5c6ccccc6c6ccc7c(c8ccccc8n7-c7ccccc7)c65)c4)c23)cc1 ; c1ccc(-n2c3ccccc3c3ccc4c(c5ccccc5n4-c4cccc(-n5c6ccccc6c6c5ccc5c7ccccc7n(-c7ccccc7)c56)c4)c32)cc1 ; c1cc(-c2cccc(-n3c4ccccc4c4ccc5c(c6ccccc6n5-c5cccc(-n6c7ccccc7c7ccccc76)n5)c43)n2)nc(-n2c3ccccc3c3ccccc32)c1]

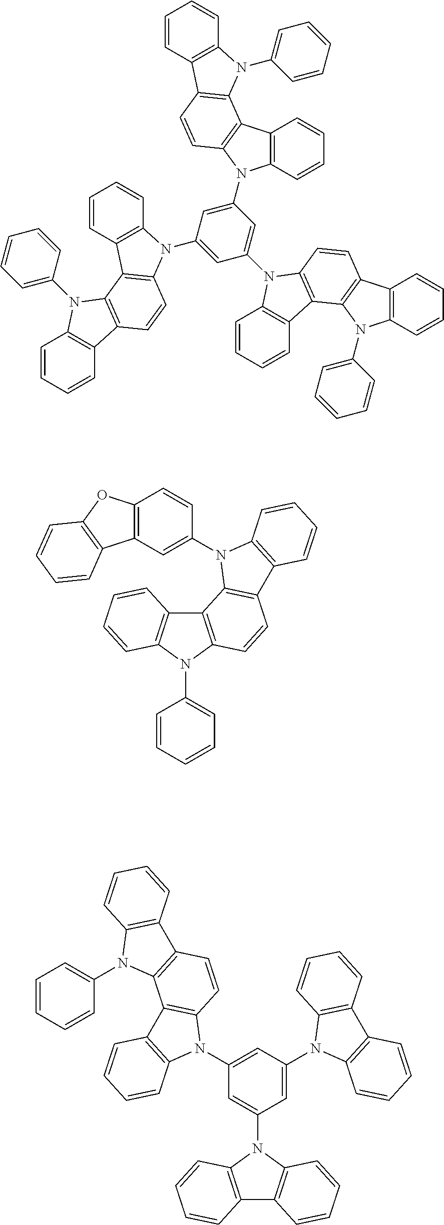 [SMILES: c1ccc(-n2c3ccccc3c3ccc4c(c5ccccc5n4-c4cc(-n5c6ccccc6c6c5ccc5c7ccccc7n(-c7ccccc7)c56)cc(-n5c6ccccc6c6c5ccc5c7ccccc7n(-c7ccccc7)c56)c4)c32)cc1 ; c1ccc(-n2c3ccccc3c3c2ccc2c4ccccc4n(-c4ccc5oc6ccccc6c5c4)c23)cc1 ; c1ccc(-n2c3ccccc3c3ccc4c(c5ccccc5n4-c4cc(-n5c6ccccc6c6ccccc65)cc(-n5c6ccccc6c6ccccc65)c4)c32)cc1]

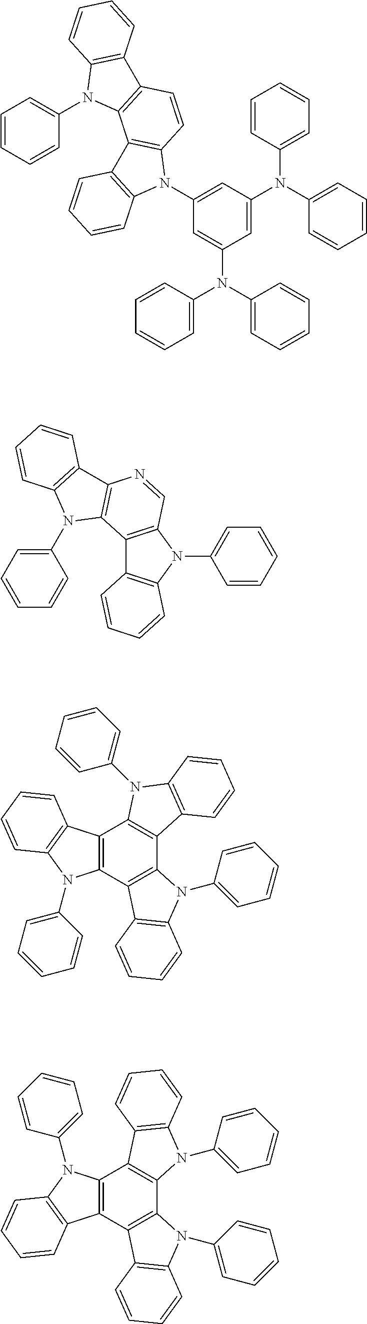 [SMILES: c1ccc(N(c2ccccc2)c2cc(N(c3ccccc3)c3ccccc3)cc(-n3c4ccccc4c4c3ccc3c5ccccc5n(-c5ccccc5)c34)c2)cc1 ; c1ccc(-n2c3ccccc3c3c2cnc2c4ccccc4n(-c4ccccc4)c23)cc1 ; c1ccc(-n2c3ccccc3c3c2c2c4ccccc4n(-c4ccccc4)c2c2c4ccccc4n(-c4ccccc4)c32)cc1 ; c1ccc(-n2c3ccccc3c3c4c5ccccc5n(-c5ccccc5)c4c4c(c5ccccc5n4-c4ccccc4)c32)cc1]

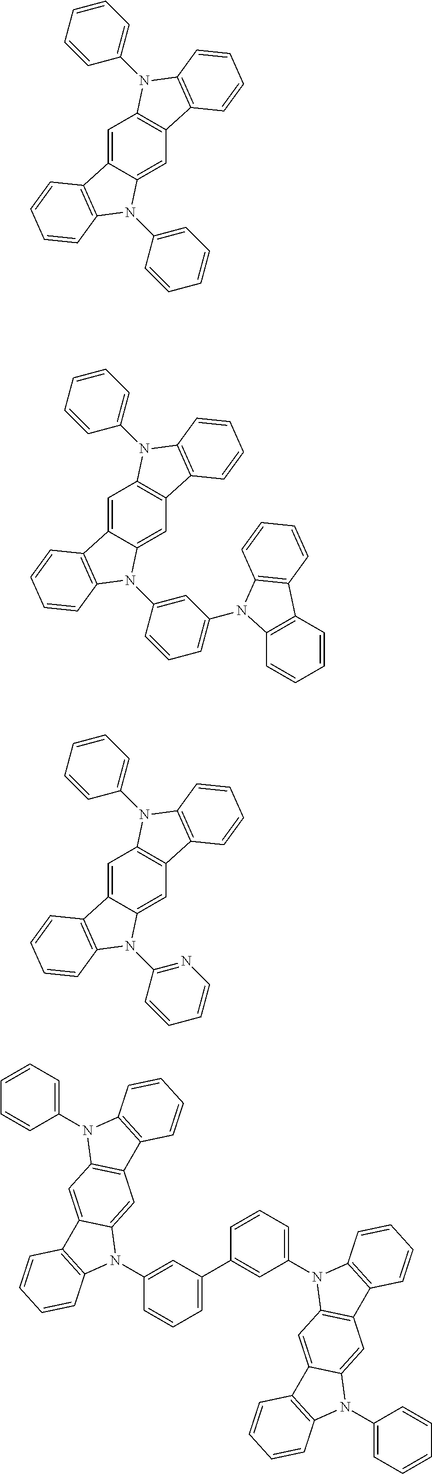 [SMILES: c1ccc(-n2c3ccccc3c3cc4c(cc32)c2ccccc2n4-c2ccccc2)cc1 ; c1ccc(-n2c3ccccc3c3cc4c(cc32)c2ccccc2n4-c2cccc(-n3c4ccccc4c4ccccc43)c2)cc1 ; c1ccc(-n2c3ccccc3c3cc4c(cc32)c2ccccc2n4-c2ccccn2)cc1 ; c1ccc(-n2c3ccccc3c3cc4c(cc32)c2ccccc2n4-c2cccc(-c3cccc(-n4c5ccccc5c5cc6c(cc54)c4ccccc4n6-c4ccccc4)c3)c2)cc1]

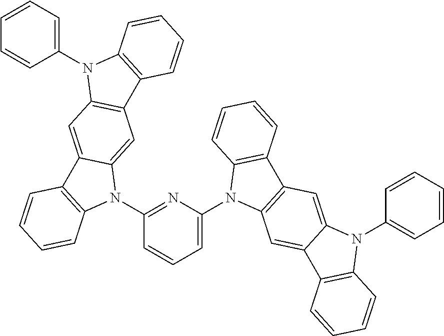 [SMILES: c1ccc(-n2c3ccccc3c3cc4c(cc32)c2ccccc2n4-c2cccc(-n3c4ccccc4c4cc5c(cc43)c3ccccc3n5-c3ccccc3)n2)cc1]

### [1-2] Second Host Compound

Although the above-described known host compound may be used as a second host compound, it is preferable to use a material having an electron accepting property.

Cited examples thereof include: a nitrogen-containing aromatic heterocyclic derivative (a carbazole derivative, an azacarbazole derivative (a compound in which one or more carbon atoms constituting the carbazole ring are substitute with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative); a dibenzofuran derivative, a dibenzothiophene derivative, a silole derivative; and an aromatic hydrocarbon ring derivative (a naphthalene derivative, an anthracene derivative and a triphenylene derivative).

Further, metal complexes having a ligand of a 8-quinolinol structure or dibnenzoquinolinol structure such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, may be also utilized as an electron transport material.

Further, a metal-free or metal phthalocyanine, or a compound whose terminal is substituted by an alkyl group or a sulfonic acid group, may be preferably utilized as an electron transport material.

A polymer material which is introduced these compounds in the polymer side-chain or a polymer main chain may be used.

Materials in which electron withdrawing groups such as a fluoro group, a cyano group, a sulfonyl group, a trifluoromethyl group and a carboranyl group are substituted for these derivatives to increase the electron accepting property may be preferably used.

From the viewpoint of the energy level for causing charge separation while suppressing the wave lengthening of the mixed film of the first host compound and the second host compound, carbazole derivative, it is preferable that the compounds represented by the following Formulas (21) and (22) are carbazole derivatives, azacarbazole-azadibenzofuran-azadibenzothiophene derivatives, and triazine derivatives.

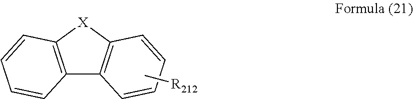

In Formula (21), X represents CRR′, N″, O, S or Si, and R, R′, and R″ each independently represent an alkyl group, an aromatic hydrocarbon ring group or an aromatic heterocyclic group. The alkyl group, the aromatic hydrocarbon ring group or the aromatic heterocyclic group in Formula (21) has the same meaning as that described for R₁₁₁ in Formula (11).

R₂₁₂ represents an electron accepting substituent. In the present invention, the electron accepting substituent is a substituent having a positive Hammett's σₚ value described below, and such a substituent has a property of easily giving an electron to the bonding atom side as compared with a hydrogen atom.

Specific examples of a substituent exhibiting electron acceptability are: a halogen atom (for example, a fluorine atom, a chlorine atom, and a bromine atom), a fluorinated hydrocarbon group (for example, a fluoromethyl group, a trifluoromethyl group, a pentafluoroethyl group, and a pentafluorophenyl group), a cyano group, a nitro group, a silyl group (for example, a trimethylsilyl group, a triisopropylsilyl group, a triphenylsilyl group, and a phenyldiethylsilyl group), and a carboranyl group.

Further, for the Hammett's σₚ value in the case of using another substituent, for example, the following documents may be referred to.

Hammett's σₚ value according to the present invention represents Hammett's substituent constant σₚ. Hammett's σₚ value is a substituent constant determined by Hammett and others from the electronic effect of the substituent on the hydrolysis of ethyl benzoate. Examples thereof are described in “Structure-activity relationship of drugs” (Nankodo Co., Ltd.: 1979), or “Substituent Constants for Correlation Analysis in chemistry and biology” (C. Hansch and A. Leo, John Wiley & Sons, New York, 1979).

Specific examples of a compound represented by Formula (21) are indicated in the following, however, the present invention is not limited to these.

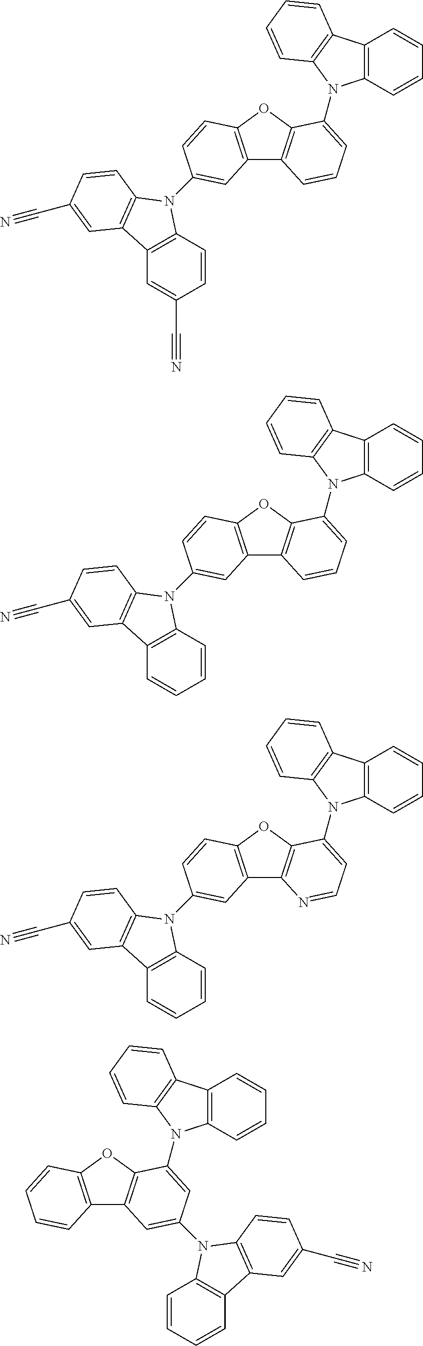

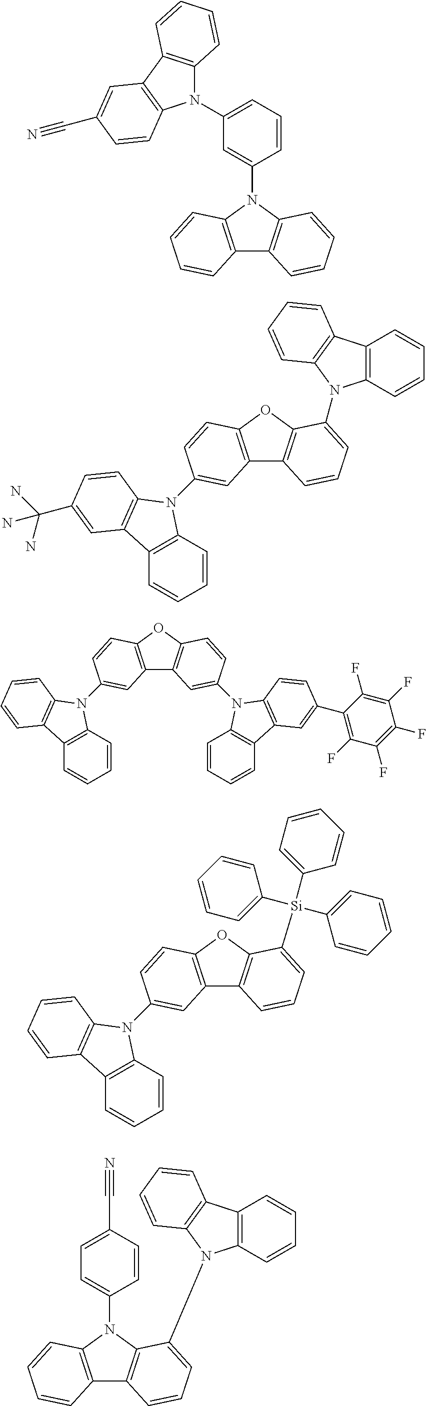

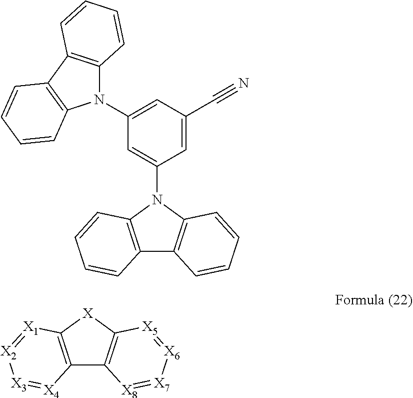

In Formula (22), X represents CRR′, N″, O, S or Si, and R, R′, and R″ each independently represent an alkyl group, an aromatic hydrocarbon ring group or an aromatic heterocyclic group. The alkyl group, the aromatic hydrocarbon ring group or the aromatic heterocyclic group in Formula (22) has the same meaning as that described for R₁₁₁ in Formula (11). In Formula (22), X₁ to X₈ each represent a nitrogen atom or CR′″, and at least one represents a nitrogen atom. R′″ each represents a single bond, a hydrogen atom or a substituent. When there are a plurality of CR′″, each CCR′″ may be the same or different.

Specific examples of a compound represented by Formula (22) are indicated in the following, however, the present invention is not limited to these.

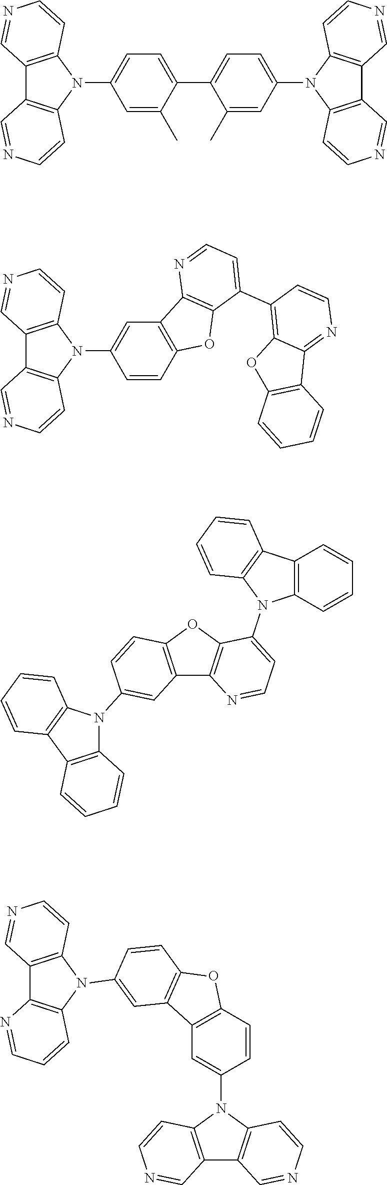 [SMILES: Cc1cc(-n2c3ccncc3c3cnccc32)ccc1-c1ccc(-n2c3ccncc3c3cnccc32)cc1C ; c1ccc2c(c1)oc1c(-c3ccnc4c3oc3ccc(-n5c6ccncc6c6cnccc65)cc34)ccnc12 ; c1ccc2c(c1)c1ccccc1n2-c1ccc2oc3c(-n4c5ccccc5c5ccccc54)ccnc3c2c1 ; c1cnc2c3cnccc3n(-c3ccc4oc5ccc(-n6c7ccncc7c7cnccc76)cc5c4c3)c2c1]

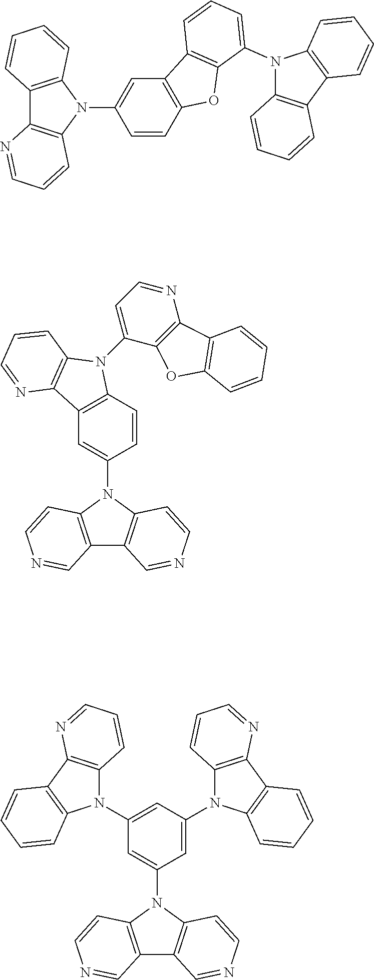 [SMILES: c1cc(-n2c3ccccc3c3ccccc32)c2oc3ccc(-n4c5ccccc5c5ncccc54)cc3c2c1 ; c1ccc2c(c1)oc1c(-n3c4ccc(-n5c6ccncc6c6cnccc65)cc4c4ncccc43)ccnc12 ; c1ccc2c(c1)c1ncccc1n2-c1cc(-n2c3ccncc3c3cnccc32)cc(-n2c3ccccc3c3ncccc32)c1]

### [1] Light Emitting Dopant

A light emitting dopant according to the present invention will be described.

As a light emitting dopant, it is preferable to employ: a fluorescence emitting dopant (also referred to as a fluorescent dopant and a fluorescent compound) and a phosphorescence emitting dopant (also referred to as a phosphorescent dopant and a phosphorescent emitting compound). In the present invention, it is preferable that at least one light emitting layer contains a phosphorescence emitting dopant.

A concentration of a light emitting compound in a light emitting layer may be arbitrarily decided based on the specific compound employed and the required conditions of the device. A concentration of a light emitting compound may be uniform in a thickness direction of the light emitting layer, or it may have any concentration distribution.

It may be used plural light emitting compounds of the present invention. It may be used a combination of fluorescent compounds each having a different structure, or a combination of a fluorescence emitting compound and a phosphorescence emitting compound. Any required emission color will be obtained by this.

Color of light emitted by an organic EL element or a compound of the present invention is specified as follows. In FIG. 4.16 on page 108 of “Shinpen Shikisai Kagaku Handbook (New Edition Color Science Handbook)” (edited by The Color Science Association of Japan, Tokyo Daigaku Shuppan Kai, 1985), values determined via Spectroradiometer CS-1000 (produced by Konica Minolta, Inc.) are applied to the CIE chromaticity coordinate, whereby the color is specified.

In the present invention, it is preferable that the organic EL element of the present invention exhibits white emission by incorporating one or plural light emitting layers containing plural light emitting dopants having different emission colors.

The combination of light emitting dopants producing white is not specifically limited. It may be cited, for example, combinations of: blue and orange; and blue, green and red.

It is preferable that “white” in the organic EL element of the present invention exhibits chromaticity in the CIE 1931 Color Specification System at 1,000 cd/m² in the region of x=0.39±0.09 and y=0.38±0.08, when measurement is done to 2-degree viewing angle front luminance via the aforesaid method.

### [2-1] Phosphorescence Emitting Dopant

A phosphorescence emitting dopant according to the present invention will be described. Hereafter, it may be called as “a phosphorescent dopant”. A phosphorescent dopant corresponds to “a phosphorescent metal complex” in the present invention.

The phosphorescence emitting dopant is a compound which is observed emission from an excited triplet state thereof. Specifically, it is a compound which emits phosphorescence at a room temperature (25° C.) and exhibits a phosphorescence quantum yield of at least 0.01 at 25° C. The phosphorescence quantum yield is preferably at least 0.1.

The phosphorescence quantum yield will be determined via a method described in page 398 of Bunko II of Dai 4 Han Jikken Kagaku Koza 7 (Spectroscopy II of 4th Edition Lecture of Experimental Chemistry 7) (1992, published by Maruzen Co. Ltd.). The phosphorescence quantum yield in a solution will be determined using appropriate solvents. However, it is only necessary for the phosphorescent dopant of the present invention to exhibit the above phosphorescence quantum yield (0.01 or more) using any of the appropriate solvents.

Two kinds of principles regarding emission of a phosphorescent dopant are cited. One is an energy transfer-type, wherein carriers recombine on a host compound on which the carriers are transferred to produce an excited state of the host compound, and then via transfer of this energy to a phosphorescent dopant, emission from the phosphorescence-emitting dopant is realized. The other is a carrier trap-type, wherein a phosphorescence-emitting dopant serves as a carrier trap and then carriers recombine on the phosphorescent dopant to generate emission from the phosphorescent dopant. In each case, the excited state energy level of the phosphorescent dopant is required to be lower than that of the host compound.

A phosphorescent dopant may be suitably selected and employed from the known materials used for a light emitting layer for an organic EL element.

Examples of a known phosphorescent dopant are compounds described in the following publications.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991, WO 2008/101842, WO 2003/040257, US 2006/835469, US 2006/0202194, US 2007/0087321, US 2005/0244673, Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290, WO 2002/015645, WO 2009/000673, US 2002/0034656, U.S. Pat. No. 7,332,232, US 2009/0108737, US 2009/0039776, U.S. Pat. Nos. 6,921,915, 6,687,266, US 2007/0190359, US 2006/0008670, US 2009/0165846, US 2008/0015355, U.S. Pat. Nos. 7,250,226, 7,396,598, US 2006/0263635, US 2003/0138657, US 2003/0152802, U.S. Pat. No. 7,090,928, Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714, WO 2006/009024, WO 2006/056418, WO 2005/019373, WO 2005/123873, WO 2005/123873, WO 2007/004380, WO 2006/082742, US 2006/0251923, US 2005/0260441, U.S. Pat. Nos. 7,393,599, 7,534,505, 7,445,855, US 2007/0190359, US 2008/0297033, U.S. Pat. No. 7,338,722, US 2002/0134984, and U.S. Pat. No. 7,279,704, US 2006/098120, US 2006/103874, WO 2005/076380, WO 2010/032663, WO 2008/140115, WO 2007/052431, WO 2011/134013, WO 2011/157339, WO 2010/086089, WO 2009/113646, WO 2012/020327, WO 2011/051404, WO 2011/004639, WO 2011/073149, JP-A 2012-069737, JP-A 2011-181303, JP-A 2009-114086, JP-A 2003-81988, JP-A 2002-302671 and JP-A 2002-363552.

Among them, preferable phosphorescence emitting dopants are organic metal complexes containing Ir as a center metal. More preferable are complexes containing at least one coordination mode selected from a metal-carbon bond, a metal-nitrogen bond, a metal-oxygen bond and a metal-sulfur bond.

### [2-2] Specific Examples of Preferred Phosphorescent Dopants

Here, specific examples of known phosphorescent dopants that may be used in the present invention will be listed, but the present invention is not limited thereto.

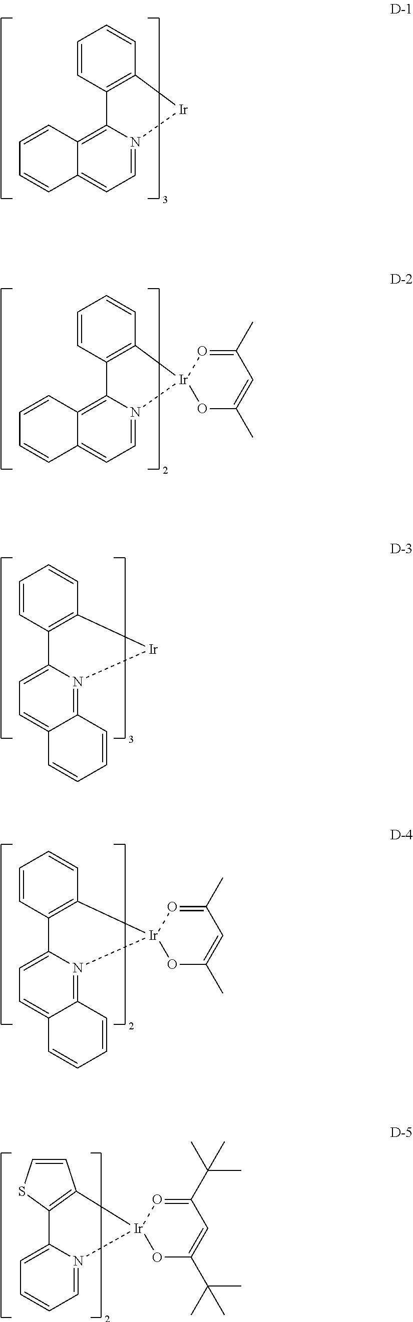

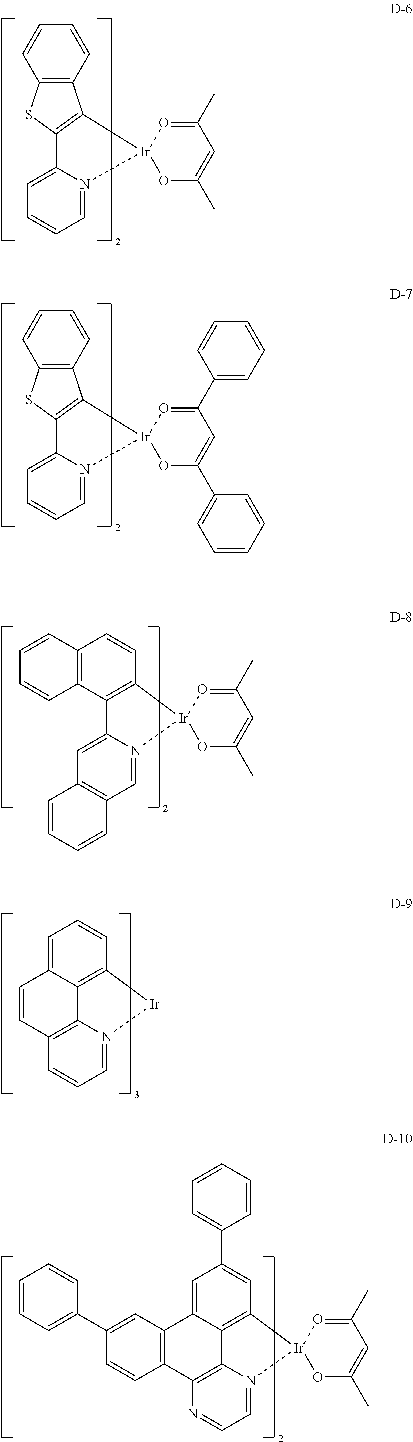

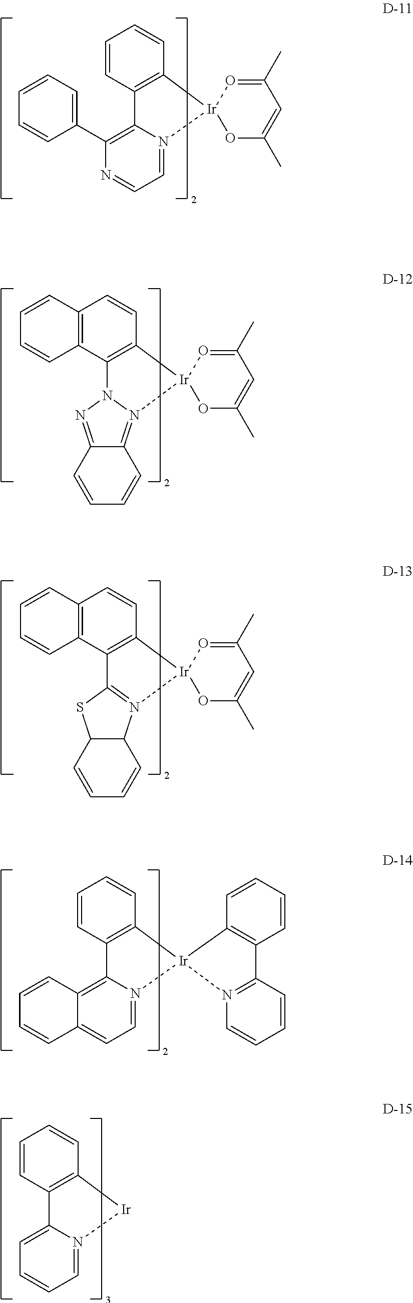

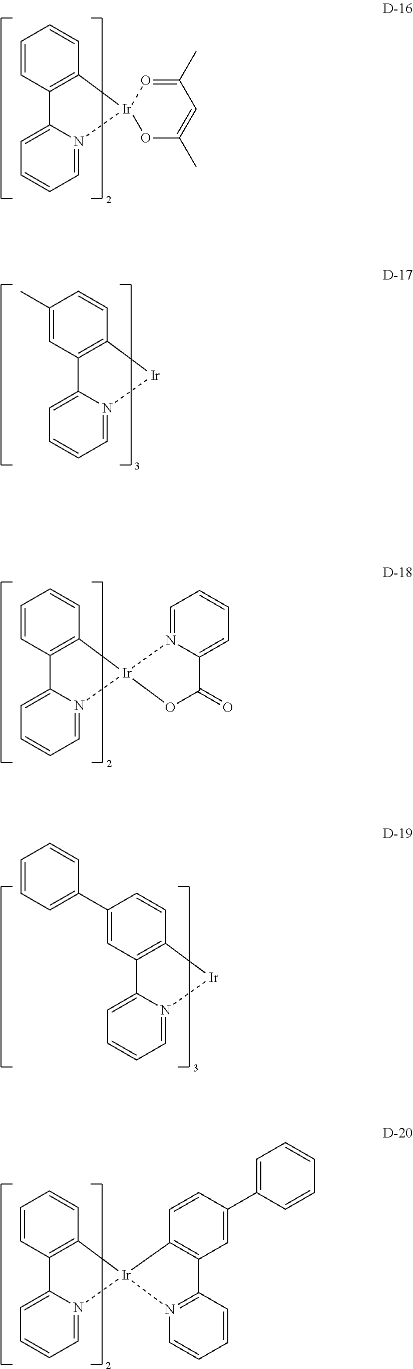

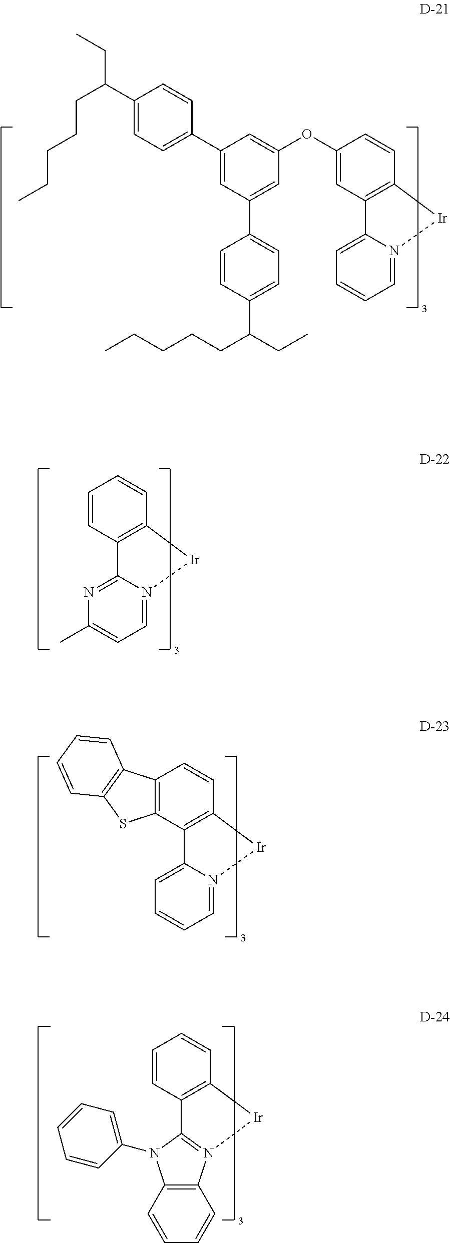

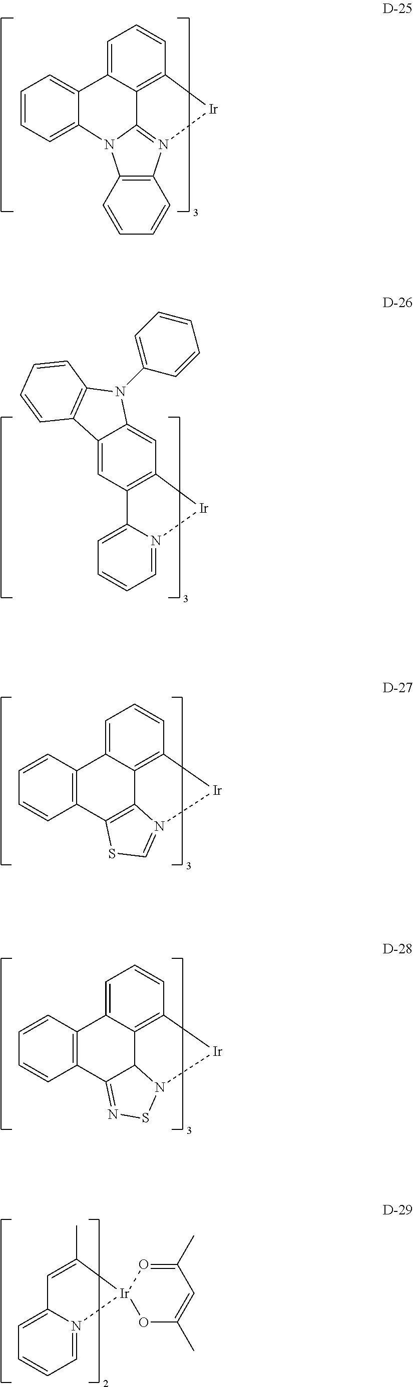

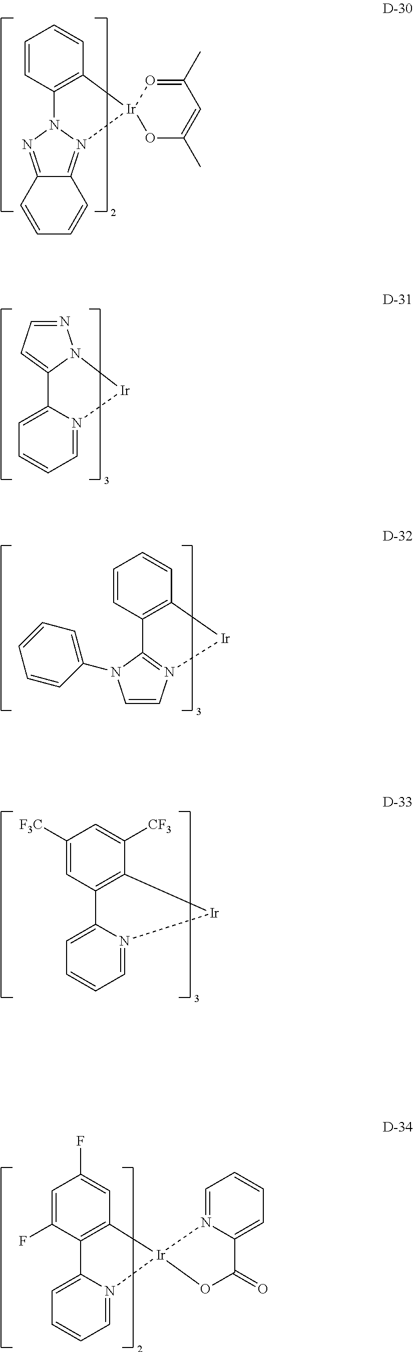

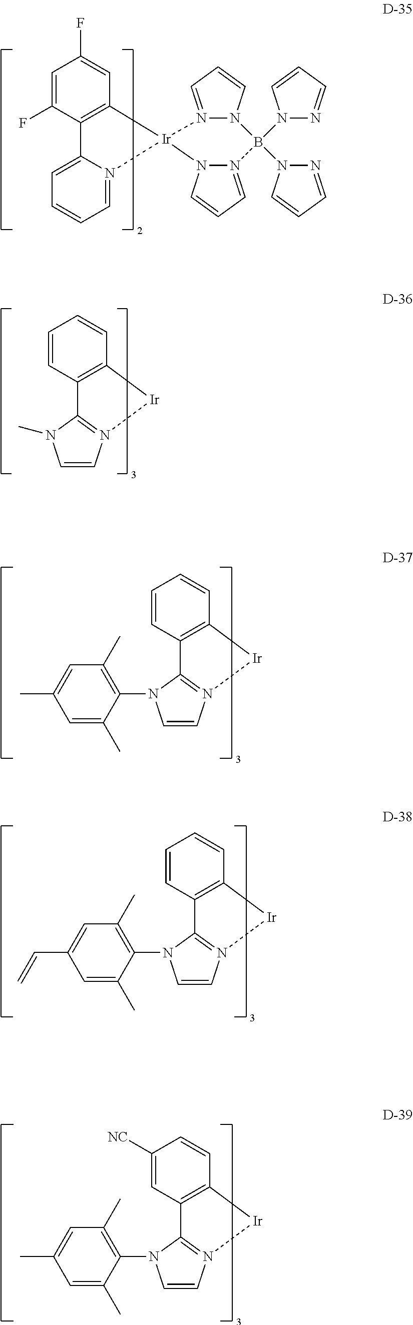

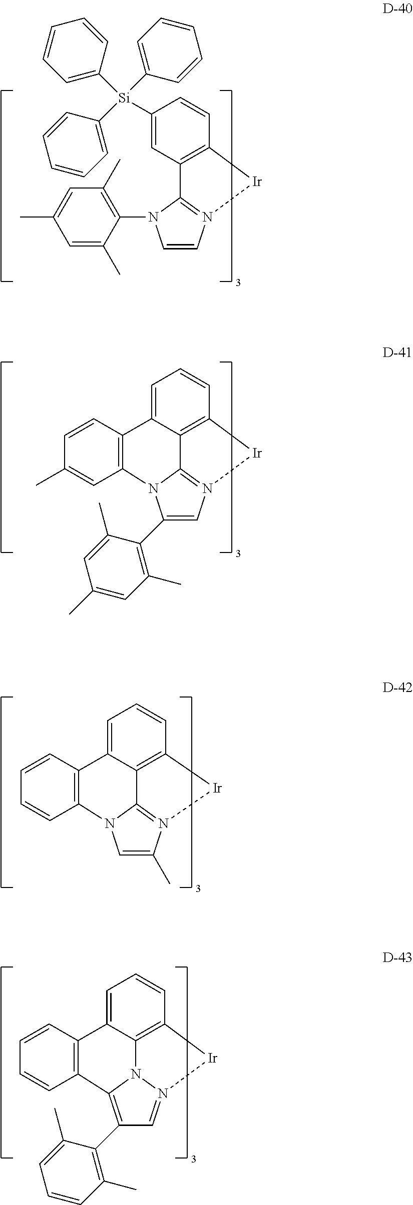

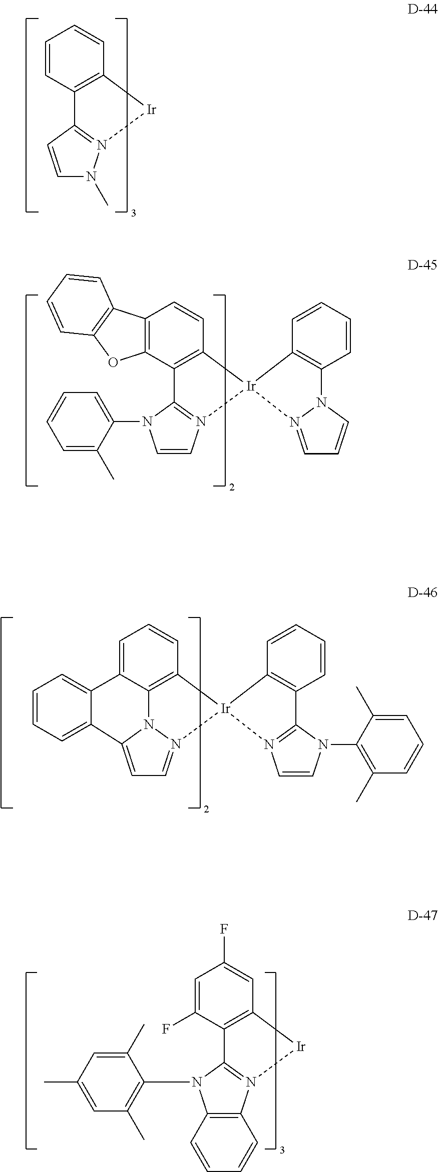

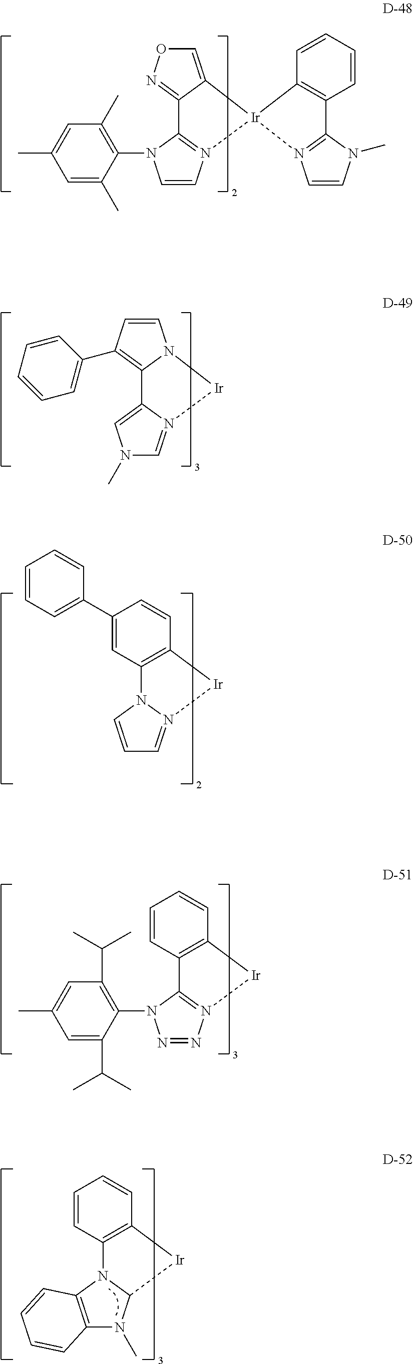

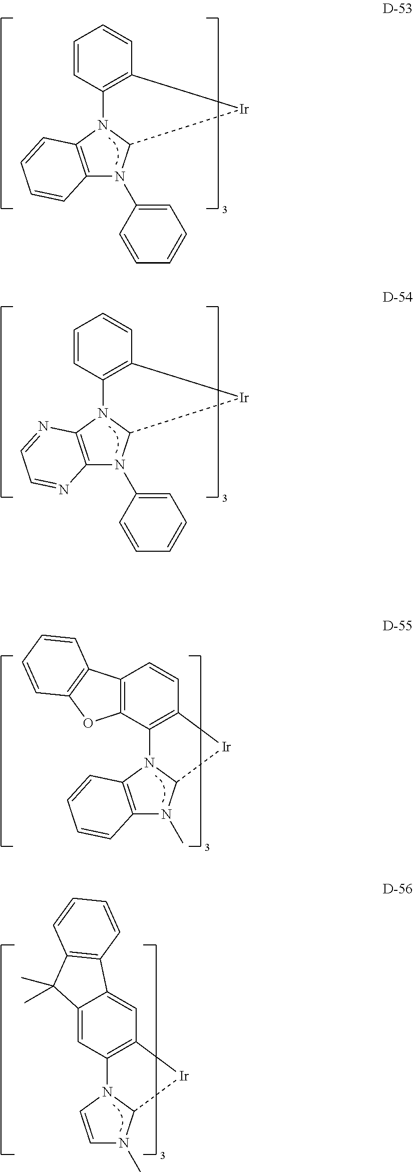

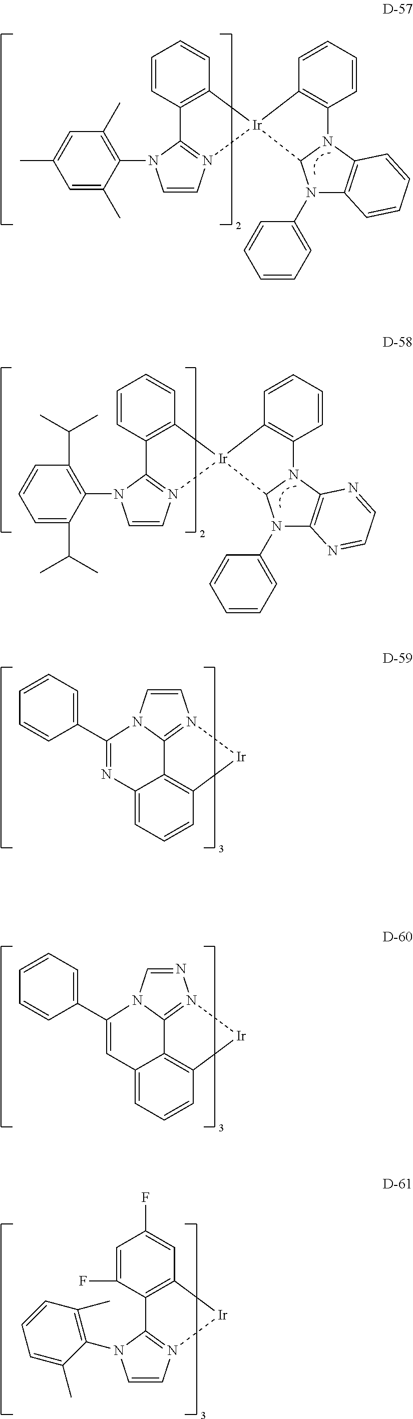

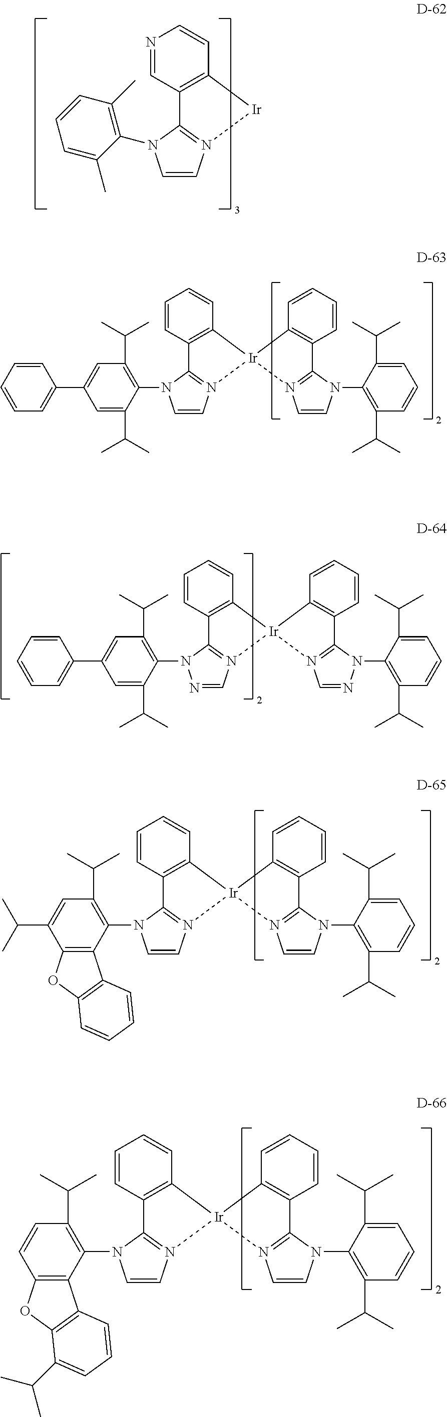

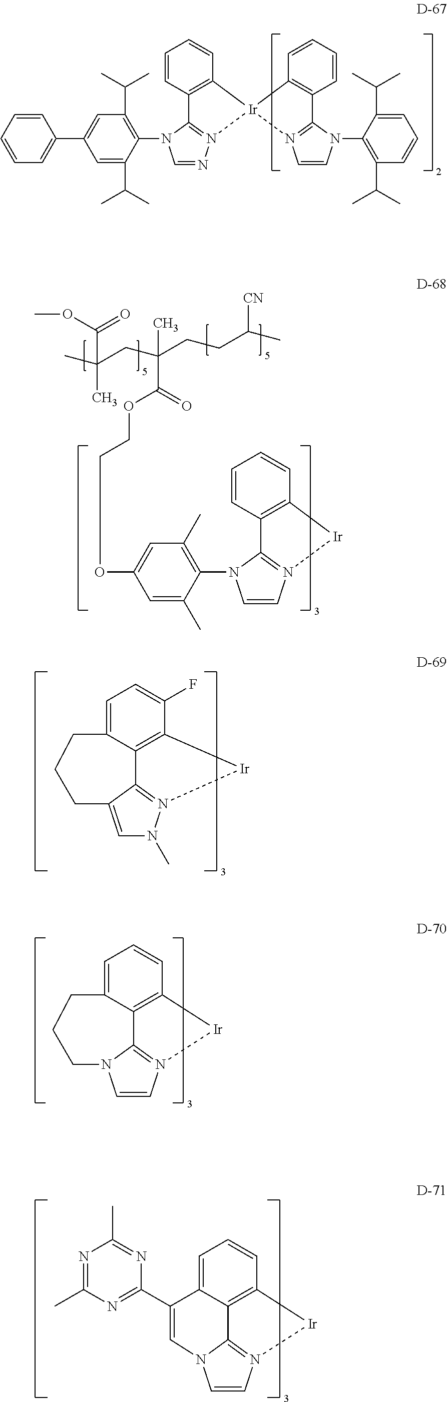

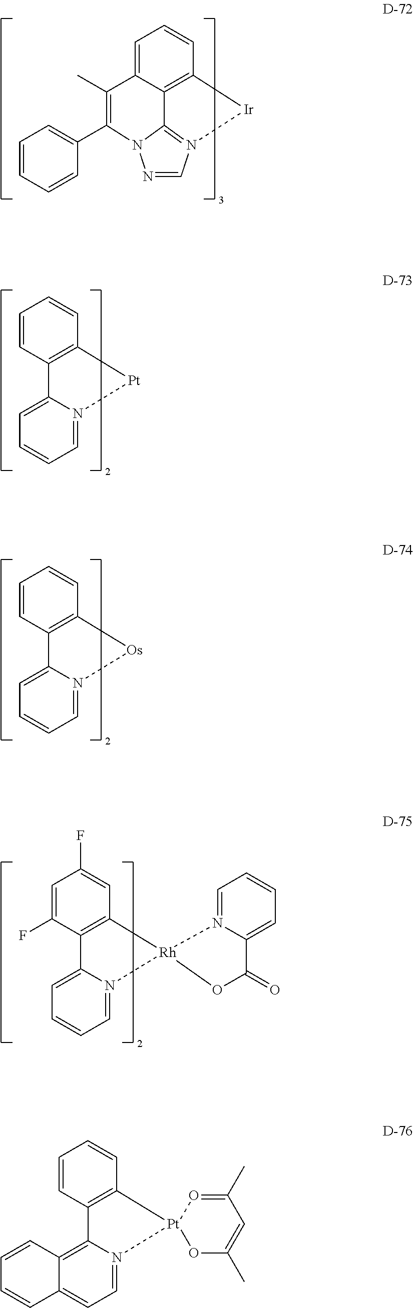

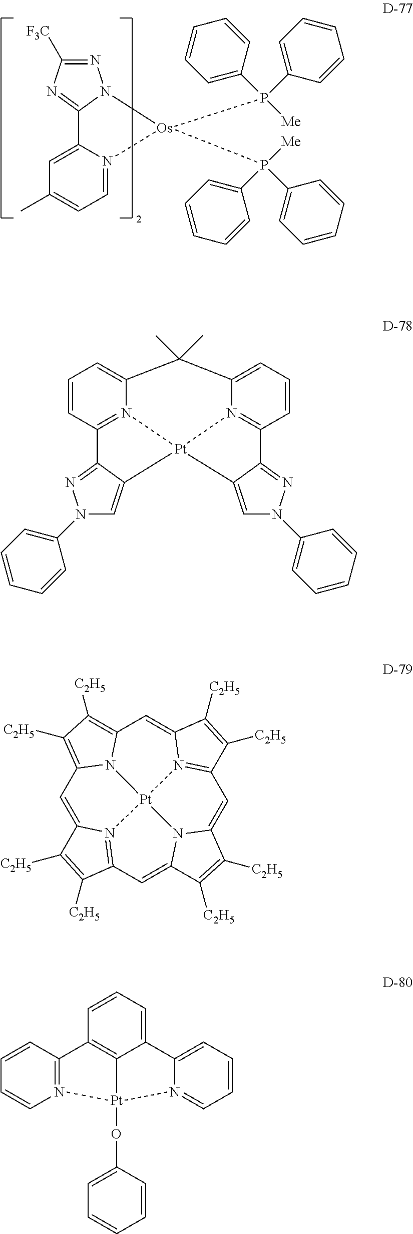

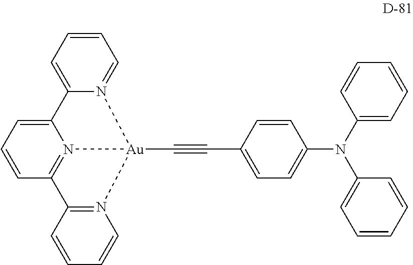

The lowest excitation triplet energy (T_{PC1}) of the phosphorescent dopant (phosphorescent metal complex) exemplified above is preferably in the range of 2.25 to 3.00 eV.

The reason for being 2.25 eV or more is that when the lowest excited triplet energy level (T_{PC1}) of the phosphorescent metal complex is 2.25 eV or less, the lowest excited singlet energy of the host compound can be made sufficiently lower than a carbon-carbon bond and a carbon-nitrogen bond generally used in organic compounds. Thereby it is difficult to obtain the effect of relaxing the excited state of the present invention.

The reason for being 3.00 eV or less is that when the lowest excited triplet energy level (T_{PC1}) of the phosphorescent metal complex is 3.00 eV or more, the lowest excited triplet energy level of the host compound is required to be 3.00 eV or more. The lowest excited triplet energy level exceeds 3.00 eV, which is the bond cleavage energy of the carbon-nitrogen bond generally used in phosphorescent metal complexes or host compounds, and bond cleavage occurs and it is difficult to obtain the effect of the present invention.

### [2-3] Fluorescent Dopant

A fluorescence emitting dopant according to the present invention will be described. Hereafter, it may be called as “a fluorescent dopant”.

A fluorescent dopant according to the present invention is a compound which is observed emission from an excited singlet state thereof. The compound is not limited as long as emission from an excited singlet state is observed.

Examples of a fluorescent dopant usable in the present invention are compounds such as: an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarylium derivative, an oxobenzanthracene derivative, a fluorescein derivative, a rhodamine derivative, a pyrylium derivative, a perylene derivative, a polythiophene derivative, and a rare earth complex compound.

In recent years, it was developed a light emitting dopant utilizing delayed fluorescence. This dopant may be used.

Specific examples of a light emitting dopant utilizing delayed fluorescence are compounds described in: WO 2011/156793, JP-A 2011-213643, and JP-A 2010-93181. However, the present invention is not limited to them.

### «Electron Transport Layer»

In the present invention, an electron transport layer is composed of a material having a function of transferring an electron. It is only required to have a function of transporting an injected electron from a cathode to a light emitting layer.

A total layer thickness of the electron transport layer is not specifically limited, however, it is generally in the range of 2 nm to 5 μm, and preferably, it is in the range of 2 to 500 nm, and more preferably, it is in the range of 5 to 200 nm.

In an organic EL element, it is known that there occurs interference between the light directly taken from the light emitting layer and the light reflected at the electrode located at the opposite side of the electrode from which the light is taken out at the moment of taking out the light which is produced in the light emitting layer. When the light is reflected at the cathode, it is possible to use effectively this interference effect by suitably adjusting the total thickness of the electron transport layer in the range of 2 nm to 5 nm.

On the other hand, the voltage will be increased when the layer thickness of the electron transport layer is made thick. Therefore, especially when the layer thickness is large, it is preferable that the electron mobility in the electron transport layer is 1×10⁻⁵ cm²/V·s or more.

As a material used for an electron transport layer (hereafter, it is called as an electron transport material), it is only required to have either a property of ejection or transport of electrons, or a barrier to holes. Any of the conventionally known compounds may be selected and they may be employed.

Cited examples thereof include: a nitrogen-containing aromatic heterocyclic derivative (a carbazole derivative, an azacarbazole derivative (a compound in which one or more carbon atoms constituting the carbazole ring are substitute with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative); a dibenzofuran derivative, a dibenzothiophene derivative, a silole derivative; and an aromatic hydrocarbon ring derivative (a naphthalene derivative, an anthracene derivative and a triphenylene derivative).

Further, metal complexes having a ligand of a 8-quinolinol structure or dibnenzoquinolinol structure such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, may be also utilized as an electron transport material.

Further, a metal-free or metal phthalocyanine, or a compound whose terminal is substituted by an alkyl group or a sulfonic acid group, may be preferably utilized as an electron transport material. A distyryl pyrazine derivative, which is exemplified as a material for a light emitting layer, may be used as an electron transport material. Further, in the same manner as used for a hole injection layer and a hole transport layer, an inorganic semiconductor such as an n-type Si and an n-type SiC may be also utilized as an electron transport material.

It may be used a polymer material which is introduced these compounds in the polymer side-chain or a polymer main chain.

In an electron transport layer according to the present invention, it is possible to employ an electron transport layer of a higher n property (electron rich) which is doped with impurities as a guest material. As examples of a dope material, listed are those described in each of JP-A Nos. 4-297076, 10-270172, 2000-196140, 2001-102175, as well as in J. Appl. Phys., 95, 5773 (2004).

Although the present invention is not limited thereto, preferable examples of a known electron transport material used in an organic EL element of the present invention are compounds described in the following publications.

U.S. Pat. Nos. 6,528,187, 7,230,107, US 2005/0025993, US 2004/0036077, US 2009/0115316, US 2009/0101870, US 2009/0179554, WO 2003/060956, WO 2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, US 2009/030202, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, JP-A 2010-251675, JP-A 2009-209133, JP-A 2009-124114, JP-A 2008-277810, JP-A 2006-156445, JP-A 2005-340122, JP-A 2003-45662, JP-A 2003-31367, JP-A 2003-282270, and WO 2012/115034.

Examples of a preferable electron transport material are: a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

Specific preferred examples of the compound used for the electron transport layer of the organic EL element of the present invention are listed below, but the present invention is not limited thereto.

An electron transport material may be used singly, or may be used in combination of plural kinds of compounds.

### «Hole Blocking Layer»

A hole blocking layer is a layer provided with a function of an electron transport layer in a broad meaning. Preferably, it contains a material having a function of transporting an electron, and having very small ability of transporting a hole. It will improve the recombination probability of an electron and a hole by blocking a hole while transporting an electron.

Further, a composition of an electron transport layer described above may be appropriately utilized as a hole blocking layer of the present invention when needed.

A hole blocking layer placed in an organic EL element of the present invention is preferably arranged at a location in the light emitting layer adjacent to the cathode side.

A thickness of a hole blocking layer according to the present invention is preferably in the range of 3 to 100 nm, and more preferably, in the range of 5 to 30 nm.

With respect to a material used for a hole blocking layer, the material used in the aforesaid electron transport layer is suitably used, and further, the material used as the aforesaid host compound is also suitably used for a hole blocking layer.

### «Electron Injection Layer»

An electron injection layer (it is also called as “a cathode buffer layer”) according to the present invention is a layer which is arranged between a cathode and a light emitting layer to decrease an operating voltage and to improve an emission luminance. An example of an electron injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

In the present invention, an electron injection layer is provided according to necessity, and as described above, it is placed between a cathode and a light emitting layer, or between a cathode and an electron transport layer.

An electron injection layer is preferably a very thin layer. The layer thickness thereof is preferably in the range of 0.1 to 5 nm depending on the materials used.

An election injection layer is detailed in JP-A Nos. 6-325871, 9-17574, and 10-74586. Examples of a material preferably used in an election injection layer include: a metal such as strontium and aluminum; an alkaline metal compound such as lithium fluoride, sodium fluoride, or potassium fluoride; an alkaline earth metal compound such as magnesium fluoride; a metal oxide such as aluminum oxide; and a metal complex such as lithium 8-hydroxyquinolate (Liq). It is possible to use the aforesaid electron transport materials.

The above-described materials used may be used singly, or plural kinds may be used together in an election injection layer.

### «Hole Transport Layer»

In the present invention, a hole transport layer contains a material having a function of transporting a hole. A hole transport layer is only required to have a function of transporting a hole injected from an anode to a light emitting layer.

The total layer thickness of a hole transport layer of the present invention is not specifically limited, however, it is generally in the range of 5 nm to 5 nm, preferably in the range of 2 to 500 nm, and more preferably in the range of 5 nm to 200 nm.

A material used in a hole transport layer (hereafter, it is called as a hole transport material) is only required to have any one of properties of injecting and transporting a hole, and a barrier property to an electron. A hole transport material may be suitably selected from the conventionally known compounds.

Examples of a hole transport material include:

a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative of anthracene or naphthalene, a fluorene derivative, a fluorenone derivative, polyvinyl carbazole, a polymer or an oligomer containing an aromatic amine in a side chain or a main chain, polysilane, and a conductive polymer or an oligomer (e.g., PEDOT:PSS, an aniline type copolymer, polyaniline and polythiophene).

Examples of a triarylamine derivative include: a benzidine type represented by α-NPD, a star burst type represented by MTDATA, a compound having fluorenone or anthracene in a triarylamine bonding core.

A hexaazatriphenylene derivative described in JP-A Nos. 2003-519432 and 2006-135145 may be also used as a hole transport material.

In addition, it is possible to employ an electron transport layer of a higher p property which is doped with impurities. As its example, listed are those described in each of JP-A Nos. 4-297076, 2000-196140, and 2001-102175, as well as in J. Appl. Phys., 95, 5773 (2004).

Further, it is possible to employ so-called p-type hole transport materials, and inorganic compounds such as p-type Si and p-type SiC, as described in JP-A No. 11-251067, and J. Huang et al. reference (Applied Physics Letters 80 (2002), p. 139). Moreover, an orthometal compounds having Ir or Pt as a center metal represented by Ir(ppy)₃ are also preferably used.

Although the above-described compounds may be used as a hole transport material, preferably used are: a triarylamine derivative, a carbazole derivative, an indolocarbazole derivative, an azatriphenylene derivative, an organic metal complex, a polymer or an oligomer incorporated an aromatic amine in a main chain or in a side chain.

Specific examples of a known hole transport material used in an organic EL element of the present invention are compounds in the aforesaid publications and in the following publications. However, the present invention is not limited to them.

Examples of a publication are: Appl. Phys. Lett. 69, 2160(1996), J. Lumin. 72-74, 985(1997), Appl. Phys. Lett. 78, 673(2001), Appl. Phys. Lett. 90, 183503(2007), Appl. Phys. Lett. 51, 913(1987), Synth. Met. 87, 171(1997), Synth. Met. 91, 209(1997), Synth. Met. 111, 421(2000), SID Symposium Digest, 37, 923(2006), J. Mater. Chem. 3, 319(1993), Adv. Mater. 6, 677(1994), Chem. Mater. 15, 3148(2003), US 2003/0162053, US 2002/0158242, US 2006/0240279, US 2008/0220265, U.S. Pat. No. 5,061,569, WO 2007/002683, WO 2009/018009, EP 650955, US 2008/0124572, US 2007/0278938, US 2008/0106190, US 2008/0018221, WO 2012/115034, JP-A 2003-519432, JP-A 2006-135145, and U.S. patent application Ser. No. 13/585,981.

A hole transport material may be used singly or may be used in combination of plural kinds of compounds.

### «Electron Blocking Layer»

An electron blocking layer is a layer provided with a function of a hole transport layer in a broad meaning. Preferably, it contains a material having a function of transporting a hole, and having very small ability of transporting an electron. It will improve the recombination probability of an electron and a hole by blocking an electron while transporting a hole.

Further, a composition of a hole transport layer described above may be appropriately utilized as an electron blocking layer of an organic EL element when needed.

An electron blocking layer placed in an organic EL element is preferably arranged at a location in the light emitting layer adjacent to the anode side.

A thickness of an electron blocking layer is preferably in the range of 3 to 100 nm, and more preferably, it is in the range of 5 to 30 nm.

With respect to a material used for an electron blocking layer, the material used in the aforesaid hole transport layer is suitably used, and further, the material used as the aforesaid host compound is also suitably used for an electron blocking layer.

### «Hole Injection Layer»

A hole injection layer (it is also called as “an anode buffer layer”) is a layer which is arranged between an anode and a light emitting layer to decrease an operating voltage and to improve an emission luminance. An example of a hole injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

A hole injection layer of the present invention is provided according to necessity, and as described above, it is placed between an anode and a light emitting layer, or between an anode and a hole transport layer.

A hole injection layer is also detailed in JP-A Nos. 9-45479, 9-260062 and 8-288069. As materials used in the hole injection layer, it is cited the same materials used in the aforesaid hole transport layer.

Among them, preferable materials are: a phthalocyanine derivative represented by copper phthalocyanine; a hexaazatriphenylene derivative described in JP-A Nos. 2003-519432 and 2006-135145; a metal oxide represented by vanadium oxide; a conductive polymer such as amorphous carbon, polyaniline (or called as emeraldine) and polythiophene; an orthometalated complex represented by tris(2-phenylpyridine) iridium complex; and a triarylamine derivative.

The above-described materials used in a hole injection layer may be used singly or plural kinds may be co-used.

### «Other Additive»

The above-described organic layer of the present invention may further contain other ingredient.

Examples of an ingredient are: halogen elements such as bromine, iodine and chlorine, and a halide compound; and a compound, a complex and a salt of an alkali metal, an alkaline earth metal and a transition metal such as Pd, Ca and Na.

Although a content of an ingredient may be arbitrarily decided, preferably, it is 1,000 ppm or less based on the total mass of the layer containing the ingredient, more preferably, it is 500 ppm or less, and still more preferably, it is 50 ppm or less.

In order to improve a transporting property of an electron or a hole, or to facilitate energy transport of an exciton, the content of the ingredient is not necessarily within these range, and other range of content may be used.

### «Forming Method of Organic Layers»

Forming methods of organic layers according to the present invention (hole injection layer, hole transport layer, light emitting layer, hole blocking layer, electron transport layer, and electron injection layer) will be described.

Forming methods of organic layers according to the present invention are not specifically limited. They may be formed by using a known method such as a vacuum vapor deposition method and a wet method (it may be called as a wet process).

Examples of a wet process include: a spin coating method, a cast method, an inkjet method, a printing method, a die coating method, a blade coating method, a roll coating method, a spray coating method, a curtain coating method, and a LB method (Langmuir Blodgett method). From the viewpoint of getting a uniform thin layer with high productivity, preferable are method highly appropriate to a roll-to-roll method such as a die coating method, a roll coating method, an inkjet method, and a spray coating method.

Examples of a liquid medium for dissolving or to dispersing a material used in an organic EL element according to the present invention include: ketones such as methyl ethyl ketone and cyclohexanone; aliphatic esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; organic solvents such as DMF and DMSO.

These will be dispersed with a dispersion method such as an ultrasonic dispersion method, a high shearing dispersion method and a media dispersion method.

A different film forming method may be applied to every organic layer. When a vapor deposition method is adopted for forming each layer, the vapor deposition conditions may be changed depending on the compounds used. Generally, the following ranges are suitably selected for the conditions, heating temperature of boat: 50 to 450° C., level of vacuum: 1×10⁻⁶ to 1×10⁻² Pa, vapor deposition rate: 0.01 to 50 nm/sec, temperature of substrate: −50 to 300° C., and layer thickness: 0.1 nm to 5 nm, preferably 5 to 200 nm.

Formation of organic layers of the present invention is preferably continuously carried out from a hole injection layer to a cathode with one time vacuuming. It may be taken out on the way, and a different layer forming method may be employed. In that case, the operation is preferably done under a dry inert gas atmosphere.

### «Anode»

As an anode of an organic EL element, a metal having a large work function (4 eV or more, preferably, 4.5 eV or more), an alloy, and a conductive compound and a mixture thereof are utilized as an electrode substance.

Specific examples of an electrode substance are: metals such as Au, and an alloy thereof; transparent conductive materials such as CuI, indium tin oxide (ITO), SnO₂, and ZnO. Further, a material such as IDIXO (In₂O₃—ZnO), which may form an amorphous and transparent electrode, may also be used.

An anode may be formed into a thin film by using these electrode substances with a method such as a vapor deposition method or a sputtering method; followed by making a pattern of a desired form by a photolithography method. Otherwise, when the requirement of pattern precision is not so severe (about 100 μm or more), a pattern may be formed through a mask of a desired form at the time of layer formation with a vapor deposition method or a sputtering method using the above-described material.

Alternatively, when a coatable substance such as an organic conductive compound is employed, it is possible to employ a wet film forming method such as a printing method or a coating method. When emitted light is taken out from the anode, the transmittance is preferably set to be 10% or more. A sheet resistance of the anode is preferably a few hundred Ω/sq or less.

Further, although a layer thickness of the anode depends on a material, it is generally selected in the range of 10 nm to 1 nm, and preferably in the range of 10 to 200 nm.

### «Cathode»

As a cathode, a metal having a small work function (4 eV or less) (it is called as an electron injective metal), an alloy, a conductive compound and a mixture thereof are utilized as an electrode substance. Specific examples of the aforesaid electrode substance includes: sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal. Among them, with respect to an electron injection property and durability against oxidation, preferable are: a mixture of election injecting metal with a second metal which is stable metal having a work function larger than the electron injecting metal. Examples thereof are: a magnesium/silver mixture, a magnesium/aluminum mixture, a magnesium/indium mixture, an aluminum/aluminum oxide (Al₂O₃) mixture, a lithium/aluminum mixture and aluminum.

A cathode may be made by using these electrode substances with a method such as a vapor deposition method or a sputtering method to form a thin film. A sheet resistance of the cathode is preferably a few hundred Ω/sq or less. A layer thickness of the cathode is generally selected in the range of 10 nm to 5 nm, and preferably in the range of 50 to 200 nm.

In order to transmit emitted light, it is preferable that one of an anode and a cathode of an organic EL element is transparent or translucent for achieving an improved luminescence.

Further, after forming a layer of the aforesaid metal having a thickness of 1 to 20 nm on the cathode, it is possible to prepare a transparent or translucent cathode by providing with a conductive transparent material described in the description for the anode thereon. By applying this process, it is possible to produce an element in which both of an anode and a cathode are transparent.

### «Support Substrate»

A support substrate which may be used for an organic EL element of the present invention is not specifically limited with respect to types such as glass and plastics. Hereafter, the support substrate may be also called as substrate body, substrate, substrate substance, or support. They may be transparent or opaque. However, a transparent support substrate is preferable when the emitting light is taken from the side of the support substrate. Support substrates preferably utilized includes such as glass, quartz and transparent resin film. A specifically preferable support substrate is a resin film capable of providing an organic EL element with a flexible property.

Examples of a resin film include: polyesters such as polyethylene terephthalate (PET) and polyethylene naphthalate (PEN), polyethylene, polypropylene, cellophane, cellulose esters and their derivatives such as cellulose diacetate, cellulose triacetate (TAC), cellulose acetate butyrate, cellulose acetate propionate (CAP), cellulose acetate phthalate, and cellulose nitrate, polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, fluororesin, Nylon, polymethyl methacrylate, acrylic resin, polyallylates and cycloolefin resins such as ARTON (trade name, made by JSR Co. Ltd.) and APEL (trade name, made by Mitsui Chemicals, Inc.).

On the surface of a resin film, it may be formed a film incorporating an inorganic or an organic compound or a hybrid film incorporating both compounds. Barrier films are preferred with a water vapor permeability of 0.01 g/(m²·24 h) or less (at 25±0.5° C., and 90±2% RH) determined based on JIS K 7129-1992. Further, high barrier films are preferred to have an oxygen permeability of 1×10⁻³ ml/(m²·24 h·atm) or less determined based on JIS K 7126-1987, and a water vapor permeability1 of 1×10⁻⁵ g/(m²·24 h) or less.

As materials that form a barrier film, employed may be those which retard penetration of moisture and oxygen, which deteriorate the element. For example, it is possible to employ silicon oxide, silicon dioxide, and silicon nitride. Further, in order to improve the brittleness of the aforesaid film, it is more preferable to achieve a laminated layer structure of inorganic layers and organic layers. The laminating order of the inorganic layer and the organic layer is not particularly limited, but it is preferable that both are alternatively laminated a plurality of times.

Barrier film forming methods are not particularly limited. Examples of employable methods include a vacuum deposition method, a sputtering method, a reactive sputtering method, a molecular beam epitaxy method, a cluster ion beam method, an ion plating method, a plasma polymerization method, a plasma CVD method, a laser CVD method, a thermal CVD method, and a coating method. Of these, specifically preferred is a method employing an atmospheric pressure plasma polymerization method, described in JP-A No. 2004-68143.

Examples of an opaque support substrate include metal plates such aluminum or stainless steel films, opaque resin substrates, and ceramic substrates.

An external quantum efficiency of light emitted by the organic EL element of the present invention is preferably 1% or more at a room temperature, but is more preferably 5% or more.

External quantum efficiency (%)=(Number of photons emitted by the organic EL element to the exterior/Number of electrons fed to organic EL element)×100.

Further, it may be used simultaneously a color hue improving filter such as a color filter, or it may be used simultaneously a color conversion filter which convert emitted light color from the organic EL element to multicolor by employing fluorescent materials.

### «Sealing»

As sealing means employed in the present invention, listed may be, for example, a method in which sealing members, electrodes, and a supporting substrate are subjected to adhesion via adhesives. The sealing members may be arranged to cover the display region of an organic EL element, and may be a concave plate or a flat plate. Neither transparency nor electrical insulation is limited.

Specifically listed are glass plates, polymer plate-films, metal plate-films. Specifically, it is possible to list, as glass plates, soda-lime glass, barium-strontium containing glass, lead glass, aluminosilicate glass, borosilicate glass, barium borosilicate glass, and quartz. Further, listed as polymer plates may be polycarbonate, acryl, polyethylene terephthalate, polyether sulfide, and polysulfone. As a metal plate, listed are those composed of at least one metal selected from the group consisting of stainless steel, iron, copper, aluminum magnesium, nickel, zinc, chromium, titanium, molybdenum, silicon, germanium, and tantalum, or alloys thereof.

In the present invention, since it is possible to achieve a thin organic EL element, it is preferable to employ a polymer film or a metal film. Further, it is preferable that the polymer film has an oxygen permeability of 1×10⁻³ mL/(m²·24 h) or less determined by the method based on JIS K 7126-1987, and a water vapor permeability of 1×10⁻³ g/(m²·24 h) or less (at 25±0.5° C., and 90±2% RH) determined by the method based on JIS K 7129-1992.

Conversion of the sealing member into concave is carried out by employing a sand blast process or a chemical etching process.

In practice, as adhesives, listed may be photo-curing and heat-curing types having a reactive vinyl group of acrylic acid based oligomers and methacrylic acid, as well as moisture curing types such as 2-cyanoacrylates. Further listed may be thermal and chemical curing types (mixtures of two liquids) such as epoxy based ones. Still further listed may be hot-melt type polyamides, polyesters, and polyolefins. Yet further listed may be cationically curable type UV curable epoxy resin adhesives.

In addition, since an organic EL element is occasionally deteriorated via a thermal process, preferred are those which enable adhesion and curing between a room temperature and 80° C. Further, desiccating agents may be dispersed into the aforesaid adhesives. Adhesives may be applied onto sealing portions via a commercial dispenser or printed on the same in the same manner as screen printing.

Further, it is appropriate that on the outside of the aforesaid electrode which interposes the organic layer and faces the support substrate, the aforesaid electrode and organic layer are covered, and in the form of contact with the support substrate, inorganic and organic material layers are formed as a sealing film. In this case, as materials that form the aforesaid film may be those which exhibit functions to retard penetration of moisture or oxygen which results in deterioration of the element. For example, it is possible to employ silicon oxide, silicon dioxide, and silicon nitride.

Still further, in order to improve brittleness of the aforesaid film, it is preferable that a laminated layer structure is formed, which is composed of these inorganic layers and layers composed of organic materials. Methods to form these films are not particularly limited. It is possible to employ, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a thermal CVD method, and a coating method.

It is preferable to inject a gas phase and a liquid phase material of inert gases such as nitrogen or argon, and inactive liquids such as fluorinated hydrocarbon or silicone oil into the space formed between the sealing member and the display region of the organic EL element. Further, it is possible to form vacuum in the space. Still further, it is possible to enclose hygroscopic compounds in the interior of the space.

Examples of a hygroscopic compound include: metal oxides (for example, sodium oxide, potassium oxide, calcium oxide, barium oxide, magnesium oxide, and aluminum oxide); sulfates (for example, sodium sulfate, calcium sulfate, magnesium sulfate, and cobalt sulfate); metal halides (for example, calcium chloride, magnesium chloride, cesium fluoride, tantalum fluoride, cerium bromide, magnesium bromide, barium iodide, and magnesium iodide); perchlorates (for example, barium perchlorate and magnesium perchlorate). In sulfates, metal halides, and perchlorates, suitably employed are anhydrides. For sulfate salts, metal halides and perchlorates, suitably used are anhydrous salts.

### «Protective Film and Protective Plate»

On the aforesaid sealing film which interposes the organic layer and faces the support substrate or on the outside of the aforesaid sealing film, a protective or a protective plate may be arranged to enhance the mechanical strength of the element. Specifically, when sealing is achieved via the aforesaid sealing film, the resulting mechanical strength is not always high enough, therefore it is preferable to arrange the protective film or the protective plate described above. Usable materials for these include glass plates, polymer plate-films, and metal plate-films which are similar to those employed for the aforesaid sealing. However, from the viewpoint of reducing weight and thickness, it is preferable to employ a polymer film.

### «Improving Method of Light Extraction»

It is generally known that an organic EL element emits light in the interior of the layer exhibiting the refractive index (being about 1.6 to 2.1) which is greater than that of air, whereby only about 15% to 20% of light generated in the light emitting layer is extracted. This is due to the fact that light incident to an interface (being an interlace of a transparent substrate to air) at an angle of Θ which is at least critical angle is not extracted to the exterior of the element due to the resulting total reflection, or light is totally reflected between the transparent electrode or the light emitting layer and the transparent substrate, and light is guided via the transparent electrode or the light emitting layer, whereby light escapes in the direction of the element side surface.

Means to enhance the efficiency of the aforesaid light extraction include, for example: a method in which roughness is formed on the surface of a transparent substrate, whereby total reflection is minimized at the interface of the transparent substrate to air (U.S. Pat. No. 4,774,435), a method in which efficiency is enhanced in such a manner that a substrate results in light collection (JP-A NO. 63-314795), a method in which a reflection surface is formed on the side of the element (JP-A No. 1-220394), a method in which a flat layer of a middle refractive index is introduced between the substrate and the light emitting body and an antireflection film is formed (JP-A No. 62-172691), a method in which a flat layer of a refractive index which is equal to or less than the substrate is introduced between the substrate and the light emitting body (JP-A No. 2001-202827), and a method in which a diffraction grating is formed between the substrate and any of the layers such as the transparent electrode layer or the light emitting layer (including between the substrate and the outside) (JP-A No. 11-283751).

In the present invention, it is possible to employ these methods while combined with the organic EL element of the present invention. Of these, it is possible to appropriately employ the method in which a flat layer of a refractive index which is equal to or less than the substrate is introduced between the substrate and the light emitting body and the method in which a diffraction grating is formed between any layers of a substrate, and a transparent electrode layer and a light emitting layer (including between the substrate and the outside space).

By combining these means, the present invention enables the production of elements which exhibit higher luminance or excel in durability.

When a low refractive index medium having a thickness, greater than the wavelength of light is formed between the transparent electrode and the transparent substrate, the extraction efficiency of light emitted from the transparent electrode to the exterior increases as the refractive index of the medium decreases.

As materials of the low refractive index layer, listed are, for example, aerogel, porous silica, magnesium fluoride, and fluorine based polymers. Since the refractive index of the transparent substrate is commonly about 1.5 to 1.7, the refractive index of the low refractive index layer is preferably approximately 1.5 or less. More preferably, it is 1.35 or less.

Further, thickness of the low refractive index medium is preferably at least two times of the wavelength in the medium. The reason is that, when the thickness of the low refractive index medium reaches nearly the wavelength of light so that electromagnetic waves escaped via evanescent enter into the substrate, effects of the low refractive index layer are lowered.

The method in which the interface which results in total reflection or a diffraction grating is introduced in any of the media is characterized in that light extraction efficiency is significantly enhanced. The above method works as follows. By utilizing properties of the diffraction grating capable of changing the light direction to the specific direction different from diffraction via so-called Bragg diffraction such as primary diffraction or secondary diffraction of the diffraction grating, of light emitted from the light entitling layer, light, which is not emitted to the exterior due to total reflection between layers, is diffracted via introduction of a diffraction grating between any layers or in a medium (in the transparent substrate and the transparent electrode) so that light is extracted to the exterior.

It is preferable that the introduced diffraction grating exhibits a two-dimensional periodic refractive index. The reason is as follows. Since light emitted in the light emitting layer is randomly generated to all directions, in a common one-dimensional diffraction grating exhibiting a periodic refractive index distribution only in a certain direction, light which travels to the specific direction is only diffracted, whereby light extraction efficiency is not sufficiently enhanced.

However, by changing the refractive index distribution to a two-dimensional one, light, which travels to all directions, is diffracted, whereby the light extraction efficiency is enhanced.

A position to introduce a diffraction grating may be between any layers or in a medium (in a transparent substrate or a transparent electrode). However, a position near the organic light emitting layer, where light is generated, is preferable. In this case, the cycle of the diffraction grating is preferably from about ½ to 3 times of the wavelength of light in the medium. The preferable arrangement of the diffraction grating is such that the arrangement is two-dimensionally repeated in the form of a square lattice, a triangular lattice, or a honeycomb lattice.

### «Light Collection Sheet»

Via a process to arrange a structure such as a micro-lens array shape on the light extraction side of the organic EL element of the present invention or via combination with a so-called light collection sheet, light is collected in the specific direction such as the front direction with respect to the light emitting element surface, whereby it is possible to enhance luminance in the specific direction.

In an example of the micro-lens array, square pyramids to realize a side length of 30 μm and an apex angle of 90 degrees are two-dimensionally arranged on the light extraction side of the substrate. The side length is preferably 10 to 100 nm. When it is less than the lower limit, coloration occurs due to generation of diffraction effects, while when it exceeds the upper limit, the thickness increases undesirably.

It is possible to employ, as a light collection sheet, for example, one which is put into practical use in the LED backlight of liquid crystal display devices. It is possible to employ, as such a sheet, for example, the luminance enhancing film (BEF), produced by Sumitomo 3M Limited. As shapes of a prism sheet employed may be, for example, A shaped stripes of an apex angle of 90 degrees and a pitch of 50 μm formed on a base material, a shape in which the apex angle is rounded, a shape in which the pitch is randomly changed, and other shapes.

Further, in order to control the light radiation angle from the light emitting element, simultaneously employed may be a light diffusion plate-film. For example, it is possible to employ the diffusion film (LIGHT-UP), produced by Kimoto Co., Ltd.

### «Applications»

It is possible to employ the organic EL element of the present invention as display devices, displays, and various types of light emitting sources.

Examples of light emitting sources include: lighting devices (home lighting and car lighting), clocks, backlights for liquid crystals, sign advertisements, signals, light sources of light memory media, light sources of electrophotographic copiers, light sources of light communication processors, and light sources of light sensors. The present invention is not limited to them. It is especially effectively employed as a backlight of a liquid crystal display device and a lighting source.

If needed, the organic EL element of the present, invention may undergo patterning via a metal mask or an ink-jet printing method during film formation. When the patterning is carried out, only an electrode may undergo patterning, an electrode and a light emitting layer may undergo patterning, or all element layers may undergo patterning. During preparation of the element, it is possible to employ conventional methods.

### «Lighting Device»

One of the embodiments of a lighting device provided with an organic EL element of the present invention will be described.

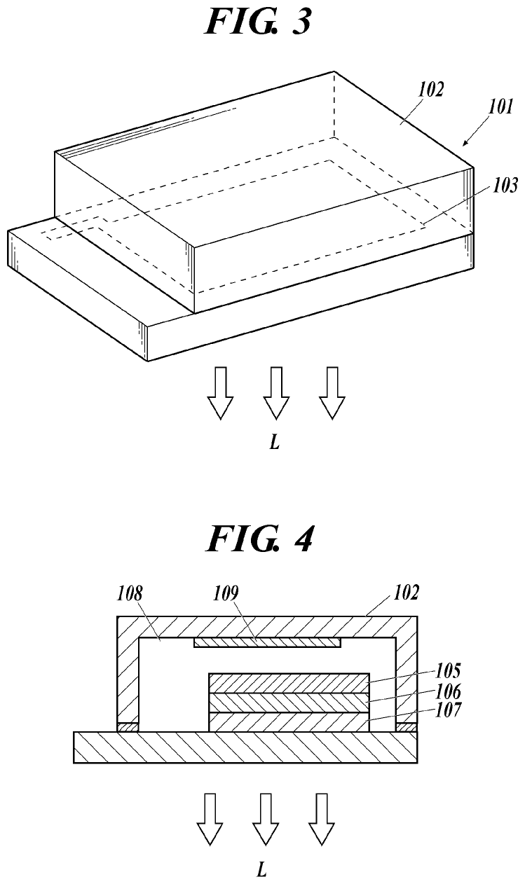

The non-light emitting surface of the organic EL element of the present invention was covered with a glass case, and a 300 μm thick glass substrate was employed as a sealing substrate. An epoxy based light curable type adhesive (LUXTRACK LC0629B produced by Toagosei Co., Ltd.) was employed in the periphery as a sealing material. The resulting one was superimposed on the aforesaid cathode to be brought into close contact with the aforesaid transparent support substrate, and curing and sealing were carried out via exposure of UV radiation onto the glass substrate side, whereby the lighting device shown in FIG. 3 and FIG. 4 was formed.

FIG. 3 is a schematic view of a lighting device. An organic EL element 101 of the present invention is covered with a glass cover 102 (incidentally, sealing by the glass cover was carried out in a globe box under nitrogen ambience (under air ambience of high purity nitrogen gas at a purity of at least 99.999%) so that the organic EL Element 101 was not brought into contact with atmosphere.

FIG. 4 is a cross-sectional view of a lighting device. In FIG. 4, 105 represents a cathode, 106 represents an organic EL layer, and 107 represents a glass substrate fitted with a transparent electrode. Further, the interior of glass cover 102 is filled with nitrogen gas 108 and a water catching agent 109 is provided.

### EXAMPLES

Hereafter, the present invention will be described specifically by referring to examples, however, the present invention is not limited to them. In examples, the indication of “part” or “%” is used. Unless particularly mentioned, it represents “mass part” or “mass %”.

Hereinafter, a single film and an organic electroluminescent device according to the present invention will be described by exemplifying examples satisfying the requirements of the present invention and comparative examples.

About various compounds used in the Examples ([Comparative Example 1] to [Comparative Example 17], [Reference Example 1] to [Reference Example 18], and [Example 1] to [Example 4]), the following compounds were used.

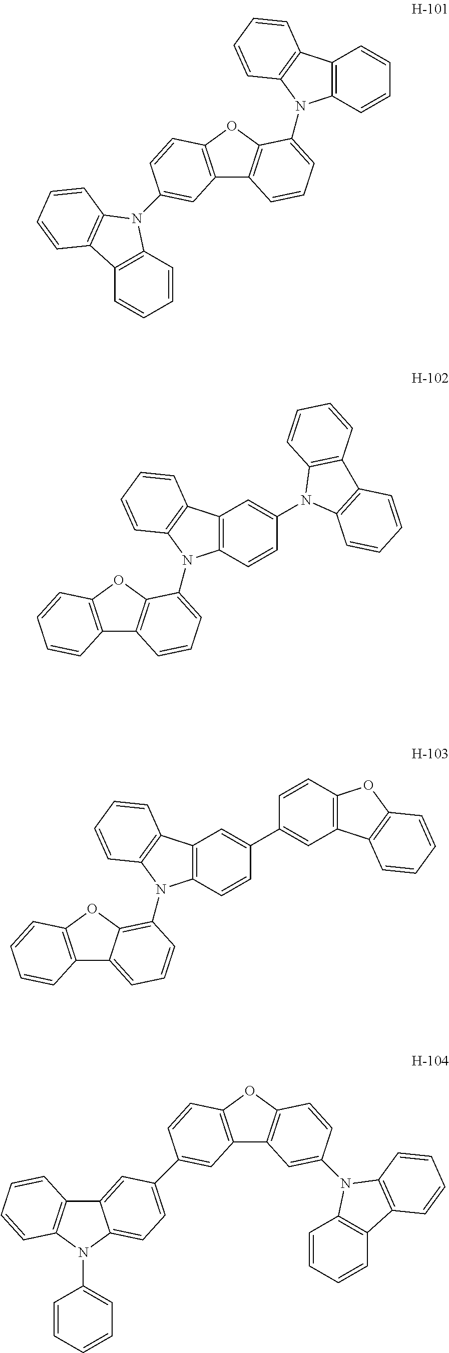 [SMILES: c1cc(-n2c3ccccc3c3ccccc32)c2oc3ccc(-n4c5ccccc5c5ccccc54)cc3c2c1 ; c1ccc2c(c1)oc1c(-n3c4ccccc4c4cc(-n5c6ccccc6c6ccccc65)ccc43)cccc12 ; c1ccc2c(c1)oc1ccc(-c3ccc4c(c3)c3ccccc3n4-c3cccc4c3oc3ccccc34)cc12 ; c1ccc(-n2c3ccccc3c3cc(-c4ccc5oc6ccc(-n7c8ccccc8c8ccccc87)cc6c5c4)ccc32)cc1]

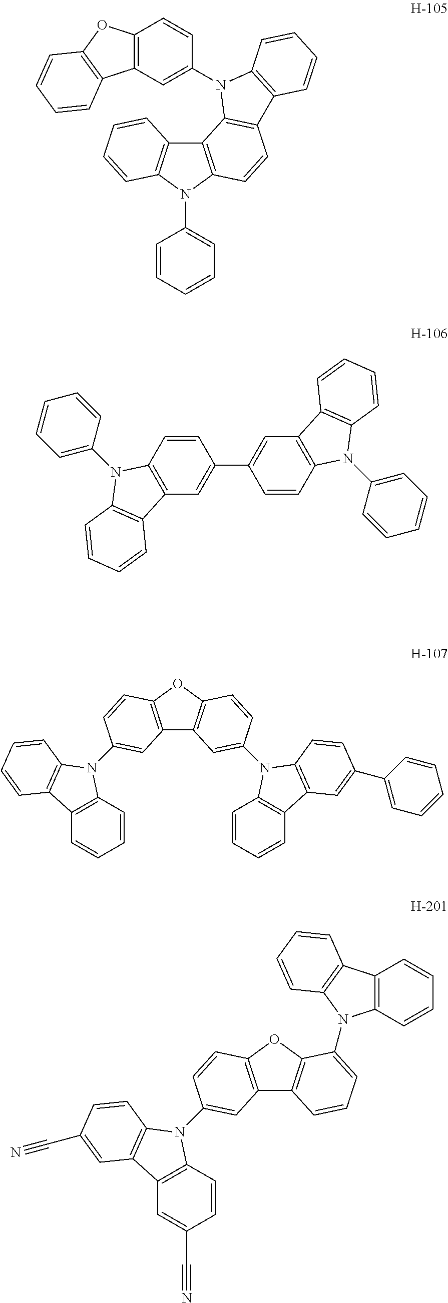 [SMILES: c1ccc(-n2c3ccccc3c3c2ccc2c4ccccc4n(-c4ccc5oc6ccccc6c5c4)c23)cc1 ; c1ccc(-n2c3ccccc3c3cc(-c4ccc5c(c4)c4ccccc4n5-c4ccccc4)ccc32)cc1 ; c1ccc(-c2ccc3c(c2)c2ccccc2n3-c2ccc3oc4ccc(-n5c6ccccc6c6ccccc65)cc4c3c2)cc1 ; N#Cc1ccc2c(c1)c1cc(C#N)ccc1n2-c1ccc2oc3c(-n4c5ccccc5c5ccccc54)cccc3c2c1]

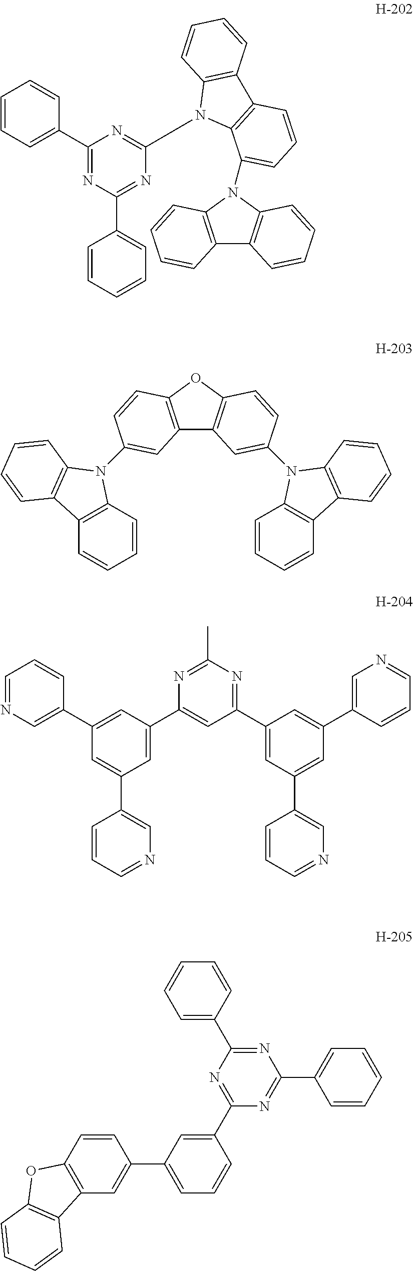 [SMILES: c1ccc(-c2nc(-c3ccccc3)nc(-n3c4ccccc4c4cccc(-n5c6ccccc6c6ccccc65)c43)n2)cc1 ; c1ccc2c(c1)c1ccccc1n2-c1ccc2oc3ccc(-n4c5ccccc5c5ccccc54)cc3c2c1 ; Cc1nc(-c2cc(-c3cccnc3)cc(-c3cccnc3)c2)cc(-c2cc(-c3cccnc3)cc(-c3cccnc3)c2)n1 ; c1ccc(-c2nc(-c3ccccc3)nc(-c3cccc(-c4ccc5oc6ccccc6c5c4)c3)n2)cc1]

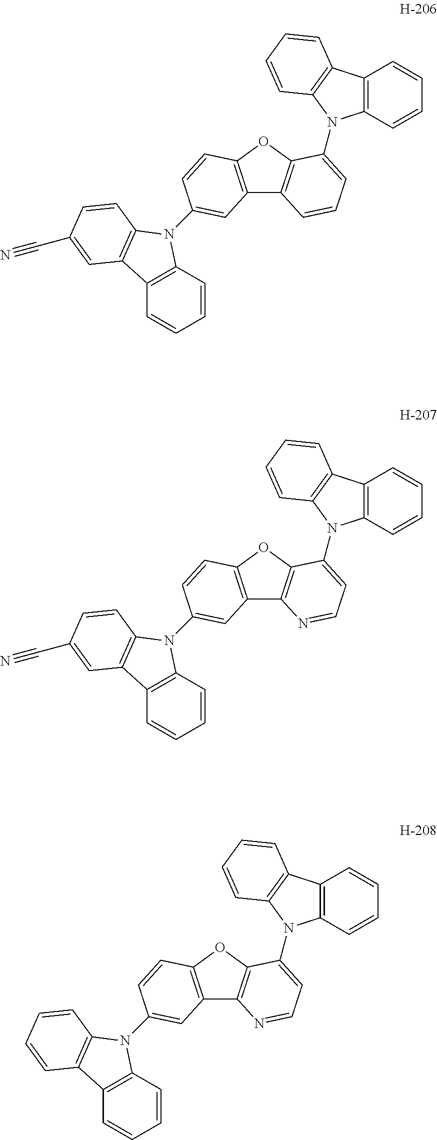 [SMILES: N#Cc1ccc2c(c1)c1ccccc1n2-c1ccc2oc3c(-n4c5ccccc5c5ccccc54)cccc3c2c1 ; N#Cc1ccc2c(c1)c1ccccc1n2-c1ccc2oc3c(-n4c5ccccc5c5ccccc54)ccnc3c2c1 ; c1ccc2c(c1)c1ccccc1n2-c1ccc2oc3c(-n4c5ccccc5c5ccccc54)ccnc3c2c1]

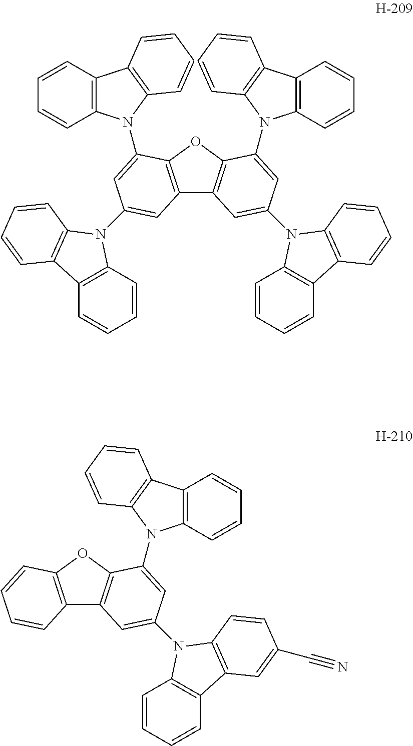 [SMILES: c1ccc2c(c1)c1ccccc1n2-c1cc(-n2c3ccccc3c3ccccc32)c2oc3c(-n4c5ccccc5c5ccccc54)cc(-n4c5ccccc5c5ccccc54)cc3c2c1 ; N#Cc1ccc2c(c1)c1ccccc1n2-c1cc(-n2c3ccccc3c3ccccc32)c2oc3ccccc3c2c1]

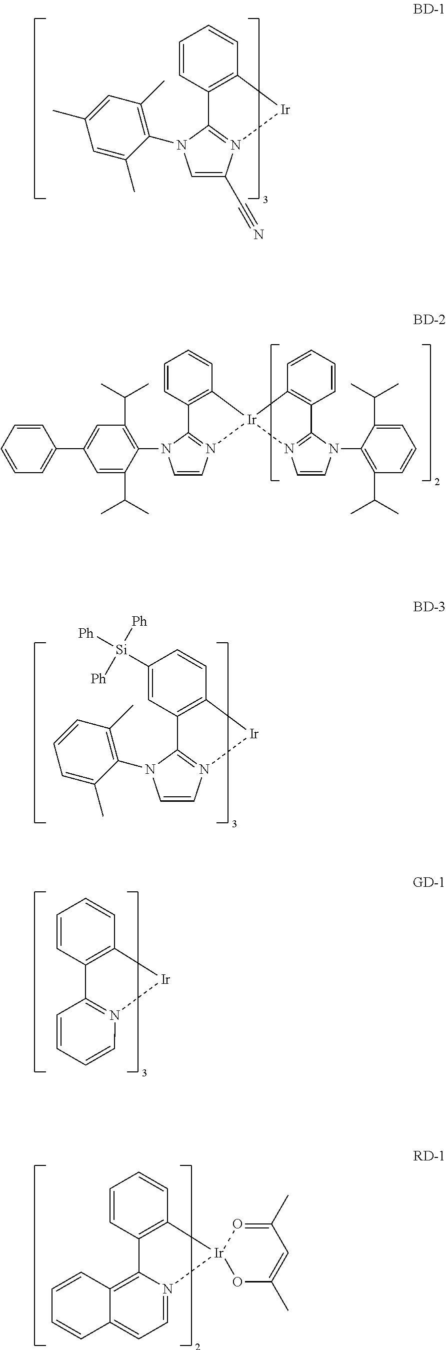

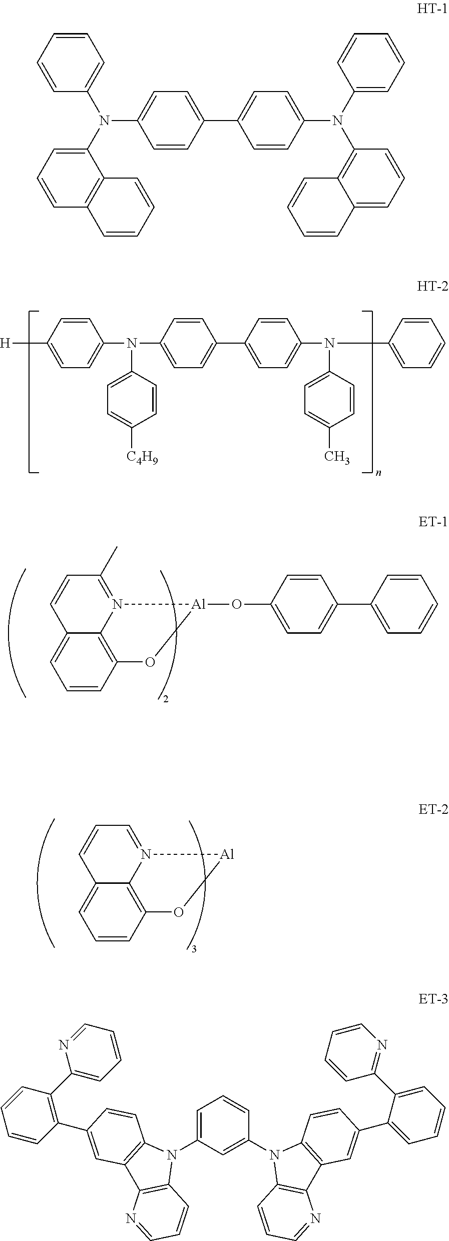

Before describing the present invention using the inventive examples and the comparative examples, first, Reference Example 1 was prepared. In Reference Example 1, the wavelength of the fluorescence emission end located on the longer wavelength side among the wavelengths of the fluorescence emission end of single films using the first host compound alone and the second host compound alone according to the present invention was compared with the fluorescence emission of a single film in which the first host compound and the second host compound were mixed at 1:1. And the fluorescence emission end shift amount (Δλ) was evaluated.

### Preparation of Single Film of Host Compound Alone (Comparative Examples 1 to 17)

A glass substrate of 50 mm×50 mm having a thickness of 0.7 mm was washed with isopropyl alcohol, followed by drying with desiccated nitrogen gas, and was subjected to UV ozone washing for 5 minutes. The resulting transparent substrate was fixed to a substrate holder of a commercial vacuum deposition apparatus. The first host compound and the second host compound indicated in Table I were loaded in each resistance heating boat for vapor deposition in the vacuum deposition apparatus with an optimum amount. As a resistance heating boat for vapor deposition, a resistance heating boat made of molybdenum or tungsten was used.

After reducing the pressure of a vacuum tank to 4×10⁻⁴ Pa, any one of the first host compound or the second host compound was vapor-deposited so that to form 100 volume %, and a 30 nm-thick evaluation single film was produced.

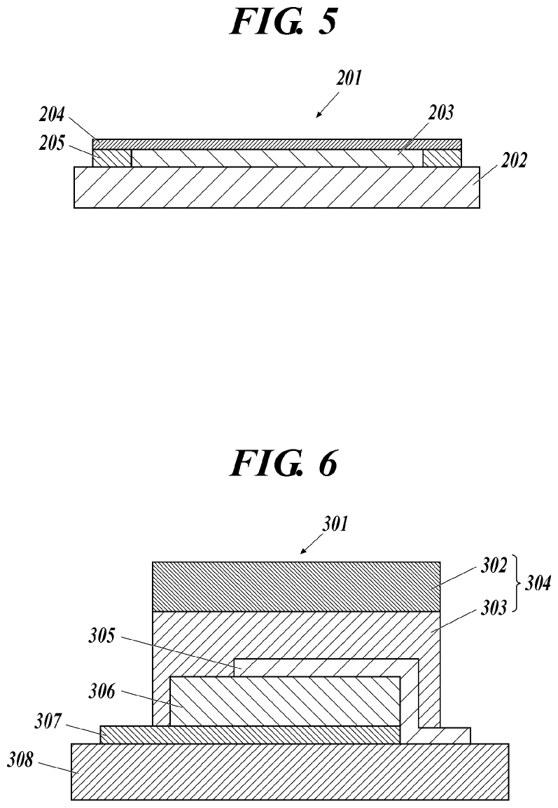

Then, using a glass substrate with a thickness of 300 μm as a sealing substrate, an epoxy-based photo-curing adhesive (ALONIX LC0629B manufactured by Toagosei Co., Ltd.) as a sealing material was applied to the periphery, and contact it with a transparent support substrate. Then, UV light was irradiated from the side of the glass substrate, cured, and sealed to prepare an evaluation single film having a configuration as illustrated in FIG. 5. In FIG. 5, 201 represents a single film sample for evaluation, 202 represents a quartz substrate, 203 represents a single film for evaluation, 204 represents a glass substrate (sealing substrate), and 205 represents an adhesive.

### Preparation of Single Film of Host Compound Mixture (for Reference Examples 1 to 18)

After reduced the vacuum chamber of the vacuum deposition apparatus to 4×10⁻⁴ Pa, a single film of host compound mixture was prepared in the same manner as preparation of the single film of the host compound except that the first host compound and the second host compound were each co-deposited to 50 volume % and 50 volume % having a layer thickness of 30 nm.

### «Measurement of Fluorescence Emission Spectrum»

The fluorescence emission spectrum was evaluated according to the following measurement method.

The emission edge was determined by exciting each single film at an excitation wavelength of 300 nm and measuring the fluorescence emission spectrum at room temperature (23° C., 55% RH). Here, the measurement of the fluorescence emission spectrum is performed using F-7000 (manufactured by Hitachi High-Technologies Corporation). The wavelength of the fluorescence emission end is defined as the wavelength on the short wavelength side whose intensity does not exceed 10% when the maximum intensity of the fluorescence is normalized to 100% in the spectrum measured at 1 nm resolution. The case where there is no wave lengthening of the fluorescence emission end difference is as follows. In comparison of emission bands of maximum emission intensity in fluorescence emission spectra of single films of the first host compound alone, the second host compound alone, and a mixture of both of the first host compound and the second host compound, a difference between a wavelength of a fluorescence emission end located on a longer wavelength side among fluorescence emission ends of the first host compound and the second host compound, and a wavelength of a fluorescence emission end of the mixture is in the range of −3 to 3 nm.

The above evaluation results are indicated in Tables I and II. As indicated in Table II, in Reference Examples 4, 5, 13 and 14 which are single films using the host compound mixture, it was confirmed that mixing causes a wave lengthening to form an exciplex.

### «Evaluation of ΔG»

To “the first host compound” and “the second host compound” which were subjected to the evaluation of the fluorescence shift amount of the single film for evaluation, evaluation of ΔG of light induced charge transfer was performed according to the following method.

By performing structural optimization of the molecular structure using B3LYP/6-31G* as a key word for “the first host compound” and “the second host compound”, the energy levels of HOMO and LUMO for each molecule were calculated, and ΔG was evaluated based on the following Expression (5).

ΔG=(LUMO_{acceptor}−HOMO_{donor})−{a smaller value of (LUMO_{acceptor}−HOMO_{acceptor}) and(LUMO_{donor}−HOMO_{donor})} Expression (5):

The above evaluation results are listed in Table II.

TABLE I

| | | | Fluorescence emission edge |
|---|---|---|---|
| Comparative | First host | Second host | wavelength of single film |
| Example No. | compound | compound | (nm) |
| 1 | H-101 | — | 349 |
| 2 | H-102 | — | 356 |
| 3 | H-103 | — | 358 |
| 4 | H-104 | — | 365 |
| 5 | H-105 | — | 363 |
| 6 | H-106 | — | 376 |
| 7 | H-107 | — | 360 |
| 8 | — | H-201 | 353 |
| 9 | — | H-202 | 427 |
| 10 | — | H-203 | 349 |
| 11 | — | H-204 | 377 |
| 12 | — | H-205 | 369 |
| 13 | — | H-206 | 350 |
| 14 | — | H-207 | 370 |
| 15 | — | H-208 | 374 |
| 16 | — | H-209 | 365 |
| 17 | — | H-210 | 348 |

TABLE II

| | First | | Second | | | | | | | | |
|---|---|---|---|---|---|---|---|---|---|---|---|
| | host compound | | host compound | | | | | | | | |
| | | Fluorescence | | Fluorescence | Fluorescence | | | | | | |
| | | emission | | emission | emission edge wavelength of | | | | | | |
| | | edge | | edge | mixed single film (nm) | | | | | | |
| | | wavelength | | wavelength | First host | | First | | Second | | |
| | | of | | of | compound:Second | Shift amount of | host compound | | host compound | | |
| Reference | | single film | | single film | host compound = | emission edge | HOMO₁ | LUMO₁ | HOMO₂ | LUMO₂ | ΔG |
| Example No. | Kind | (nm) | Kind | (nm) | 50:50 Volume % | wavelength *1 | (eV) | (eV) | (eV) | (eV) | (eV) |
| 1 | H-101 | 349 | H-201 | 353 | 352 | −1 | −5.38 | −1.42 | −5.65 | −1.85 | −0.27 |
| 2 | H-101 | 349 | H-202 | 427 | 427 | 0 | −5.38 | −1.42 | −5.24 | −1.87 | 0.14 |
| 3 | H-101 | 349 | H-203 | 349 | 349 | 0 | −5.38 | −1.42 | −5.38 | −1.44 | 0.00 |
| 4 | H-101 | 349 | H-204 | 377 | 386 | 9 | −5.38 | −1.42 | −6.49 | −2.05 | −0.63 |
| 5 | H-101 | 349 | H-205 | 369 | 379 | 10 | −5.38 | −1.42 | −5.88 | −1.83 | −0.41 |
| 6 | H-101 | 349 | H-206 | 350 | 350 | 0 | −5.38 | −1.42 | −5.55 | −1.64 | −0.17 |
| 7 | H-102 | 356 | H-201 | 353 | 359 | 3 | −5.11 | −1.31 | −5.65 | −1.85 | −0.54 |
| 8 | H-102 | 356 | H-207 | 370 | 369 | −1 | −5.11 | −1.31 | −5.78 | −1.90 | −0.60 |
| 9 | H-102 | 356 | H-208 | 374 | 372 | −2 | −5.11 | −1.31 | −5.38 | −1.70 | −0.27 |
| 10 | H-103 | 358 | H-201 | 353 | 359 | 1 | −5.22 | −1.23 | −5.65 | −1.85 | −0.44 |
| 11 | H-104 | 365 | H-201 | 353 | 365 | 0 | −5.27 | −1.15 | −5.65 | −1.85 | −0.39 |
| 12 | H-105 | 363 | H-201 | 353 | 363 | 0 | −4.98 | −1.17 | −5.65 | −1.85 | −0.68 |
| 13 | H-106 | 376 | H-202 | 376 | 438 | 62 | −4.98 | −0.69 | −5.38 | −1.89 | −0.40 |
| 14 | H-106 | 376 | H-204 | 377 | 430 | 53 | −4.98 | −0.69 | −6.49 | −2.05 | −1.36 |
| 15 | H-107 | 360 | H-209 | 365 | 365 | 0 | −5.31 | −1.48 | −5.49 | −1.73 | −0.18 |
| 16 | H-107 | 360 | H-210 | 348 | 361 | 1 | −5.31 | −1.48 | −5.61 | −1.62 | −0.14 |
| 17 | H-206 | 350 | H-204 | 377 | 378 | 1 | −5.55 | −1.64 | −6.49 | −2.05 | −0.41 |
| 18 | H-207 | 370 | H-204 | 377 | 377 | 0 | −5.78 | −1.90 | −6.49 | −2.05 | −0.15 |

*1: (Fluorescent edge wavelength of mixed host compounds single film) − (Longer fluorescent edge wavelength of solo host compound single film)

In order to express charge separation in the excited state, ΔG in Expression (5) needs to be negative, and in the present application, ΔG<−0.1 (eV). There is no limit to the lower limit of the negative ΔG range, but as is generally known by the electron transfer reaction rate of Marcus, it is preferred that −ΔG is close to the reorientation energy because charge separation most efficiently occurs. Although the reorientation energy of the organic compound varies depending on the compound to be used, it is approximately 0.1 to 1.0 eV. Therefore, ΔG is preferably in the range of −0.1 to −1.0 eV. In the combinations of Reference Examples 1, 4 to 13, 15, and 16, ΔG was in the range of −1.0 to −0.1 eV, and it was confirmed that the charge transfer spontaneously proceeded.

### Example 1

In Example 1, the characteristics of the vapor deposition film formation white light lighting device (organic EL element) containing the first host compound and the second host compound were evaluated.

### (Preparation of Lighting Device 1-1)

An anode was prepared by making patterning to a glass substrate having a thickness of 0.7 mm on which ITO (indium tin oxide) was formed with a thickness of 110 nm. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

On the transparent support substrate thus prepared was applied a 70% solution of poly (3,4-ethylenedioxythiphene)-polystyrene sulfonate (PEDOT/PSS, Baytron P AI4083, made by Bayer ΔG.) diluted with water by using a spin coating method at 3,000 rpm for 30 seconds to form a film, and then it was dried at 130° C. for one hour. A hole injection-transport layer having a thickness of 30 nm was prepared. Then, the resulting transparent support substrate was fixed to a substrate holder of a commercial vacuum deposition apparatus. As a resistance heating boat for vapor deposition, a resistance heating boat made of molybdenum or tungsten was used.

Then, after reducing the pressure of a vacuum tank to 4×10⁻⁴ Pa, a green phosphorescent metal complex GD-1, a compound RD-3, a compound F-1 and a compound H-2 were co-deposited with a thickness of 80 nm so that the phosphorescent metal complex was 1 volume %, the compound RD-3 was 0.5 volume %, the compound F-1 was 15.5 volume %, and the compound H-2 was 83 volume % to form a light emitting layer (hereinafter abbreviated as EML). Subsequently, ET-1 was deposited with a thickness of 30 nm, whereby an electron transport layer was formed. Subsequently, 2 nm thick potassium fluoride (KF) was vapor deposited, and then, 150 nm thick aluminum was vapor deposited to form a cathode.

Subsequently, the non-light emitting surface of the prepared organic EL element was covered with a glass cover. Thus, a lighting device 1-1 was prepared.

Subsequently, the non-light emitting surface of the prepared organic EL element was covered with a glass cover. Thus, a lighting device 1-1 was prepared.

Next, lighting devices 1-2 to 1-6 were prepared in the same manner as preparation of the lighting device 1-1, except that the first host compound of the lighting device 1-1 was changed to the host compound indicated in Table III.

Further, except that the host compound was changed to 41 volume % of the first host compound and 41 volume % of the second host compound, lighting devices 1-7 to 1-22 were produced in the same manner as the lighting device 1-1.

The external quantum efficiencies of the produced lighting devices 1-1 to 1-22 were measured as follows, and the light-emitting properties were evaluated. Further, the half-life was measured as described below to evaluate the continuous drive stability (element lifetime).

### <External Quantum Efficiency (EQE)>

Each lighting device was allowed to emit light with a constant electric current of 2.5 mA/cm² at room temperature (at about 23° C.). The external quantum efficiency (EQE) was determined by measuring the luminance (L0) (cd/m²) measured immediately after starting to emit light.

Here, the measurement of luminance was done with Spectroradiometer CS-2000 (produced by Konica Minolta Inc.). The external quantum efficiency was represented by a relative value when the external quantum efficiency of the lighting device 1-1 was set to be 100.

### <Element Lifetime>

According to the following measurement method, evaluation of continuous drive stability (element lifetime) was performed by half-life measurement.

The prepared lighting device was driven with a constant electric current to give an initial luminance of 4,000 cd/m². The time required for decease in one half of the initial luminance was determined, and it was used as a scale for a half-life. The emission lifetime was represented as a relative value when the emission lifetime of the lighting device 1-1 was set to be 100. When the value is larger, it indicates that the durability is better compared with the comparative sample.

The above evaluation results are indicated in Table III.

### «Evaluation of ΔG′ and ΔG″»

About “the first host compound” and “the second host compound” described in the reference example, evaluation of ΔG′ and ΔG″ of the photoinduced charge transfer between “the first host compound” and “the second host compound” and “phosphorescent metal complex” according to the following method was performed based on Expressions (2a) and (2b).

By performing structural optimization of the targeted molecular structure using B3LYP/LanL2DZ for the blue phosphorescent metal complex used in the present invention, the energy level of LUMO, the energy level of HOMO, and the lowest excited triplet energy level were calculated. Evaluation of ΔG′ and ΔG″ was performed based on the following Expressions (2a) and (2b). The energy level of LUMO, the energy level of HOMO, and the lowest excited triplet energy level of BD-1 were determined to be −1.00 eV, −4.83 eV, and 2.78 eV, respectively, and they were used for the calculation.

ΔG′=(LUMO_{PC}−HOMO₁)−T_{PC1}>0 Expression (2a):

ΔG″=(LUMO₂−HOMO_{PC})−T_{PC1}>0 Expression (2b):

Wherein, LUMO_{PC} represents an energy level of LUMO of the phosphorescent metal complex,

HOMO_{PC} represents an energy level of HOMO of the phosphorescent metal complex,

T_{PC1} represents a lowest excited triplet energy level of the phosphorescent metal complex,

HOMO₁ represents an energy level of HOMO of the first host compound,

LUMO₂ represents an energy level of LUMO of the second host compound.

The above evaluation results are listed in Table III. It is preferable that both ΔG′ and ΔG″ are positively large directions (ΔG′>0, ΔG″>0) because in this case deactivation or formation of exciplex between the blue phosphorescent complex and the host compound does not occur.

TABLE III

| | | First host | | Second | | | | | | | | |
|---|---|---|---|---|---|---|---|---|---|---|---|---|
| | | compound | | host compound | | | | | | | | |
| | | | Com- | | Com- | | | | | Evaluation | | |
| | | | position | | position | Dopant | | | | (Relative value) | | |
| Lighting | | | ratio | | ratio | Blue | Properties | | | External | | |
| device | Comparative Example/ | | (Volume | | (Volume | phosphorescent | ΔG | ΔG′ | ΔG″ | quantum | Element | Re- |
| No. | Reference Example No. | Kind | %) | Kind | %) | metal complex | (eV) | (eV) | (eV) | efficiency | lifetime | marks |
| 1-1 | Comparative Example 1 | H-101 | 82 | — | — | BD-1 | — | — | — | 100 | 100 | *1 |
| 1-2 | Comparative Example 2 | H-102 | 82 | — | — | BD-1 | — | — | — | 91 | 69 | *1 |
| 1-3 | Comparative Example 3 | H-103 | 82 | — | — | BD-1 | — | — | — | 114 | 77 | *1 |
| 1-4 | Comparative Example 4 | H-104 | 82 | — | — | BD-1 | — | — | — | 106 | 75 | *1 |
| 1-5 | Comparative Example 6 | H-106 | 82 | — | — | BD-1 | — | — | — | 80 | 42 | *1 |
| 1-6 | Comparative Example 8 | — | — | H-201 | 82 | BD-1 | — | — | — | 125 | 78 | *1 |
| 1-7 | Reference Example 2 | H-101 | 41 | H-202 | 41 | BD-1 | 0.14 | 0.18 | 1.60 | 112 | 69 | *1 |
| 1-8 | Reference Example 3 | H-101 | 41 | H-203 | 41 | BD-1 | 0.00 | 0.60 | 1.60 | 98 | 101 | *1 |
| 1-9 | Reference Example 4 | H-101 | 41 | H-204 | 41 | BD-1 | −0.63 | −0.01 | 1.60 | 42 | 18 | *1 |
| 1-10 | Reference Example 5 | H-101 | 41 | H-205 | 41 | BD-1 | −0.41 | 0.21 | 1.60 | 61 | 46 | *1 |
| 1-11 | Reference Example 13 | H-106 | 41 | H-202 | 41 | BD-1 | −0.40 | 0.16 | 1.20 | 97 | 24 | *1 |
| 1-12 | Reference Example 14 | H-106 | 41 | H-204 | 41 | BD-1 | −1.36 | −0.01 | 1.20 | 101 | 32 | *1 |
| 1-13 | Reference Example 1 | H-101 | 41 | H-201 | 41 | BD-1 | −0.27 | 0.20 | 1.60 | 128 | 116 | *2 |
| 1-14 | Reference Example 6 | H-101 | 41 | H-206 | 41 | BD-1 | −0.17 | 0.40 | 1.60 | 121 | 174 | *2 |
| 1-15 | Reference Example 7 | H-102 | 41 | H-201 | 41 | BD-1 | −0.54 | 0.20 | 1.33 | 134 | 217 | *2 |
| 1-16 | Reference Example 8 | H-102 | 41 | H-207 | 41 | BD-1 | −0.60 | 0.14 | 1.33 | 132 | 236 | *2 |
| 1-17 | Reference Example 9 | H-102 | 41 | H-208 | 41 | BD-1 | −0.27 | 0.32 | 1.31 | 124 | 180 | *2 |
| 1-18 | Reference Example 10 | H-103 | 41 | H-201 | 41 | BD-1 | −0.44 | 0.20 | 1.44 | 119 | 163 | *2 |
| 1-19 | Reference Example 11 | H-104 | 41 | H-201 | 41 | BD-1 | −0.39 | 0.20 | 1.49 | 106 | 159 | *2 |
| 1-20 | Reference Example 12 | H-105 | 41 | H-201 | 41 | BD-1 | −0.68 | 0.18 | 1.18 | 120 | 122 | *2 |
| 1-21 | Reference Example 17 | H-206 | 41 | H-204 | 41 | BD-1 | −0.41 | −0.01 | 1.77 | 98 | 131 | *2 |
| 1-22 | Reference Example 18 | H-207 | 41 | H-204 | 41 | BD-1 | −0.15 | −0.01 | 2.00 | 101 | 127 | *2 |

*1: Comparative example
*2: Inventive example

As apparent from Table III, the lighting devices 1-13 to 1-22 of the present invention are excellent in the external quantum efficiency and the element lifetime as compared with the lighting devices 1-1 to 1-6 using a single host compound. Further, in the lighting devices 1-7 and 1-8, which use a combination in which light-induced charge transfer does not occur spontaneously, it was found that an element lifetime is inferior. Thus, when the host not satisfying the relationship of the present invention is mixed, the effect of the present invention is not exhibited. Further, in the lighting devices 1-9 to 1-12, which use a host compound producing an exciplex, it was found that the external quantum efficiency and the element lifetime decrease.

In the lighting devices 1-21 and 1-2, which use a combination of having a negative ΔG′ value, it was found that an improvement in the external quantum efficiency is inferior to the lighting devices 1-13 to 1-20 of the present invention.

The lighting devices 2-1 and 2-4 were produced in the same manner as production of the lighting device in Example 1, except that the first host compound, the second host compound, and their composition ratio are changed as described in Table IV, and the blue phosphorescent metal complex are changed to BD-2. The same evaluations as in Example 1 were performed. The results are listed in Table IV.

The energy level of LUMO, the energy level of HOMO, and the lowest excitation triplet energy of BD-2 were determined to be −1.10 eV, −4.43 eV, and 2.81 eV, respectively, and they were used for the calculation.

TABLE IV

| | Combination | First | | Second | | | | | | Evaluation | | |
|---|---|---|---|---|---|---|---|---|---|---|---|---|
| | Comparative | host compound | | host compound | | Dopant | | | | (Relative value) | | |
| Lighting | Example/ | | Composition | | Composition | Blue | Properties | | | External | | |
| device | Reference | | ratio | | ratio | phosphorescent | ΔG | ΔG′ | ΔG″ | quantum | Element | |
| No. | Example No. | Kind | (Volume %) | Kind | (Volume %) | metal complex | (eV) | (eV) | (eV) | efficiency | lifetime | Remarks |
| 2-1 | Comparative | H-102 | 82 | — | — | BD-2 | — | — | — | 100 | 100 | *1 |
| | Example 2 | | | | | | | | | | | |
| 2-2 | Comparative | H-103 | 82 | — | — | BD-2 | — | — | — | 94 | 121 | *1 |
| | Example 3 | | | | | | | | | | | |
| 2-3 | Reference | H-102 | 61 | H-208 | 21 | BD-2 | −0.27 | 0.32 | 1.31 | 130 | 176 | *2 |
| | Example 9 | | | | | | | | | | | |
| 2-4 | Reference | H-103 | 41 | H-201 | 41 | BD-2 | −0.44 | 0.20 | 1.44 | 125 | 167 | *2 |
| | Example 10 | | | | | | | | | | | |

*1: Comparative example
*2: Inventive example

From Table IV, it can be seen that the lighting devices 2-3 and 2-4 of the present invention are excellent in the external quantum efficiency and the element lifetime.

### Example 3

Next, in Example 3, the characteristics of the blue light emitting lighting device (and element) produced by the wet process using a coating liquid were confirmed.

### «Preparation of Lighting Device for Evaluation»

### (Preparation of Substrate)

First, on the entire surface of a polyethylene naphthalate film (hereinafter abbreviated as PEN) (manufactured by Teijin DuPont Films Co. Ltd.) on which the anode is to be formed, an atmospheric pressure plasma discharge treatment using an apparatus having the structure described in JP-A No. 2004-68143 was carried out to form an inorganic gas barrier layer made of SiOₓ having a thickness of 500 nm. In this way, a flexible substrate having gas barrier properties of an oxygen permeability of 0.001 ml/(m²·24 h) or less and a water vapor permeability of 0.001 g/(m²·24 h) or less was prepared.

### (Formation of Anode)

ITO (indium tin oxide) having a thickness of 120 nm was formed on the above-described substrate by a sputtering method and patterned by a photolithography method. Thus, an anode was formed. The pattern was such that the area of the light emitting region was 5 cm×5 cm.

### (Formation of Hole Injection Layer)

The substrate on which the anode was formed was subjected to ultrasonic washing with isopropyl alcohol, followed by drying with desiccated nitrogen gas, and was subjected to UV ozone washing for 5 minutes. Then, a dispersion liquid of poly (3,4-ethylenedioxythiophene)/polystyrene sulfonate (PEDOT/PSS) was prepared in the same manner as in Example 16 of Japanese Patent No. 4,509,787. A 2 mass % solution prepared by diluting the above-described dispersion liquid with isopropyl alcohol was applied by a die coating method and followed by air dried to form a hole injection layer having a thickness of 40 nm.

### (Formation of Hole Transport Layer)

Subsequently, the substrate on which the hole injection layer was formed was transferred under a nitrogen atmosphere using nitrogen gas (grade G1), and the coating solution for forming a hole transport layer having the following composition was coated by a die coating method at 5 m/min, followed by air dried, and then kept at 130° C. for 30 minutes. Thus, a hole transport layer having a thickness of 30 nm was formed.

### <Coating Solution for Forming Hole Transport Layer>

Hole transport material HT-2 (weight average molecular weight Mw=80000):
10 mass parts

Chlorobenzene: 3000 mass parts

### (Formation of Light Emitting Layer)

Subsequently, the substrate on which the hole transport layer was formed was coated by a die coating method at a coating rate of 5 m/min using a coating solution for forming a light emitting layer having the following composition, followed by air dried, and then kept at 120° C. for 30 minutes. Thus, a light emitting layer having a thickness of 50 nm was formed.

### <Coating Solution for Forming Light Emitting Layer>

First host compound indicated in Table V: 9 mass parts

Blue phosphorescent metal complex BD-3: 1 mass part

Isopropyl acetate: 2,000 mass parts

### (Formation of Blocking Layer)

Subsequently, the substrate on which the light emitting layer was formed was coated by a die coating method at a coating rate of 5 m/min using a coating solution for forming a blocking layer having the following composition, followed by air dried, and then kept at 80° C. for 30 minutes. Thus, a blocking layer having a thickness of 10 nm was formed.

### (Formation of Electron Transport Layer)

Subsequently, the substrate on which the light emitting layer was formed was coated by a die coating method at a coating rate of 5 m/min using a coating solution for forming an electron transport layer having the following composition, followed by air dried, and then kept at 80° C. for 30 minutes. Thus, an electron transport layer having a thickness of 30 nm was formed.

### <Coating Solution for Forming Electron Transport Layer>

ET-3: 6 mass parts

1H,1H,3H-Tetrafluoropropanol (TFPO): 2000 mass parts

### (Formation of Electron Injection Layer and Cathode)

Subsequently, the substrate was attached to a vacuum vapor deposition apparatus without exposure to the atmosphere. Also, molybdenum resistance heating boats each containing sodium fluoride and potassium fluoride were attached to the vacuum evaporation apparatus, and the vacuum chamber was reduced to 4×10⁻⁵ Pa. Thereafter, the boat was energized and heated, and sodium fluoride was vapor-deposited on the electron transport layer at 0.02 nm/sec. Thus, a thin film having a thickness of 1 nm was formed. Similarly, potassium fluoride was vapor-deposited on the sodium fluoride thin film at 0.02 nm/sec. Thus, an electron injection layer with a layer thickness of 1.5 nm was formed.

Here, from the hole injection layer to the electron injection layer are referred to as “organic functional layers”.

Subsequently, aluminum was vapor-deposited to form a cathode having a thickness of 100 nm.

### (Sealing)

To the laminate body formed by the above steps, a sealing substrate was bonded using a commercially available roll laminating apparatus.

As a sealing substrate, the following material was prepared. An adhesive layer having a layer thickness of 1.5 μm was provided on a flexible aluminum foil having a thickness of 30 μm (made by Toyo Aluminum K.K.) using a two-liquid reaction type urethane adhesive for dry lamination, then a polyethylene terephthalate (PET) film having a thickness of 12 μm was laminated.

A thermosetting adhesive as a sealing adhesive was uniformly applied with a thickness of 20 μm along the adhesive surface (gloss surface) of the aluminum foil of the sealing substrate using a dispenser. This was dried under a vacuum of 100 Pa or less for 12 hours. Further, the sealing substrate was moved to a nitrogen atmosphere having a dew point temperature of −80° C. or less and an oxygen concentration of 0.8 ppm and dried for 12 hours or more, and the moisture content of the sealing adhesive was adjusted to be 100 ppm or less.

As the thermosetting adhesive, an epoxy adhesive obtained by mixing the following (A) to (C) was used.

(A) Bisphenol A diglycidyl ether (DGEBA)

(B) Dicyandiamide (DICY)

(C) Epoxy adduct type curing accelerator

The sealing substrate was brought into close contact with the above laminate body and tightly sealed under a pressure bonding condition of a pressure roll temperature of 100° C., a pressure of 0.5 MPa, and a machine speed of 0.3 m/min using a pressure roll.

As described above, the organic EL element 3-1 having the same configuration as that of the organic EL element having the configuration indicated in FIG. 4 were prepared.

Subsequently, organic EL elements 3-2 and 3-3 were produced in the same manner except that the first host compound and the second host compound were combined as described in Table V in the coating solution for forming a light emitting layer as described below.

### <Coating Solution for Forming Light Emitting Layer>

First host compound indicated in Table V: 4.5 mass parts

Second host compound indicated in Table V: 4.5 mass parts

Blue phosphorescent metal complex BD-3: 1.0 mass part

Isopropyl acetate: 2,000 mass parts

As described above, the organic EL element 3-1 to the organic EL element 3-3 were produced, and they were referred to as lighting devices 3-1 to 3-3.

### «Evaluation of Luminescence (External Quantum Efficiency) and Continuous Driving Stability (Element Lifetime) by Half-Life Measurement»

Evaluation of luminescence (external quantum efficiency) and continuous driving stability (element lifetime) by half-life measurement, and evaluation of ΔG′ and ΔG″ were performed in the same manner as in Example 1. The energy level of LUMO, the energy level of HOMO, and the lowest excitation triplet energy of BD-3 were determined to be −0.70 eV, −4.54 eV, and 2.80 eV, respectively, and they were used for the calculation.

The external quantum efficiency (EQE) and the element lifetime of each evaluation lighting device were determined as a relative value with the values of the evaluation lighting device 3-1 to be 100.

TABLE V

| | Combination | First | | Second | | | | | | Evaluation | | |
|---|---|---|---|---|---|---|---|---|---|---|---|---|
| | Comparative | host compound | | host compound | | Dopant | | | | (Relative value) | | |
| | Example/ | | Composition | | Composition | Blue | Properties | | | External | | |
| Lighting | Reference | | ratio | | ratio | phosphorescent | ΔG | ΔG′ | ΔG″ | quantum | Element | |
| device No. | Example No. | Kind | (Volume %) | Kind | (Volume %) | metal complex | (eV) | (eV) | (eV) | efficiency | lifetime | Remarks |
| 3-1 | Comparative | H-107 | 90 | — | — | BD-3 | — | — | — | 100 | 100 | *1 |
| | Example 7 | | | | | | | | | | | |
| 3-2 | Reference | H-107 | 45 | H-209 | 45 | BD-3 | −0.18 | 0.01 | 1.77 | 112 | 142 | *2 |
| | Example 15 | | | | | | | | | | | |
| 3-3 | Reference | H-107 | 45 | H-210 | 45 | BD-3 | −0.14 | 0.12 | 1.77 | 109 | 134 | *2 |
| | Example 16 | | | | | | | | | | | |

*1: Comparative example
*2: Inventive example

From Table V, it can be seen that the lighting devices 3-2 and 3-3 of the present invention are excellent in the external quantum efficiency and the element lifetime.

### Example 4

Next, in Example 4, the characteristics of a blue-emitting lighting device (organic EL element) produced by an ink-jet (hereinafter, abbreviated as IJ) process were confirmed.

### <<Preparation of Lighting Device for Evaluation»

### (Preparation of Substrate)

First, on the entire surface of a polyethylene naphthalate film (hereinafter abbreviated as PEN) (manufactured by Teijin DuPont Films Co. Ltd.) on which the anode is to be formed, an atmospheric pressure plasma discharge treatment using an apparatus having the structure described in JP-A No. 2004-68143 was carried out to form an inorganic gas barrier layer made of SiOₓ having a thickness of 500 nm. In this way, a flexible substrate having gas barrier properties of an oxygen permeability of 0.001 mL/(m²·24 h) or less and a water vapor permeability of 0.001 g/(m²·24 h) or less was prepared.

### (Formation of Anode)

ITO (indium tin oxide) having a thickness of 120 nm was formed on the above-described substrate by a sputtering method and patterned by a photolithography method. Thus, an anode was formed. The pattern was such that the area of the light emitting region was 5 cm×5 cm.

### (Formation of Hole Injection Layer)

The substrate on which the anode was formed was subjected to ultrasonic washing with isopropyl alcohol, followed by drying with desiccated nitrogen gas, and was subjected to UV ozone washing for 5 minutes. Then, a dispersion liquid of poly (3,4-ethylenedioxythiophene)/polystyrene sulfonate (PEDOT/PSS) was prepared in the same manner as in Example 16 of Japanese Patent No. 4,509,787. A 2 mass % solution prepared by diluting the above-described dispersion liquid with isopropyl alcohol was applied by an ink-jet method and dried at 80° C. for 5 minutes to form a hole injection layer having a thickness of 40 nm.

### (Formation of Hole Transport Layer)

Subsequently, the substrate on which the hole injection layer was formed was transferred under a nitrogen atmosphere using nitrogen gas (grade G1), and the coating solution for forming a hole transport layer having the following composition was coated by an IJ process and followed by dried at 150° C. for 30 minutes. Thus, a hole transport layer having a thickness of 30 nm was formed.

### <Coating Solution for Forming Hole Transport Layer>

Hole transport material HT-2 (weight average molecular weight Mw=80000):
10 mass parts

(p)-Xylene: 3000 mass parts

### (Formation of Light Emitting Layer)

Subsequently, the substrate on which the hole transport layer was formed was coated by an IJ process using a coating solution for forming a light emitting layer having the following composition, and then dried at 130° C. for 30 minutes. Thus, a light emitting layer having a thickness of 50 nm was formed.

### <Coating Solution for Forming Light Emitting Layer>

First host compound described in Table VI: 9 mass parts

Blue phosphorescent metal complex BD-3: 1 mass part

Isopropyl acetate: 2000 mass parts

### (Formation of Electron Transport Layer)

Subsequently, the substrate on which the blocking layer was formed was coated by an IJ process using a coating solution for forming an electron transport layer having the following composition, followed by air dried, and then kept at 80° C. for 30 minutes. Thus, an electron transport layer having a thickness of 30 nm was formed.

### <Coating Solution for Forming Electron Transport Layer>

ET-3: 6 mass parts

1H,1H,3H-Tetrafluoropropanol (TFPO): 2000 mass parts

### (Formation of Electron Injection Layer and Cathode)

Subsequently, the substrate was attached to a vacuum vapor deposition apparatus without exposure to the atmosphere. Also, molybdenum resistance heating boats containing sodium fluoride and potassium fluoride were attached to the vacuum evaporation apparatus, and the vacuum chamber was reduced to 4×10′ Pa. Thereafter, the boat was energized and heated, and sodium fluoride was vapor-deposited on the electron transport layer at 0.02 nm/sec. Thus, a thin film having a thickness of 1 nm was formed. Similarly, potassium fluoride was vapor-deposited on the sodium fluoride thin film at 0.02 nm/sec. Thus, an electron injection layer with a layer thickness of 1.5 nm was formed.

Subsequently, aluminum was vapor-deposited to form a cathode having a thickness of 100 nm.

### (Sealing)

To the laminate body formed by the above steps, a sealing substrate was bonded using a commercially available roll laminating apparatus.

As a sealing substrate, the following material was prepared. An adhesive layer having a layer thickness of 1.5 μm was provided on a flexible aluminum foil having a thickness of 30 μm (made by Toyo Aluminum K.K.) using a two-liquid reaction type urethane adhesive for dry lamination, then a polyethylene terephthalate (PET) film having a thickness of 12 μm was laminated.

A thermosetting adhesive as a sealing adhesive was uniformly applied with a thickness of 20 μm along the adhesive surface (gloss surface) of the aluminum foil of the sealing substrate using a dispenser. This was dried under a vacuum of 100 Pa or less for 12 hours. Further, the sealing substrate was moved to a nitrogen atmosphere having a dew point temperature of −80° C. or less and an oxygen concentration of 0.8 ppm and dried for 12 hours or more, and the moisture content of the sealing adhesive was adjusted to be 100 ppm or less.

As the thermosetting adhesive, an epoxy adhesive obtained by mixing the following (A) to (C) was used.

(A) Bisphenol A diglycidyl ether (DGEBA)

(B) Dicyandiamide (DICY)

(C) Epoxy adduct type curing accelerator

The sealing substrate was brought into close contact with the above laminate body and tightly sealed under a pressure bonding condition of a pressure roll temperature of 100° C., a pressure of 0.5 MPa, and a machine speed of 0.3 m/min using a pressure roll.

In the manner described above, an organic EL element 4-1 having the same configuration as that of the organic EL element having the structure indicated in FIG. 6 was produced. In FIG. 6, 301 represents an organic EL element, 302 represents a sealing member, 303 represents an adhesive layer, 304 represents a sealing material, 305 represents a cathode, 306 represents an organic functional layer, 307 represents an anode, and 308 represents a flexible substrate.

Subsequently, organic EL elements 4-2 and 4-3 were produced in the same manner except that the first host compound and the second host compound were combined as described in Table VI in the coating solution for forming a light emitting layer as described below.

### <Coating Solution for Forming Light Emitting Layer>

First host compound indicated in Table VI: 4.5 mass parts

Second host compound indicated in Table VI: 4.5 mass parts

Blue phosphorescent metal complex BD-3: 1 mass part

Isopropyl acetate: 2,000 mass parts

As described above, the organic EL element 4-1 to the organic EL element 4-3 were produced, and they were referred to as lighting devices 4-1 to 4-3.

### «Evaluation of Luminescence (External Quantum Efficiency) and Continuous Driving Stability (Element Lifetime) by Half-Life Measurement»

Evaluation of luminescence (external quantum efficiency) and continuous driving stability (element lifetime) by half-life measurement were performed in the same manner as in Example 1.

The external quantum efficiency (EQE) and the element lifetime of each evaluation lighting device were determined as a relative value with the values of the evaluation lighting device 4-1 to be 100.

TABLE VI

| | Combination | First | | Second | | | | | | Evaluation | | |
|---|---|---|---|---|---|---|---|---|---|---|---|---|
| | Comparative | host compound | | host compound | | Dopant | | | | (Relative value) | | |
| | Example/ | | Composition | | Composition | Blue phosphorescent | Properties | | | External | | |
| Lighting | Reference | | ratio | | ratio | metal | ΔG | ΔG′ | ΔG″ | quantum | Element | |
| device No. | Example No. | Kind | (Volume %) | Kind | (Volume %) | complex | (eV) | (eV) | (eV) | efficiency | lifetime | Remarks |
| 4-1 | Comparative | H-107 | 90 | — | — | BD-3 | — | — | — | 100 | 100 | *1 |
| | Example 7 | | | | | | | | | | | |
| 4-2 | Reference | H-107 | 45 | H-209 | 45 | BD-3 | −0.18 | 0.01 | 1.77 | 116 | 164 | *2 |
| | Example 15 | | | | | | | | | | | |
| 4-3 | Reference | H-107 | 45 | H-210 | 45 | BD-3 | −0.14 | 0.12 | 1.77 | 114 | 142 | *2 |
| | Example 16 | | | | | | | | | | | |

*1: Comparative example
*2: Inventive example

From Table VI, it can be seen that the lighting devices 4-2 and 4-3 of the present invention are excellent in the external quantum efficiency and the element lifetime.

### INDUSTRIAL APPLICABILITY

The organic EL element of the present invention is an device having a high external quantum efficiency and an improved element lifetime, and it may be used as a display device, a display, various light sources, particularly a backlight of a liquid crystal display, and a light source for illumination.

### DESCRIPTION OF SYMBOLS

101: Lighting device
102: Glass cover
103: Organic EL element
105: Cathode
106: Organic EL layer
107: Glass substrate having a transparent electrode
108: Nitrogen gas
109: Water catching agent
201: Single film sample for evaluation
202: Quartz substrate
203: Single film for evaluation
204: Glass substrate (sealing substrate)
205: Adhesive
301: Organic EL element
302: Sealing member
303: Adhesive layer
304: Sealing material
305: Cathode
306: Organic functional layer
307: Anode
308: Flexible substrate

What is claimed is:

1. An organic electroluminescent element comprising a light emitting layer containing at least a first host compound, a second host compound, and a phosphorescent metal complex disposed between a cathode and an anode, wherein the first host compound and the second host compound have the following characteristics (A) and (B),
(A) characteristic of fluorescence emission spectrum:
in comparison of emission bands of maximum emission intensity in fluorescence emission spectra of single films of the first host compound alone, the second host compound alone, and a mixture of both of the first host compound and the second host compound, a difference between a wavelength of a fluorescence emission end located on a longer wavelength side among fluorescence emission ends of the first host compound and the second host compound, and a wavelength of a fluorescence emission end of the mixture is in the range of −3 to 3 nm; and
(B) characteristic of molecular orbital energy levels:
when energy levels of a highest occupied molecular orbital (HOMO) and a lowest unoccupied molecular orbital (LUMO) of the first host compound and the second host compound are respectively HOMO₁, LUMO₁, HOMO₂ and LUMO₂, the energy levels respectively satisfy relationships represented by Expressions (1a) to (1c),
LUMO₁>LUMO₂ Expression (1a):
HOMO₁>HOMO₂ Expression (1b):
ΔG=(LUMO₂−HOMO₁)−{a smaller value among (LUMO₁−HOMO₁) and (LUMO₂−HOMO₂)}<−0.1 (eV). Expression (1c):

2. The organic electroluminescent element described in claim 1, satisfying relationships represented by Expressions (2a) and (2b),
ΔG′=(LUMO_{PC}−HOMO₁)−T_{PC1}>0 Expression (2a):
ΔG″=(LUMO₂−HOMO_{PC})−T_{PC1}>0 Expression (2b):
wherein, LUMO_{PC} represents an energy level of LUMO of the phosphorescent metal complex,
HOMO_{PC} represents an energy level of HOMO of the phosphorescent metal complex,
T_{PC1} represents a lowest excited triplet energy level of the phosphorescent metal complex,
HOMO₁ represents an energy level of HOMO of the first host compound,
LUMO₂ represents an energy level of LUMO of the second host compound.

3. The organic electroluminescent element described in claim 2, wherein the phosphorescent metal complex has the lowest excited triplet energy level (T_{PC1}) in the range of 2.25 to 3.00 eV.
